(19) United States
(12) Patent Application Publication
(10) Pub. No.: US 2026/0090106 A1
(43) Pub. Date: Mar. 26, 2026

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Daisuke KUROSAKI, Utsunomiya (JP); Miwa TANABE, Tochigi (JP); Seiji YASUMOTO, Tochigi (JP); Junichi KOEZUKA, Tochigi (JP)

(21) Appl. No.: 19/136,996

(22) PCT Filed: Dec. 18, 2023
(86) PCT No.: PCT/IB2023/062853

§ 371 Date: Jun. 9, 2025

(30) Foreign Application Priority Data
Dec. 23, 2022 (JP) 2022-206945
Mar. 1, 2023 (JP) 2023-031234
May 2, 2023 (JP) 2023-076169

(51) Int. Cl. H10D 86/60; H10D 30/01; H10D 30/67; H10D 62/10; H10D 86/01; H10D 86/40; H10K 59/12; H10K 59/121; H10K 59/123; H10K 65/00

(52) U.S. Cl. CPC H10D 86/60; H10D 30/0314; H10D 30/6728; H10D 30/6731; H10D 30/6734; H10D 30/6736; H10D 30/6757; H10D 62/102; H10D 86/0221; H10D 86/0231; H10D 86/421; H10D 86/431; H10D 86/471; H10D 86/481; H10K 59/1201; H10K 59/1213; H10K 59/123; H10K 65/00

(57) ABSTRACT

A semiconductor device is provided over a base insulating layer including hydrogen. A first conductive layer, a spacer, and a second conductive layer are provided over the base insulating layer. The spacer and the second conductive layer comprise an opening reaching the first conductive layer in which a metal oxide layer is provided. The metal oxide layer includes a region in contact with the first conductive layer and the second conductive layer. The first conductive layer and the second conductive layer function as one and the other of a source electrode and a drain electrode of the transistor. A gate insulating layer is provided over the metal oxide layer to include a region positioned in the opening. A gate electrode is provided to include a region facing the metal oxide layer with the gate insulating layer between the region and the metal oxide layer in the opening.

### TECHNICAL FIELD

One embodiment of the present invention relates to a semiconductor device and a method for manufacturing the semiconductor device. One embodiment of the present invention relates to a transistor and a method for manufacturing the transistor. One embodiment of the present invention relates to a display device that includes a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### BACKGROUND ART

Semiconductor devices that include transistors are applied to a wide range of electronic devices. In a display device, for example, when transistors occupy smaller areas, the pixel size can be smaller and higher resolution can be achieved. Therefore, miniaturization of transistors has been required.

As devices requiring high-resolution display devices, for example, devices for virtual reality (VR), augmented reality (AR), substitutional reality (SR), or mixed reality (MR) have been actively developed.

As display devices, for example, light-emitting apparatuses that include organic EL (Electro Luminescence) elements or light-emitting diodes (LEDs) have been developed.

Patent Document 1 discloses a high-resolution display device that includes an organic EL element.

### REFERENCE

### [Patent Document]

[Patent Document 1] International Publication No. 2016/038508

### SUMMARY OF THE INVENTION

### Problems to be Solved by the Invention

A transistor may have a low on-state current when the contact resistance between a semiconductor layer including a channel formation region and a source electrode or a drain electrode is high. This may reduce the operation speed of a semiconductor device including the transistor. When the operation speed of a semiconductor device included in a display device is reduced, for example, the frame frequency decreases in some cases.

An object of one embodiment of the present invention is to provide a transistor having a high on-state current. Another object is to provide a transistor having favorable electrical characteristics. Another object is to provide a transistor having a minute size. Another object is to provide a transistor having a small channel length. Another object is to provide a semiconductor device including any of these transistors.

Another object is to provide a semiconductor device that operates at high speed. Another object is to provide a semiconductor device that occupies a small area. Another object is to provide a semiconductor device having low wiring resistance. Another object is to provide a semiconductor device or a display device having low power consumption. Another object is to provide a highly reliable transistor, a highly reliable semiconductor device, or a highly reliable display device. Another object is to provide a display device having a high frame frequency. Another object is to provide a display device that can easily achieve higher resolution. Another object is to provide a method for manufacturing a semiconductor device or a display device with high productivity. Another object is to provide a novel transistor, a novel semiconductor device, a novel display device, and manufacturing methods thereof.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a semiconductor device which includes a first insulating layer, a second insulating layer, a first conductive layer, and a metal oxide layer and in which the first conductive layer is provided over the first insulating layer; the second insulating layer is provided over the first conductive layer; the second insulating layer is provided with a first opening reaching the first conductive layer; the metal oxide layer includes a region positioned in the first opening and being in contact with the first conductive layer; and the first insulating layer includes hydrogen.

Alternatively, in the above embodiment, the second insulating layer may include a first layer and a second layer over the first layer, the first layer may include a region in contact with the first insulating layer, and the first insulating layer may include a region with a hydrogen content higher than or equal to a hydrogen content of the first layer.

Alternatively, in the above embodiment, a hydrogen diffusion coefficient of the first layer may be lower than a hydrogen diffusion coefficient of the first conductive layer.

Alternatively, in the above embodiment, the second layer may include oxygen.

Alternatively, in any of the above embodiments, the semiconductor device may include a second conductive layer; the second conductive layer may be provided over the second insulating layer; the second conductive layer may be provided with a second opening including a region overlapping with the first opening; and the second conductive layer may include a region in contact with the metal oxide layer.

Alternatively, in any of the above embodiments, the semiconductor device may include a second conductive layer; the second conductive layer may be provided over the second insulating layer; the second conductive layer may be provided with a second opening including a region overlapping with the first opening; the second conductive layer may include a region in contact with the metal oxide layer; the second insulating layer may include a third layer over the second layer and a fourth layer over the third layer; the fourth layer may include a region in contact with the second conductive layer; and the fourth layer may include a region with a hydrogen content higher than or equal to a hydrogen content of the third layer.

Alternatively, in the above embodiment, the semiconductor device may include a third insulating layer and a third conductive layer; the third insulating layer may be provided over the metal oxide layer to include a region positioned in the first opening; and the third conductive layer may be provided to include a region facing the metal oxide layer with the third insulating layer between the region and the metal oxide layer in the first opening.

Alternatively, in the above embodiment, the hydrogen content of each of the first insulating layer, the first layer, the third layer, and the fourth layer may be measured by SIMS.

Alternatively, in the above embodiment, a hydrogen diffusion coefficient of the third layer may be lower than a hydrogen diffusion coefficient of the second conductive layer.

Alternatively, in the above embodiment, the hydrogen diffusion coefficient of each of the first conductive layer, the second conductive layer, the first layer, and the second layer may be measured by TDS or SIMS.

Alternatively, in the above embodiment, the third layer may include a material that is the same as a material the first layer includes, and the fourth layer may include a material that is the same as a material the first insulating layer includes.

Another embodiment of the present invention is a method for manufacturing a semiconductor device, the method including: forming a first insulating layer including hydrogen; forming a first conductive layer over the first insulating layer; forming a second insulating layer over the first conductive layer; forming a second conductive layer over the second insulating layer; processing the second conductive layer to form a first opening, the first opening including a region overlapping with the first conductive layer; processing the second insulating layer to form a second opening, the second opening including a region overlapping with the first opening, the second opening reaching the first conductive layer; forming a metal oxide layer, the metal oxide layer including a region that includes a region positioned in the second opening and that is in contact with the first conductive layer, the metal oxide layer including a region that is in contact with the second conductive layer; forming a third insulating layer over the metal oxide layer, the third insulating layer including a region positioned in the second opening; and forming a third conductive layer, the third conductive layer including a region facing the metal oxide layer with the third insulating layer between the region and the metal oxide layer in the second opening.

Alternatively, in the above embodiment, a first layer including a region in contact with the first insulating layer and a second layer over the first layer may be formed as the second insulating layer, and a proportion of a molecule including hydrogen in a film formation gas for the first layer may be lower than or equal to a proportion of a molecule including hydrogen in a film formation gas for the first insulating layer.

Alternatively, in the above embodiment, the first layer may be formed to have a hydrogen diffusion coefficient lower than a hydrogen diffusion coefficient of the first conductive layer.

Alternatively, in the above embodiment, oxygen may be supplied to the second layer after the second layer is formed but before the second conductive layer is formed.

Alternatively, in any of the above embodiments, a third layer over the second layer and a fourth layer over the third layer may be formed as the second insulating layer; a proportion of a molecule including hydrogen in a film formation gas for the fourth layer may be higher than or equal to a proportion of a molecule including hydrogen in a film formation gas for the third layer; and the second conductive layer may be formed to include a region in contact with the fourth layer.

Alternatively, in the above embodiment, the third layer may be formed to have a hydrogen diffusion coefficient lower than a hydrogen diffusion coefficient of the second conductive layer.

Alternatively, in the above embodiment, the third layer may be formed to include a material that is the same as a material the first layer includes, and the fourth layer may be formed to include a material that is the same as a material the first insulating layer includes.

### Effect of the Invention

According to one embodiment of the present invention, a transistor having a high on-state current can be provided. Alternatively, a transistor having favorable electrical characteristics can be provided. Alternatively, a transistor having a minute size can be provided. Alternatively, a transistor having a small channel length can be provided. Alternatively, a semiconductor device including any of these transistors can be provided.

Alternatively, a semiconductor device that operates at high speed can be provided. Alternatively, a semiconductor device that occupies a small area can be provided. Alternatively, a semiconductor device having low wiring resistance can be provided. Alternatively, a semiconductor device or a display device having low power consumption can be provided. Alternatively, a highly reliable transistor, a highly reliable semiconductor device, or a highly reliable display device can be provided. Alternatively, a display device having a high frame frequency can be provided. Alternatively, a display device that can easily achieve higher resolution can be provided. Alternatively, a method for manufacturing a semiconductor device or a display device with high productivity can be provided. Alternatively, a novel transistor, a novel semiconductor device, a novel display device, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating a structure example of a semiconductor device. FIG. 1B and

FIG. 1C are cross-sectional views illustrating the structure example of the semiconductor device.

FIG. 2A to FIG. 2D are perspective views illustrating a structure example of a semiconductor device.

FIG. 3A is a plan view illustrating a structure example of a semiconductor device. FIG. 3B is a cross-sectional view illustrating the structure example of the semiconductor device.

FIG. 4A and FIG. 4B are cross-sectional views illustrating structure examples of a semiconductor device.

FIG. 5A and FIG. 5B are cross-sectional views illustrating a structure example of a semiconductor device.

FIG. 6A is a plan view illustrating a structure example of a semiconductor device. FIG. 6B and FIG. 6C are cross-sectional views illustrating the structure example of the semiconductor device.

FIG. 7A is a plan view illustrating a structure example of a semiconductor device. FIG. 7B is a cross-sectional view illustrating the structure example of the semiconductor device.

FIG. 8A and FIG. 8B are cross-sectional views illustrating structure examples of a semiconductor device.

FIG. 9A to FIG. 9C are cross-sectional views illustrating structure examples of a semiconductor device.

FIG. 10A to FIG. 10C are cross-sectional views illustrating structure examples of a semiconductor device.

FIG. 11A is a plan view illustrating a structure example of a semiconductor device. FIG. 11B and

FIG. 11C are cross-sectional views illustrating the structure example of the semiconductor device.

FIG. 12A is a plan view illustrating a structure example of a semiconductor device. FIG. 12B and FIG. 12C are cross-sectional views illustrating the structure example of the semiconductor device.

FIG. 13A is a plan view illustrating a structure example of a semiconductor device. FIG. 13B and FIG. 13C are cross-sectional views illustrating the structure example of the semiconductor device.

FIG. 14A is a plan view illustrating a structure example of a semiconductor device. FIG. 14B is a cross-sectional view illustrating the structure example of the semiconductor device.

FIG. 15A and FIG. 15B are cross-sectional views illustrating structure examples of semiconductor devices.

FIG. 16A is a plan view illustrating a structure example of a semiconductor device. FIG. 16B and

FIG. 16C are cross-sectional views illustrating the structure example of the semiconductor device.

FIG. 17A and FIG. 17B are cross-sectional views illustrating a structure example of a semiconductor device.

FIG. 18A to FIG. 18C are plan views illustrating examples of opening shapes.

FIG. 19A to FIG. 19D are circuit diagrams illustrating structure examples of a semiconductor device.

FIG. 20A and FIG. 20B are cross-sectional views illustrating structure examples of a semiconductor device.

FIG. 21A is a plan view illustrating a structure example of a semiconductor device. FIG. 21B is a cross-sectional view illustrating the structure example of the semiconductor device.

FIG. 22A and FIG. 22B are cross-sectional views illustrating a structure example of a semiconductor device.

FIG. 23A is a plan view illustrating a structure example of a semiconductor device. FIG. 23B is a cross-sectional view illustrating the structure example of the semiconductor device.

FIG. 24A to FIG. 24D are cross-sectional views illustrating an example of a method for manufacturing a semiconductor device.

FIG. 25A to FIG. 25C are cross-sectional views illustrating an example of a method for manufacturing a semiconductor device.

FIG. 26A and FIG. 26B are cross-sectional views illustrating an example of a method for manufacturing a semiconductor device.

FIG. 27A and FIG. 27B are cross-sectional views illustrating an example of a method for manufacturing a semiconductor device.

FIG. 28 is a perspective view illustrating a structure example of a display device.

FIG. 29A and FIG. 29B are cross-sectional views illustrating structure examples of display devices.

FIG. 30 is a cross-sectional view illustrating a structure example of a display device.

FIG. 31A to FIG. 31C are cross-sectional views illustrating structure examples of a display device.

FIG. 32A and FIG. 32B are cross-sectional views illustrating structure examples of display devices.

FIG. 33 is a cross-sectional view illustrating a structure example of a display device.

FIG. 34 is a cross-sectional view illustrating a structure example of a display device.

FIG. 35 is a cross-sectional view illustrating a structure example of a display device.

FIG. 36A and FIG. 36B are cross-sectional views illustrating structure examples of display devices.

FIG. 37A to FIG. 37D are diagrams illustrating examples of electronic devices.

FIG. 38A to FIG. 38F are diagrams illustrating examples of electronic devices.

FIG. 39A to FIG. 39G are diagrams illustrating examples of electronic devices.

FIG. 40 is a cross-sectional view illustrating a structure of samples in Example.

FIG. 41A and FIG. 41B are graphs showing carrier concentration and contact resistance of samples in Example.

FIG. 42A and FIG. 42B are graphs showing carrier concentration and contact resistance of samples in Example.

FIG. 43 is a graph showing carrier concentration and contact resistance of samples in Example.

FIG. 44 is a graph showing Id-Vg characteristics and field-effect mobility of transistors in Example.

FIG. 45 is a graph showing Id-Vg characteristics and field-effect mobility of transistors in Example.

FIG. 46A is a graph showing probability distribution of threshold voltages of transistors in Example. FIG. 46B is a graph showing probability distribution of field-effect mobility of the transistors in Example.

FIG. 47A is a graph showing channel lengths of transistors in Example. FIG. 47B is a graph showing the amounts of change in threshold voltage of the transistors in Example.

FIG. 48 is a graph showing Id-Vg characteristics and field-effect mobility of transistors in Example.

FIG. 49A is a graph showing probability distribution of threshold voltages of transistors in Example. FIG. 49B is a graph showing probability distribution of drain currents of transistors in Example.

FIG. 50A is a graph showing channel lengths of transistors in Example. FIG. 50B is a graph showing the amounts of change in threshold voltage of the transistors in Example.

FIG. 51A is a graph showing Id-Vg characteristics of a transistor in Example. FIG. 51B is a graph showing a change over time in threshold voltage of the transistor in Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

Note that the terms “film” and “layer” can be used interchangeably depending on the case or the circumstances. For example, the term “conductive layer” can be replaced with the term “conductive film” in some cases. For another example, the term “insulating layer” can be replaced with the term “insulating film” in some cases. For another example, the term “semiconductor layer” can be replaced with the term “semiconductor film” in some cases.

A transistor is a kind of semiconductor element and can achieve a function of amplifying a current or a voltage, a switching operation for controlling conduction or non-conduction, and the like. An IGFET (Insulated Gate Field Effect Transistor) and a thin film transistor (TFT) are in the category of a transistor in this specification.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

In this specification and the like, the term “electrically connected” includes the case where components are connected to each other through an “object having any electric action”. Here, there is no particular limitation on the “object having any electric function” as long as electric signals can be transmitted and received between the components that are connected through the object. Examples of the “object having any electric function” include a switching element such as a transistor, a resistor, a coil, a capacitor, and other elements with a variety of functions as well as an electrode or a wiring.

Unless otherwise specified, an off-state current in this specification and the like refers to a leakage current between a source and a drain generated when a transistor is in an off state (also referred to as a non-conducting state or a cutoff state). Unless otherwise specified, an off state of an n-channel transistor refers to a state where a voltage V_{gs} between its gate and source is lower than a threshold voltage Vₜₕ (in a p-channel transistor, higher than Vₜₕ).

In this specification and the like, normally-on characteristics mean a state where a channel exists without application of a voltage to a gate and a current flows through a transistor. Furthermore, normally-off characteristics mean a state where a current does not flow through a transistor when no potential or a ground potential is applied to a gate.

In this specification and the like, the expression “having substantially the same top-view shapes” means that the outlines of stacked layers at least partly overlap with each other. For example, the expression encompasses the case of processing an upper layer and a lower layer with the use of the same mask pattern or mask patterns that are partly the same. The expression “having substantially the same top-view shapes” also sometimes encompasses the case where the outlines do not completely overlap with each other; for instance, the outline of the upper layer may be positioned inward or outward from the outline of the lower layer. In the case where top-view shapes are the same or substantially the same, it can be said that end portions match or substantially match each other.

In this specification and the like, a top-view shape of a component means the contour shape of the component in a plan view. A plan view means that the component is observed from a normal direction of a surface where the component is formed or from a normal direction of a surface of a support (e.g., a substrate) where the component is formed.

In this specification and the like, a tapered shape refers to such a shape that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is greater than 0° and less than 90°. Note that the side surface, the substrate surface, and the formation surface of the component are not necessarily completely flat, and may have a substantially planar shape with a small curvature or a substantially planar shape with slight unevenness.

Note that in this specification and the like, an oxynitride refers to a material in which the oxygen content is higher than the nitrogen content. A nitride oxide refers to a material in which the nitrogen content is higher than the oxygen content. Here, an oxide film encompasses a film including an oxynitride, and a nitride film encompasses a film including a nitride oxide.

In this specification and the like, when the expression “A is in contact with B” is used, at least part of A is in contact with B. In other words, A includes a region in contact with B, for example.

In this specification and the like, when the expression “A is provided over B” is used, at least part of A is provided over B. In other words, A includes a region provided over B, for example.

In this specification and the like, when the expression “A overlaps with B” is used, at least part of A overlaps with B. In other words, A includes a region overlapping with B, for example.

In this specification and the like, a device formed using a metal mask or an FMM (fine metal mask, high-resolution metal mask) may be referred to as a device having an MM (metal mask) structure. In this specification and the like, a device fabricated without using a metal mask or an FMM is sometimes referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can extend the freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may also be referred to as a mask layer) refers to a layer that is positioned above at least a light-emitting layer (specifically, a layer processed into an island shape among layers included in an EL layer) and has a function of protecting the light-emitting layer in the manufacturing process.

In this specification and the like, an island shape refers to a state where two or more layers formed using the same material in the same step are physically separated from each other. For example, an island-shaped light-emitting layer refers to a state where the light-emitting layer and its adjacent light-emitting layer are physically separated from each other.

In this specification and the like, step disconnection refers to a phenomenon in which a layer, a film, or an electrode is split because of the shape of its formation surface (e.g., a step).

### Embodiment 1

In this embodiment, structure examples of a semiconductor device of one embodiment of the present invention and a manufacturing method example thereof are described.

In a transistor included in the semiconductor device of one embodiment of the present invention (also referred to as a transistor of one embodiment of the present invention), a source electrode and a drain electrode are positioned at different levels, and a current flows in the height direction in a semiconductor layer. In other words, the channel length direction can be regarded as having a component of the height direction (vertical direction); accordingly, the transistor of one embodiment of the present invention can also be referred to as a vertical transistor, a vertical-channel transistor, or the like.

Specifically, an insulating layer functioning as a spacer is provided between a lower electrode that is one of the source electrode and the drain electrode of the transistor and an upper electrode that is the other of the source electrode and the drain electrode of the transistor. Note that in the following description, an insulating layer functioning as a spacer is sometimes simply referred to as a spacer, and a spacer may be rephrased as an insulating layer.

A first opening reaching the lower electrode is provided in the spacer, and a second opening including a region overlapping with the first opening is provided in the upper electrode. The semiconductor layer where a channel is formed is provided to include a region in contact with the lower electrode and a region in contact with the upper electrode and to include the region positioned in the first opening and the region positioned in the second opening. A gate insulating layer and a gate electrode are provided in the first opening and the second opening to overlap with the semiconductor layer. Since the source electrode, the semiconductor layer, and the drain electrode can be provided to overlap with each other, the area occupied by the transistor can be significantly smaller than that of what is called a planar transistor in which a semiconductor layer is positioned over a plane.

As the semiconductor layer included in the transistor of one embodiment of the present invention, a layer including a metal oxide exhibiting semiconductor characteristics (also referred to as an oxide semiconductor) can be used. Here, in this specification and the like, a layer including a metal oxide exhibiting semiconductor characteristics is referred to as a metal oxide layer or an oxide semiconductor layer. Examples of a metal oxide that can be used for the semiconductor layer include an oxide containing indium, an oxide containing gallium, and an oxide containing zinc. Examples of a metal oxide that can be used for the semiconductor layer include indium oxide, indium zinc oxide, and indium gallium zinc oxide.

Here, the transistor may have a low on-state current when the contact resistance between the source electrode and the semiconductor layer or the contact resistance between the drain electrode and the semiconductor layer is high.

In view of this, the transistor of one embodiment of the present invention is provided over a base insulating layer including hydrogen. Specifically, the base insulating layer including hydrogen is provided over a substrate, the lower electrode of the transistor is provided over the base insulating layer, and the metal oxide layer is provided over the lower electrode. More specifically, the lower electrode of the transistor is provided to include a region in contact with the top surface of the base insulating layer including hydrogen, and the metal oxide layer is provided to include a region in contact with the top surface of the lower electrode. This allows hydrogen included in the base insulating layer to be transmitted through the lower electrode and to be supplied to the region of the metal oxide layer that is in contact with the lower electrode and a region in the vicinity thereof. Here, the base insulating layer includes at least a region where the hydrogen content per unit volume is higher than or equal to the hydrogen content per unit volume of the spacer.

In this specification and the like, the simple term “content” sometimes refers to a content per unit volume or unit area.

Reaction between oxygen bonded to a metal atom included in the metal oxide layer and hydrogen generates water, and thus forms an oxygen vacancy (Vo) in the metal oxide. A defect that is an oxygen vacancy into which hydrogen enters (hereinafter referred to as VoH) functions as a donor and generates an electron serving as a carrier. In some cases, bonding of part of hydrogen to oxygen bonded to a metal atom generates electrons serving as carriers. Generation of electrons serving as carriers in the metal oxide layer reduces the resistance of the metal oxide layer. In the above manner, the hydrogen supply to the region of the metal oxide layer that is in contact with the lower electrode can reduce the contact resistance between the metal oxide layer and the lower electrode. Accordingly, the transistor can have a higher on-state current and favorable electrical characteristics. This allows the semiconductor device to operate at high speed.

The spacer may have a single-layer structure or a stacked-layer structure of a plurality of layers. For example, the spacer can have a three-layer stacked structure of a first insulating layer, a second insulating layer over the first insulating layer, and a third insulating layer over the second insulating layer. Alternatively, the spacer can have a four-layer stacked structure in which a fourth insulating layer is provided over the third insulating layer.

The first insulating layer can be formed using a material that does not easily allow diffusion of hydrogen. The first insulating layer can be formed using, for example, a material that is less likely to allow diffusion of hydrogen than the first conductive layer or a material that is less likely to allow diffusion of hydrogen than the second insulating layer. The first insulating layer can be formed using, for example, a material having a lower hydrogen diffusion coefficient than the first conductive layer or a material having a lower hydrogen diffusion coefficient than the second insulating layer. In that case, hydrogen included in the base insulating layer can be inhibited from being supplied to, for example, the region of the metal oxide layer that is away from the region where the lower electrode and the metal oxide layer are in contact with each other. For example, hydrogen included in the base insulating layer can be inhibited from being supplied to the region of the metal oxide layer that is in contact with the second insulating layer. It is thus possible to inhibit a reduction in the channel length of the transistor and a reduction in the threshold voltage of the transistor, that is, a negative shift of the threshold voltage. This can reduce a cutoff current, so that the transistor can have normally-off characteristics (i.e., the transistor can have a positive threshold voltage value). Thus, the reliability of the transistor of one embodiment of the present invention can be increased, and the reliability of the semiconductor device of one embodiment of the present invention can be increased.

As the second insulating layer, a layer including oxygen can be used. For example, the second insulating layer can include a region having a higher oxygen content than at least one of the first insulating layer, the third insulating layer, and the fourth insulating layer. In that case, oxygen can be supplied to the region of the metal oxide layer that is in contact with neither the lower electrode nor the upper electrode. Accordingly, oxygen can be supplied to a channel formation region of the metal oxide layer. This facilitates a reduction in oxygen vacancies in the metal oxide layer and formation of an i-type channel formation region. As a result, the transistor of one embodiment of the present invention can have favorable electrical characteristics and increased reliability. Thus, the semiconductor device of one embodiment of the present invention can have increased reliability.

The third insulating layer can be formed using a material that does not easily allow diffusion of hydrogen. For example, the third insulating layer can be formed using a material that can be used for the first insulating layer.

Here, the first insulating layer and the third insulating layer can be formed using a material that does not easily allow diffusion of oxygen as well as hydrogen. The first insulating layer and the third insulating layer can be formed using, for example, a material that is less likely to allow diffusion of oxygen than the second insulating layer. The first insulating layer and the third insulating layer can be formed using, for example, a material having a lower oxygen diffusion coefficient than the second insulating layer. For example, each of the first insulating layer and the third insulating layer can be formed using a nitride insulating film, and the second insulating layer can be formed using an oxide insulating film. Specifically, for example, each of the first insulating layer and the third insulating layer can be formed using a silicon nitride film or a silicon nitride oxide film, and the second insulating layer can be formed using a silicon oxide film or a silicon oxynitride film.

In the above manner, diffusion of oxygen included in the second insulating layer to outside the spacer due to heating, for example, can be inhibited. In other words, when the first insulating layer and the third insulating layer that do not easily allow diffusion of oxygen are provided below and above the second insulating layer such that the second insulating layer is sandwiched therebetween, oxygen can be enclosed in the second insulating layer. Accordingly, oxygen can be favorably supplied to the channel formation region of the metal oxide layer.

The fourth insulating layer can be provided to include a region in contact with the bottom surface of the upper electrode and can include hydrogen. This allows hydrogen included in the fourth insulating layer to be transmitted through the upper electrode and to be supplied to the region of the metal oxide layer that is in contact with the upper electrode and a region in the vicinity thereof. Thus, the contact resistance between the metal oxide layer and the upper electrode can be reduced. Accordingly, the transistor can have a higher on-state current and favorable electrical characteristics. This allows the semiconductor device to operate at high speed. Here, when the third insulating layer provided under the fourth insulating layer is formed using a material that does not easily allow diffusion of hydrogen, hydrogen included in the fourth insulating layer can be inhibited from being supplied to, for example, the region of the metal oxide layer that is away from the upper electrode and the fourth insulating layer. For example, hydrogen included in the fourth insulating layer can be inhibited from being supplied to the region of the metal oxide layer that is in contact with the fourth insulating layer. It is thus possible to inhibit a reduction in the channel length of the transistor and a negative shift of the threshold voltage of the transistor. This can reduce a cutoff current, so that the transistor can have normally-off characteristics. Thus, the reliability of the transistor of one embodiment of the present invention can be increased, and the reliability of the semiconductor device of one embodiment of the present invention can be increased.

The base insulating layer and the fourth insulating layer each include a region where the hydrogen content is higher than or equal to the hydrogen content of the first insulating layer and higher than or equal to the hydrogen content of the third insulating layer, for example. In other words, the first insulating layer and the third insulating layer each include a region where the hydrogen content is lower than or equal to the hydrogen content of the base insulating layer and lower than or equal to the hydrogen content of the fourth insulating layer, for example. In the above manner, the channel length of the transistor can be inhibited from being reduced by hydrogen supply to the region in contact with the second insulating layer, for example, while the contact resistance between the metal oxide layer and each of the lower electrode and the upper electrode is reduced. Thus, the transistor of one embodiment of the present invention can have a high on-state current and high reliability. The semiconductor device of one embodiment of the present invention can operate at high speed and have high reliability.

For example, the base insulating layer and the fourth insulating layer can have substantially the same hydrogen content per unit volume. The fourth insulating layer can be formed using a material that can be used for the base insulating layer. Each of the base insulating layer and the fourth insulating layer can be formed using a nitride insulating film, for example. Examples of the nitride insulating film include silicon nitride and silicon nitride oxide. A silicon nitride film and a silicon nitride oxide film can each be a film that releases much hydrogen depending on the film formation conditions (e.g., a film formation gas or power at the time of film formation) and thus can be suitably used for the base insulating layer and the fourth insulating layer. Here, in the case where the base insulating layer and the fourth insulating layer include the same material and have substantially the same hydrogen content per unit volume, the base insulating layer and the fourth insulating layer can be formed under the same conditions.

When the expression “substantially the same” is used in this specification and the like, an error of ±40% is allowed.

### Structure Example 1 of Semiconductor Device

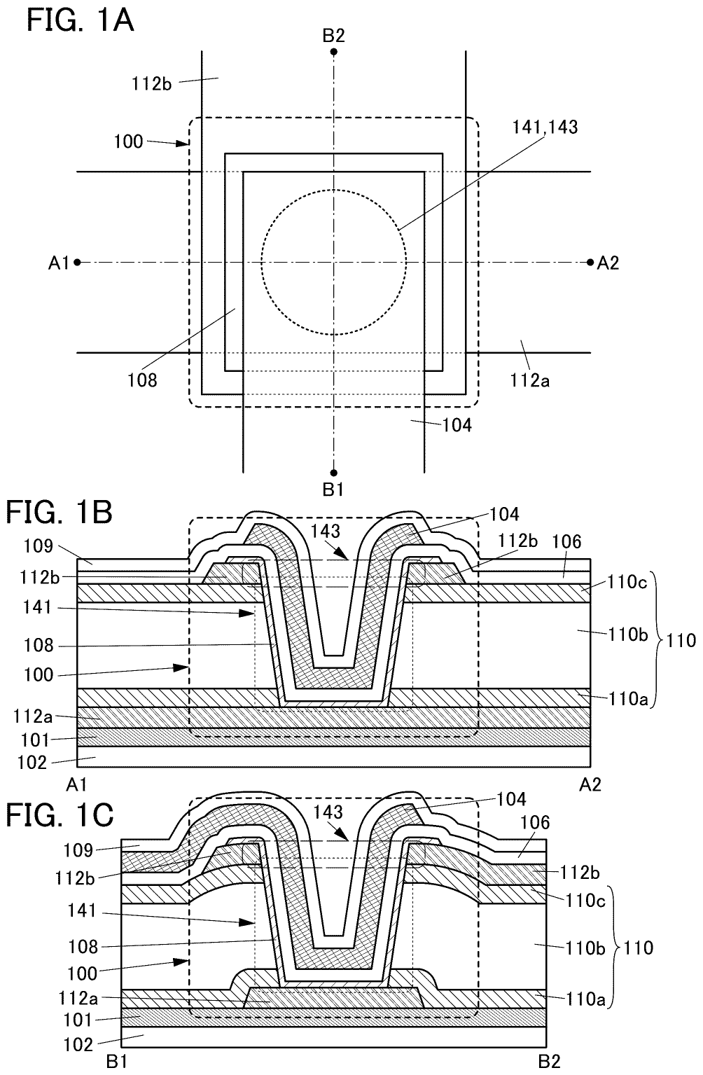

FIG. 1A is a plan view illustrating a structure example of the semiconductor device of one embodiment of the present invention, and illustrates a structure example of a transistor 100. Some components such as an insulating layer are omitted in FIG. 1A. Some components are omitted also in the following plan views.

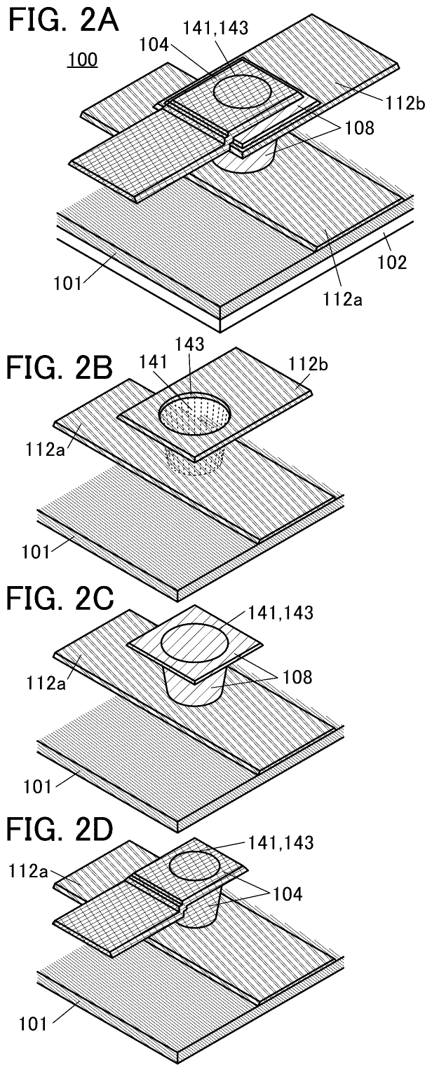

FIG. 1B is a cross-sectional view taken along dashed-dotted line A1-A2 in FIG. 1A, and FIG. 1C is a cross-sectional view taken along dashed-dotted line B1-B2 in FIG. 1A. FIG. 2A is a perspective view corresponding to the structure example in FIG. 1A to FIG. 1C. In the example illustrated in FIG. 2A, some components illustrated in FIG. 1A to FIG. 1C, such as some insulating layers, are omitted.

The semiconductor device of one embodiment of the present invention includes a substrate 102, an insulating layer 101 functioning as a base insulating layer over the substrate 102, an insulating layer 110 over the insulating layer 101, and the transistor 100. The transistor 100 includes a conductive layer 112a, a semiconductor layer 108, a conductive layer 112b, an insulating layer 106, and a conductive layer 104. The layers included in the transistor 100 may each have a single-layer structure or a stacked-layer structure.

The conductive layer 112a is provided over the insulating layer 101 to include a region in contact with the top surface of the insulating layer 101. The conductive layer 112a functions as one of a source electrode and a drain electrode of the transistor 100.

The insulating layer 110 is provided over the insulating layer 101 and the conductive layer 112a. The insulating layer 110 can include a region in contact with the top surface of the insulating layer 101, a region in contact with the top surface of the conductive layer 112a, and a region in contact with a side surface of the conductive layer 112a. The insulating layer 110 is provided with an opening 141 reaching the conductive layer 112a.

The conductive layer 112b is provided over the insulating layer 110. The conductive layer 112b can include a region in contact with the top surface of the insulating layer 110. The conductive layer 112b is provided with an opening 143 including a region overlapping with the opening 141. The conductive layer 112b functions as the other of the source electrode and the drain electrode of the transistor 100.

As described above, the conductive layer 112a is provided under the insulating layer 110, and the conductive layer 112b is provided over the insulating layer 110. Thus, the conductive layer 112a can be referred to as a lower electrode of the transistor 100, and the conductive layer 112b can be referred to as an upper electrode of the transistor 100. As described above, the conductive layer 112a functions as the one of the source electrode and the drain electrode of the transistor 100, and the conductive layer 112b functions as the other of the source electrode and the drain electrode of the transistor 100. Thus, in the transistor 100, the one of the source electrode and the drain electrode is the lower electrode, and the other of the source electrode and the drain electrode is the upper electrode. The insulating layer 110 has a function of a spacer for controlling the distance between the lower electrode and the upper electrode of the transistor 100.

The insulating layer 110 has a stacked-layer structure of an insulating layer 110a over the insulating layer 101 and the conductive layer 112a, an insulating layer 110b over the insulating layer 110a, and an insulating layer 110c over the insulating layer 110b. That is, the insulating layer 110 has a three-layer stacked structure in the example illustrated in FIG. 1B and FIG. 1C.

The insulating layer 110a can include a region in contact with the top surface of the insulating layer 101, a region in contact with the top surface of the conductive layer 112a, and a region in contact with the side surface of the conductive layer 112a. The insulating layer 110c can include a region in contact with the bottom surface of the conductive layer 112b. In other words, the conductive layer 112b can include a region in contact with the top surface of the insulating layer 110c.

FIG. 2B is a diagram selectively illustrating the insulating layer 101, the conductive layer 112a, the conductive layer 112b, the opening 141, and the opening 143 from the perspective view in FIG. 2A. The opening 141 provided in the insulating layer 110 is indicated by dashed lines. As illustrated in FIG. 2B, the conductive layer 112b is provided with the opening 143 in a region overlapping with the conductive layer 112a. It is preferable that the conductive layer 112b not be provided in the opening 141. In other words, it is preferable that the conductive layer 112b not include a region that is in contact with a side surface of the insulating layer 110 on the opening 141 side.

The semiconductor layer 108 includes a region positioned in the opening 141 and a region positioned in the opening 143. The semiconductor layer 108 includes a region in contact with the top surface of the conductive layer 112a, a region in contact with the side surface of the insulating layer 110, a region in contact with the top surface of the conductive layer 112b, and a region in contact with a side surface of the conductive layer 112b. The semiconductor layer 108 includes a region in contact with an end portion of the insulating layer 110 on the opening 141 side (which can be regarded as a side wall of the opening 141) and an end portion of the conductive layer 112b on the opening 143 side (which can be regarded as a side wall of the opening 143). The semiconductor layer 108 includes a region in contact with the top surface of the conductive layer 112a in the opening 141.

In the above manner, the semiconductor layer 108 is provided over the conductive layer 112a and the conductive layer 112b. As described above, the conductive layer 112a is provided over the insulating layer 101. Thus, the conductive layer 112a is provided between the insulating layer 101 and the semiconductor layer 108. Here, in the semiconductor device of one embodiment of the present invention, the insulating layer 101 includes hydrogen. Specifically, the insulating layer 101 includes a region where the hydrogen content per unit volume is higher than or equal to the hydrogen content per unit volume of the insulating layer 110. The semiconductor layer 108 includes a material that has reduced resistance when supplied with hydrogen. For example, the semiconductor layer 108 includes an oxide semiconductor, which is a metal oxide exhibiting semiconductor characteristics. In this case, the semiconductor layer 108 is also referred to as a metal oxide layer or an oxide semiconductor layer.

Examples of a metal oxide that can be used for the semiconductor layer 108 include an oxide containing indium, an oxide containing gallium, and an oxide containing zinc. Examples of a metal oxide that can be used for the semiconductor layer 108 include indium oxide, indium zinc oxide, and indium gallium zinc oxide. Note that the insulating layer 101 does not necessarily include hydrogen as long as it includes a material that reduces the resistance of the semiconductor layer 108 when supplied to the semiconductor layer 108.

When the insulating layer 101 includes hydrogen, the hydrogen included in the insulating layer 101 is transmitted through the conductive layer 112a and is supplied to the region of the semiconductor layer 108 that is in contact with the conductive layer 112a and a region in the vicinity thereof. As described above, the semiconductor layer 108 includes a material that has reduced resistance when supplied with hydrogen. Thus, the hydrogen supply to the region of the semiconductor layer 108 that is in contact with the conductive layer 112a can reduce the contact resistance between the semiconductor layer 108 and the conductive layer 112a. Accordingly, the transistor 100 can have a higher on-state current and favorable electrical characteristics. This allows the semiconductor device to operate at high speed.

The contents of hydrogen, oxygen, nitrogen, and any other element can be measured by secondary ion mass spectrometry (SIMS) or X-ray photoelectron spectroscopy (XPS), for example. When the content percentage of a target element is high (e.g., higher than or equal to 0.5 atomic %, or higher than or equal to 1 atomic %), XPS is suitable. By contrast, when the content percentage of a target element is low (e.g., lower than or equal to 0.5 atomic %, or lower than or equal to 1 atomic %), SIMS is suitable. To compare the contents of elements, analysis with a combination of SIMS and XPS is preferably performed. A hydrogen content is preferably measured by SIMS, in which case the hydrogen content can be measured with high sensitivity. Measuring the released amount of the element by thermal desorption spectroscopy (TDS) enables comparing the content of the element in two layers, for example.

FIG. 2C is a diagram selectively illustrating the insulating layer 101, the conductive layer 112a, the semiconductor layer 108, the opening 141, and the opening 143 from the perspective view in FIG. 2A. As illustrated in FIG. 2C, the semiconductor layer 108 is provided to cover the opening 141 and the opening 143.

Although an end portion of the semiconductor layer 108 is provided on the top surface of the conductive layer 112b in the example illustrated in FIG. 1B and FIG. 1C, the semiconductor layer 108 may cover an end portion of the conductive layer 112b, and the end portion of the semiconductor layer 108 may be provided over the insulating layer 110, for example.

The insulating layer 106 is provided over the insulating layer 110, the semiconductor layer 108, and the conductive layer 112b. The insulating layer 106 is provided over the semiconductor layer 108 to include a region positioned in the opening 141 and a region positioned in the opening 143. The insulating layer 106 is provided along the side wall of the opening 141 and the side wall of the opening 143 with the semiconductor layer 108 between the insulating layer 106 and the side walls. The insulating layer 106 functions as a gate insulating layer of the transistor.

The conductive layer 104 is provided over the insulating layer 106. The conductive layer 104 is provided to include a region positioned in the opening 141 and a region facing the semiconductor layer 108 with the insulating layer 106 between the region and the semiconductor layer 108 in the opening 143. In other words, the conductive layer 104 is provided to include a region overlapping with the semiconductor layer 108 with the insulating layer 106 therebetween in the opening 141 and the opening 143. The conductive layer 104 functions as a gate electrode of the transistor 100.

FIG. 2D is a diagram selectively illustrating the insulating layer 101, the conductive layer 112a, the conductive layer 104, the opening 141, and the opening 143 from the perspective view in FIG. 2A. As illustrated in FIG. 2D, the conductive layer 104 is provided to cover the opening 141 and the opening 143.

The conductive layer 112a, the conductive layer 112b, and the conductive layer 104 can function as wirings, and the transistor 100 can be provided in the region where these wirings overlap with each other. That is, the areas occupied by the transistor 100 and the wirings can be reduced in a circuit including the transistor 100 and the wirings. Accordingly, the area occupied by the circuit can be reduced, which makes it possible to provide a small semiconductor device.

An insulating layer 109 is provided over the conductive layer 104 and the insulating layer 106. The insulating layer 109 is provided to cover the conductive layer 104.

The insulating layer 109 functions as a protective layer. The insulating layer 109 is preferably formed using a material that does not easily allow diffusion of impurities. Providing the insulating layer 109 can favorably inhibit diffusion of impurities to the transistor 100 from the outside and increase the reliability of the semiconductor device. Examples of the impurities include water and hydrogen. The insulating layer 109 includes, for example, one or both of an inorganic insulating film and an organic insulating film. The insulating layer 109 may have a stacked-layer structure of an inorganic insulating film and an organic insulating film.

In the case where the insulating layer 109 is formed using an inorganic insulating film, the insulating layer 109 can be formed using a material that can be used for the insulating layer 110. Examples of the inorganic insulating film usable for the insulating layer 109 include an oxide insulating film and a nitride insulating film. Specifically, the insulating layer 109 can be formed using one or more of silicon nitride, silicon nitride oxide, silicon oxynitride, aluminum oxide, aluminum oxynitride, aluminum nitride, hafnium oxide, and hafnium aluminate. In the case where the insulating layer 109 is formed using an organic insulating film, one or both of an acrylic resin and a polyimide resin can be used, for example.

When the semiconductor device of one embodiment of the present invention is used for a pixel circuit of a display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel, for example.

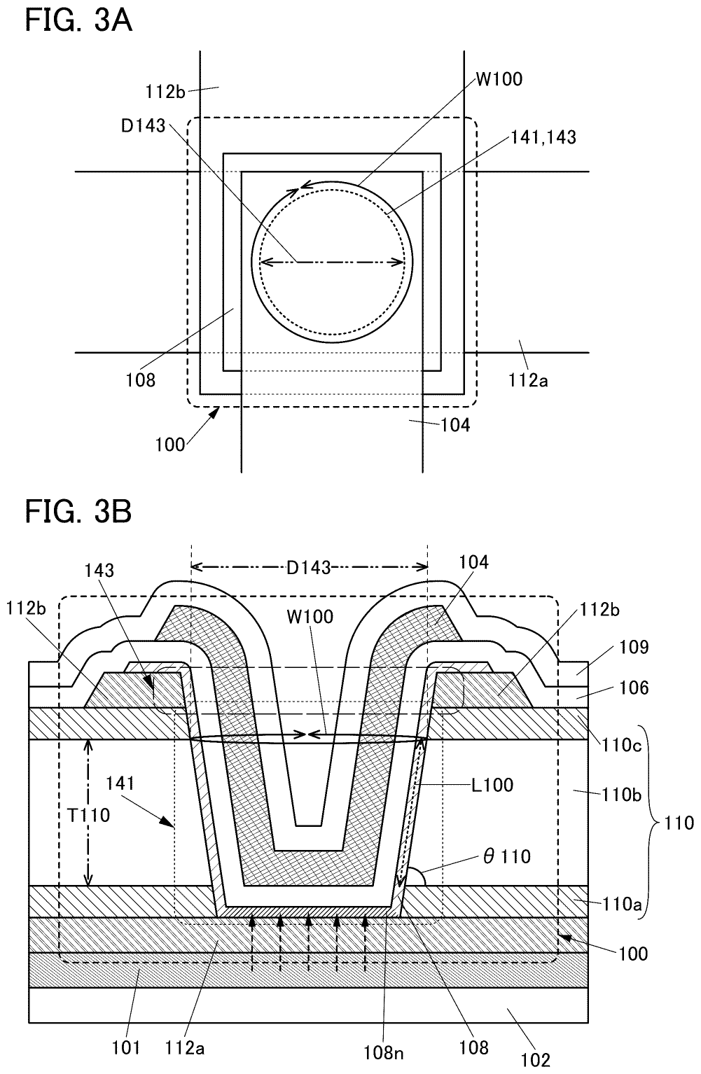

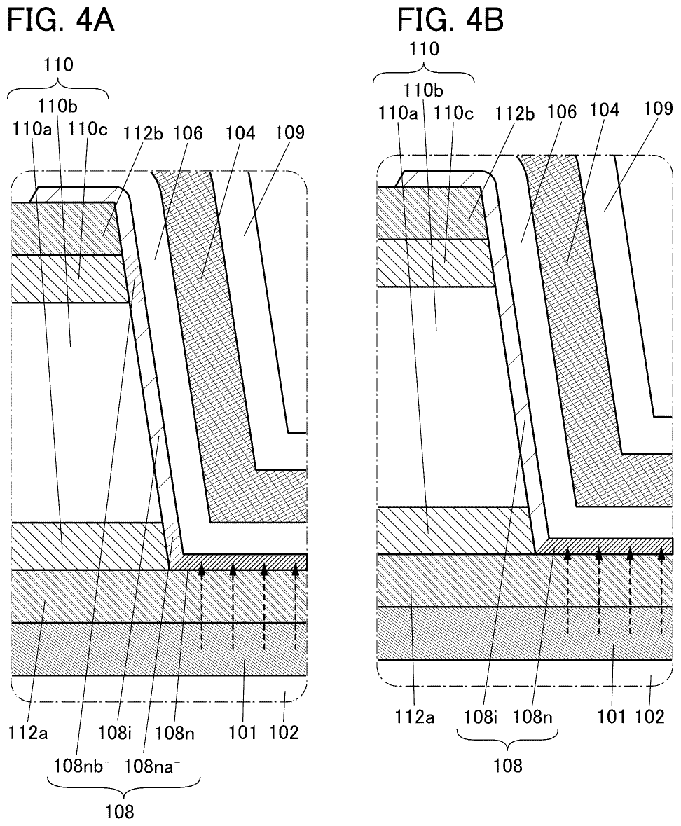

FIG. 3A is a plan view illustrating the structure example of the semiconductor device of one embodiment of the present invention, and illustrates the structure example of the transistor 100. FIG. 3A is the plan view of FIG. 1A where a diameter D143 and a channel width W100 are shown. FIG. 3B is an enlarged view including the structure illustrated in FIG. 1B and illustrates the structure example of the transistor 100. In FIG. 3B, the diameter D143, the channel width W100, a channel length L100, a thickness T110, and an angle θ110 are shown. FIG. 4A is an enlarged view of the semiconductor layer 108 illustrated in FIG. 3B and a region in the vicinity thereof.

In the semiconductor layer 108, the region in contact with the conductive layer 112a functions as one of a source region and a drain region, and the region in contact with the conductive layer 112b functions as the other of the source region and the drain region. The semiconductor layer 108 includes a channel formation region between the source region and the drain region.

Here, high contact resistance between the conductive layer 112a and the semiconductor layer 108 may lead to high electrical resistance of the one of the source region and the drain region of the semiconductor layer 108 and a low on-state current of the transistor. Thus, in the semiconductor device of one embodiment of the present invention, the insulating layer 101 is an insulating layer including hydrogen and the semiconductor layer 108 is a layer including a material that has reduced resistance when supplied with hydrogen, as described above. In the case where the semiconductor layer 108 is a metal oxide layer, for example, reaction between oxygen bonded to a metal atom included in the semiconductor layer 108 and hydrogen generates water, and thus forms an oxygen vacancy (Vo) in the metal oxide. A defect that is an oxygen vacancy into which hydrogen enters (VoH) functions as a donor and generates an electron serving as a carrier. In some cases, bonding of part of hydrogen to oxygen bonded to a metal atom generates electrons serving as carriers. Generation of electrons serving as carriers in the semiconductor layer 108 reduces the resistance of the semiconductor layer 108. Note that as described above, the insulating layer 101 does not necessarily include hydrogen as long as it includes a material that reduces the resistance of the semiconductor layer 108 when supplied to the semiconductor layer 108.

In FIG. 3B and FIG. 4A, an example of a state where hydrogen included in the insulating layer 101 is supplied to the semiconductor layer 108 is indicated by dashed single-headed arrows. As illustrated in FIG. 3B and FIG. 4A, hydrogen included in the insulating layer 101 is transmitted through the conductive layer 112a and is supplied to the region of the semiconductor layer 108 that is in contact with the conductive layer 112a and a region in the vicinity thereof. Thus, the region of the semiconductor layer 108 that is in contact with the conductive layer 112a and a region in the vicinity thereof become a low-resistance region. The low-resistance region is referred to as a region 108n. The region 108n functions as the source region or the drain region of the transistor 100.

When the region 108n, which is a low-resistance region, is formed in the region of the semiconductor layer 108 that is in contact with the conductive layer 112a, the contact resistance between the semiconductor layer 108 and the conductive layer 112a can be reduced. Accordingly, the transistor 100 can have a higher on-state current and favorable electrical characteristics. This allows the semiconductor device to operate at high speed.

The insulating layer 101 can be formed using a material that can be used for the insulating layer 110. The insulating layer 101 can be formed using one or both of a nitride insulating film and an oxide insulating film, for example. Examples of the nitride insulating film include a silicon nitride film, a silicon nitride oxide film, and an aluminum nitride film. Examples of the oxide insulating film include a silicon oxynitride film, a silicon oxide film, an aluminum oxynitride film, an aluminum oxide film, a hafnium oxide film, and a hafnium aluminate film. In particular, the insulating layer 101 is preferably formed using one or both of a silicon nitride film and a silicon nitride oxide film, in which case the insulating layer 101 can be a film that releases much hydrogen depending on the film formation conditions (e.g., a film formation gas or power at the time of film formation).

The insulating layer 101 preferably releases hydrogen when heated. When the insulating layer 101 releases hydrogen by being heated during the manufacturing process of the transistor 100, the hydrogen can be favorably supplied to the semiconductor layer 108.

The thickness of the insulating layer 101 is preferably greater than or equal to 1 nm and less than or equal to 500 nm, further preferably greater than or equal to 5 nm and less than or equal to 500 nm, still further preferably greater than or equal to 5 nm and less than or equal to 200 nm, yet still further preferably greater than or equal to 10 nm and less than or equal to 200 nm, yet still further preferably greater than or equal to 30 nm and less than or equal to 200 nm, yet still further preferably greater than or equal to 50 nm and less than or equal to 200 nm. When the thickness of the insulating layer 101 is large, the hydrogen content of the insulating layer 101 can be high, so that hydrogen can be favorably supplied to the semiconductor layer 108. Meanwhile, when the thickness of the insulating layer 101 is too large, the productivity of the semiconductor device of one embodiment of the present invention decreases; thus, the thickness is preferably set in consideration of the productivity.

The insulating layer 110 is preferably formed using an inorganic insulating film. Examples of the inorganic insulating film include an oxide insulating film and a nitride insulating film. Examples of the oxide insulating film include a silicon oxide film, a silicon oxynitride film, an aluminum oxide film, an aluminum oxynitride film, a magnesium oxide film, a gallium oxide film, a gallium oxynitride film, a germanium oxide film, an yttrium oxide film, an yttrium oxynitride film, a zirconium oxide film, a lanthanum oxide film, a neodymium oxide film, a hafnium oxide film, a hafnium oxynitride film, a tantalum oxide film, a cerium oxide film, a gallium zinc oxide film, and a hafnium aluminate film. Examples of the nitride insulating film include a silicon nitride film, a silicon nitride oxide film, an aluminum nitride film, and an aluminum nitride oxide film.

The insulating layer 110 includes a region in contact with the semiconductor layer 108. In the case where the semiconductor layer 108 is a metal oxide layer, at least part of the portion of the insulating layer 110 that is in contact with the semiconductor layer 108 is preferably formed using an oxide to improve the characteristics of the interface between the semiconductor layer 108 and the insulating layer 110. Specifically, the portion of the insulating layer 110 that is in contact with the channel formation region of the semiconductor layer 108 is preferably formed using an oxide. The channel formation region is a high-resistance region having a low carrier concentration. The channel formation region can be regarded as an i-type (intrinsic) or substantially i-type region.

As the insulating layer 110b, which includes a region in contact with the channel formation region of the semiconductor layer 108, a layer including oxygen is preferably used. It is preferable that the insulating layer 110b include a region having a higher oxygen content than one or both of the insulating layer 110a and the insulating layer 110c. In that case, oxygen can be supplied to the region of the semiconductor layer 108 that is in contact with neither the conductive layer 112a nor the conductive layer 112b. For example, oxygen can be supplied to the region of the semiconductor layer 108 that is in contact with the insulating layer 110b and a region in the vicinity thereof. Accordingly, oxygen can be supplied to the channel formation region of the semiconductor layer 108. This facilitates a reduction in oxygen vacancies in the semiconductor layer 108 and formation of an i-type channel formation region. As a result, the transistor 100 can have favorable electrical characteristics and increased reliability. Thus, the semiconductor device of one embodiment of the present invention can have increased reliability. Note that the oxygen content can be measured by a method similar to that for measuring the hydrogen content.

The insulating layer 110b is further preferably formed using a film that releases oxygen when heated. When the insulating layer 110b releases oxygen by being heated during the manufacturing process of the transistor 100, the oxygen can be supplied to the semiconductor layer 108. The oxygen supply from the insulating layer 110b to the semiconductor layer 108, particularly to the channel formation region of the semiconductor layer 108, reduces the amount of oxygen vacancies in the semiconductor layer 108, so that the transistor can have favorable electrical characteristics and high reliability.

For example, the insulating layer 110b can be supplied with oxygen when heat treatment in an oxygen-containing atmosphere or plasma treatment in an oxygen-containing atmosphere is performed. Alternatively, an oxide film may be formed over the top surface of the insulating layer 110b by a sputtering method in an oxygen atmosphere to supply oxygen. After that, the oxide film may be removed.

The insulating layer 110b is preferably formed by a film formation method such as a sputtering method or a plasma-enhanced chemical vapor deposition (PECVD) method. In particular, by a sputtering method as a film formation method that does not use a hydrogen gas as a film formation gas, a film having an extremely low hydrogen content can be formed. In that case, supply of hydrogen to the channel formation region of the semiconductor layer 108 is inhibited and the electrical characteristics of the transistor 100 can be stabilized.

The insulating layer 110b is preferably formed using any one or more of the oxide insulating films described above. Specifically, the insulating layer 110b is preferably formed using one or both of a silicon oxide film and a silicon oxynitride film.

Each of the insulating layer 110a and the insulating layer 110c can be formed using a material that does not easily allow diffusion of hydrogen. In that case, hydrogen can be inhibited from being diffused from outside the transistor to the semiconductor layer 108 through the insulating layer 110a or the insulating layer 110c. In particular, when the insulating layer 110a is formed using a material that does not easily allow diffusion of hydrogen, hydrogen included in the insulating layer 101 can be inhibited from being supplied to, for example, the region of the semiconductor layer 108 that is away from a region where the conductive layer 112a and the semiconductor layer 108 are in contact with each other. For example, hydrogen included in the insulating layer 101 can be inhibited from being supplied to the region of the semiconductor layer 108 that is in contact with the insulating layer 110a. It is thus possible to inhibit a reduction in the channel length of the transistor 100 and a reduction in the threshold voltage of the transistor 100, that is, a negative shift of the threshold voltage. This can reduce a cutoff current, so that the transistor can have normally-off characteristics. Thus, the reliability of the transistor 100 can be increased, and the reliability of the semiconductor device of one embodiment of the present invention can be increased.

The insulating layer 110a can be formed using, for example, a material that is less likely to allow diffusion of hydrogen than the conductive layer 112a or a material that is less likely to allow diffusion of hydrogen than the insulating layer 110b. The insulating layer 110a can be formed using, for example, a material having a lower hydrogen diffusion coefficient than the conductive layer 112a or a material having a lower hydrogen diffusion coefficient than the insulating layer 110b. The insulating layer 110c can be formed using, for example, a material that is less likely to allow diffusion of hydrogen than the conductive layer 112b or a material that is less likely to allow diffusion of hydrogen than the insulating layer 110b. The insulating layer 110c can be formed using, for example, a material having a lower hydrogen diffusion coefficient than the conductive layer 112b or a material having a lower hydrogen diffusion coefficient than the insulating layer 110b. The hydrogen diffusion coefficient in the insulating layer 110c can be substantially the same as the hydrogen diffusion coefficient in the insulating layer 110a.

The insulating layer 110c can include a material that is the same as the material included in the insulating layer 110a. For example, the insulating layer 110c can be formed using the same material as the insulating layer 110a. In that case, the insulating layer 110a and the insulating layer 110c can be formed under the same conditions. Note that when the film formation time of the insulating layer 110a and the film formation time of the insulating layer 110c are made different from each other, for example, the thickness of the insulating layer 110a and the thickness of the insulating layer 110c can be made different from each other.

The insulating layer 110a and the insulating layer 110c can be formed using a material that does not easily allow diffusion of oxygen as well as hydrogen. The insulating layer 110a and the insulating layer 110c can be formed using, for example, a material that is less likely to allow diffusion of oxygen than the insulating layer 110b. The insulating layer 110a and the insulating layer 110c can be formed using, for example, a material having a lower oxygen diffusion coefficient than the insulating layer 110b. In that case, it is possible to prevent oxygen included in the insulating layer 110b from being transmitted toward the substrate 102 side through the insulating layer 110a and being transmitted toward the conductive layer 112b side and the insulating layer 106 side through the insulating layer 110c due to heating. In other words, when the insulating layer 110a and the insulating layer 110c that do not easily allow diffusion of oxygen are provided below and above the insulating layer 110b such that the insulating layer 110b is sandwiched therebetween, oxygen can be enclosed in the insulating layer 110b. Accordingly, oxygen can be favorably supplied to the semiconductor layer 108.

For calculation of the diffusion coefficients of hydrogen, oxygen, and the like, TDS can be used, for example. Alternatively, SIMS may be used.

It is preferable that the insulating layer 110a and the insulating layer 110c be each formed using any one or more of the oxide insulating films and nitride insulating films described above. Specifically, it is preferable to use one or more of a silicon nitride film, a silicon nitride oxide film, a silicon oxynitride film, an aluminum oxide film, an aluminum oxynitride film, an aluminum nitride film, a hafnium oxide film, and a hafnium aluminate film.

It is preferable that the insulating layer 110a and the insulating layer 110c be each formed using any one or more of the nitride insulating films described above. Specifically, it is preferable that the insulating layer 110a and the insulating layer 110c be each formed using one or both of a silicon nitride film and a silicon nitride oxide film.

A silicon nitride film and a silicon nitride oxide film release fewer impurities (e.g., water and hydrogen), are less likely to transmit oxygen and hydrogen, and thus can be suitably used for each of the insulating layer 110a and the insulating layer 110c.

The insulating layer 110a and the insulating layer 110c may be formed using any of the above-described aluminum-containing films, for example. The insulating layer 110a and the insulating layer 110c are each preferably formed using, for example, an aluminum oxide film. An aluminum oxide film is suitable because it can have a lower hydrogen content than a silicon nitride film.

The conductive layer 112a and the conductive layer 112b are oxidized by oxygen included in the insulating layer 110b and have high electrical resistance in some cases. Providing the insulating layer 110a between the insulating layer 110b and the conductive layer 112a can inhibit the conductive layer 112a from being oxidized and having high resistance. In a similar manner, providing the insulating layer 110c between the insulating layer 110b and the conductive layer 112b can inhibit the conductive layer 112b from being oxidized and having high resistance. Accordingly, the amount of oxygen supplied from the insulating layer 110b to the semiconductor layer 108 is increased, whereby the amount of oxygen vacancies in the semiconductor layer 108 can be reduced.

The thickness of each of the insulating layer 110a and the insulating layer 110c is preferably greater than or equal to 5 nm and less than or equal to 150 nm, further preferably greater than or equal to 5 nm and less than or equal to 100 nm, still further preferably greater than or equal to 5 nm and less than or equal to 70 nm, yet still further preferably greater than or equal to 10 nm and less than or equal to 70 nm, yet still further preferably greater than or equal to 10 nm and less than or equal to 50 nm, yet still further preferably greater than or equal to 20 nm and less than or equal to 50 nm. When the thickness of each of the insulating layer 110a and the insulating layer 110c is in the above-described range, the amount of oxygen vacancies in the semiconductor layer 108, or specifically the channel formation region, can be reduced. Note that the insulating layer 110a and the insulating layer 110c may have the same thickness or different thicknesses.

It is preferable that, for example, the insulating layer 110a and the insulating layer 110c be formed using silicon nitride films or silicon nitride oxide films and the insulating layer 110b be formed using a silicon oxide film or a silicon oxynitride film.

Here, the insulating layer 110a may include hydrogen depending on the film formation conditions. For example, the insulating layer 110a may include hydrogen in the case where a nitride insulating film is formed for the insulating layer 110a by a CVD method and ammonia (NH₃) is used as a nitrogen source. In that case, hydrogen may be supplied to the region of the semiconductor layer 108 that is in contact with the insulating layer 110a and a region in the vicinity thereof to reduce the resistance of these regions. In FIG. 4A, such a low-resistance region is a region 108na⁻. Similarly, the insulating layer 110c may include hydrogen depending on the film formation conditions, and hydrogen may be supplied to the region of the semiconductor layer 108 that is in contact with the insulating layer 110c and a region in the vicinity thereof to reduce the resistance of these regions. In FIG. 4A, such a low-resistance region is a region 108nb⁻. The region 108na⁻ functions as the one of the source region and the drain region of the transistor 100, and the region 108nb⁻ functions as the other of the source region and the drain region of the transistor 100. Here, in FIG. 4A, the region of the semiconductor layer 108 that functions as the channel formation region of the transistor 100 is referred to as a region 108i. The region 108i can be an i-type region.

Note that in the case where oxygen contained in the insulating layer 110b is diffused to the region of the semiconductor layer 108 that is in contact with the insulating layer 110a and a region in the vicinity thereof, for example, some regions being close to the insulating layer 110b and being included in the region of the semiconductor layer 108 that is in contact with the insulating layer 110a and a region in the vicinity thereof do not have reduced resistance and become the region 108i in some cases. Likewise, in the case where oxygen contained in the insulating layer 110b is diffused to the region of the semiconductor layer 108 that is in contact with the insulating layer 110c and a region in the vicinity thereof, for example, some regions being close to the insulating layer 110b and being included in the region of the semiconductor layer 108 that is in contact with the insulating layer 110c and a region in the vicinity thereof do not have reduced resistance and become the region 108i in some cases. When the insulating layer 110a and the insulating layer 110c do not include hydrogen, for example, the region 108na⁻ and the region 108nb⁻ are not formed in the semiconductor layer 108 as illustrated in FIG. 4B, in some cases.

The insulating layer 101 includes a region where the hydrogen content is higher than or equal to the hydrogen content of the insulating layer 110a, for example. In other words, the insulating layer 110a includes a region where the hydrogen content is lower than or equal to the hydrogen content of the insulating layer 101, for example. In this case, the region 108na and the region 108nb⁻ illustrated in FIG. 4A can have lower electrical resistance than the region 108i and higher electrical resistance than the region 108n.

In the above manner, the channel length of the transistor 100 can be inhibited from being reduced by hydrogen supply to the region of the semiconductor layer 108 that is in contact with the insulating layer 110b, for example, while the contact resistance between the semiconductor layer 108 and the conductive layer 112a is reduced. Thus, the transistor 100 can have a high on-state current and high reliability. The semiconductor device of one embodiment of the present invention can operate at high speed and have high reliability.

The channel length, the channel width, and the like of the transistor 100 will be described below.

In FIG. 3B, the channel length L100 of the transistor 100 is indicated by a dashed double-headed arrow. In the example illustrated in FIG. 3B, the region of the semiconductor layer 108 that is in contact with the insulating layer 110b and a region in the vicinity thereof become an i-type region and function as the channel formation region. The region of the semiconductor layer 108 that is in contact with the insulating layer 110a, a region in the vicinity thereof, the region of the semiconductor layer 108 that is in contact with the insulating layer 110c, and a region in the vicinity thereof are low-resistance regions as illustrated in FIG. 4A. Here, in a cross-sectional view, the channel length L100 can be the shortest distance between the portion of the semiconductor layer 108 that is in contact with the insulating layer 110a and the portion of the semiconductor layer 108 that is in contact with the insulating layer 110c.

The channel length L100 of the transistor 100 corresponds to the length of a side surface of the insulating layer 110b on the opening 141 side in a cross-sectional view. In other words, the channel length L100 depends on the thickness T110 of the insulating layer 110b and the angle θ110 formed by the side surface of the insulating layer 110b on the opening 141 side and the formation surface of the insulating layer 110b (which is the top surface of the insulating layer 110a here). Thus, the channel length L100 can have a value smaller than that of the definition limit of a light-exposure apparatus, for example, which enables the transistor to have a minute size. Specifically, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, it is also possible to obtain a transistor with a channel length shorter than 10 nm without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

When the channel length L100 is small, the transistor 100 can have a high on-state current. With the use of the transistor 100, a circuit capable of high-speed operation can be manufactured. Thus, the use of the semiconductor device of one embodiment of the present invention for a display device can increase the frame frequency of the display device.

Furthermore, the use of the transistor 100 can reduce the area occupied by the circuit. Therefore, a semiconductor device with a small size can be obtained. The application of the semiconductor device of one embodiment of the present invention to a large-sized display device or a high-definition display device would reduce signal delay in wirings and reduce display unevenness if the number of wirings is increased, for example. In addition, since the area occupied by the circuit can be reduced, the bezel of the display device can be narrowed.

By adjusting the thickness T110 of the insulating layer 110b and the angle θ110, the channel length L100 can be controlled. Note that in FIG. 3B, the thickness T110 of the insulating layer 110b is indicated by the dashed-dotted double-headed arrow.

The thickness T110 of the insulating layer 110b can be, for example, greater than or equal to 10 nm, greater than or equal to 50 nm, greater than or equal to 100 nm, greater than or equal to 150 nm, greater than or equal to 200 nm, greater than or equal to 300 nm, greater than or equal to 400 nm, or greater than or equal to 500 nm and less than 3.0 μm, less than or equal to 2.5 μm, less than or equal to 2.0 μm, less than or equal to 1.5 μm, less than or equal to 1.2 μm, or less than or equal to 1.0 μm.

The region of the semiconductor layer 108 that is in contact with the insulating layer 110a, a region in the vicinity thereof, the region of the semiconductor layer 108 that is in contact with the insulating layer 110c, and a region in the vicinity thereof may be included in the channel formation region. For example, in the case where these regions are i-type regions as illustrated in FIG. 4B, these regions can be included in the channel formation region. Here, in a cross-sectional view, the channel length L100 can be the shortest distance between the portion of the semiconductor layer 108 that is in contact with the conductive layer 112a and the portion of the semiconductor layer 108 that is in contact with the conductive layer 112b. The channel length L100 corresponds to the sum of the lengths of side surfaces of the insulating layer 110a, the insulating layer 110b, and the insulating layer 110c on the opening 141 side in a cross-sectional view.

In FIG. 3A and FIG. 3B, the diameter D143 of the opening 143 is indicated by the dashed-two dotted double-headed arrow. In the example illustrated in FIG. 3A, the top-view shape of each of the opening 141 and the opening 143 is a circle having the diameter D143. Here, the channel width W100 of the transistor 100 is equal to the length of the circumference of this circle. That is, the channel width W100 isπ×D143. In the case where the opening 141 and the opening 143 have circular top-view shapes as described above, the channel width of the transistor can be smaller than in the case where the opening 141 and the opening 143 have any other shape.

The diameter of the opening 141 and the diameter of the opening 143 are sometimes different from each other. Each of the diameter of the opening 141 and the diameter of the opening 143 varies from position to position in the depth direction in some cases. The average value of the following three diameters can be used as the diameter of the opening, for example: the diameter at the highest level of the insulating layer 110 (or the insulating layer 110b) in a cross-sectional view, the diameter at the lowest level of the insulating layer 110 (or the insulating layer 110b) in a cross-sectional view, and the diameter at the midpoint between these levels. For another example, any of the diameter at the highest level of the insulating layer 110 (or the insulating layer 110b) in a cross-sectional view, the diameter at the lowest level of the insulating layer 110 (or the insulating layer 110b) in a cross-sectional view, and the diameter at the midpoint between these levels can be used as the diameter of the opening.

In the case where the opening 143 is formed by a photolithography method and an etching method, the diameter D143 of the opening 143 is larger than or equal to the definition limit of a light-exposure apparatus. The diameter D143 can be, for example, greater than or equal to 20 nm, greater than or equal to 50 nm, greater than or equal to 100 nm, greater than or equal to 200 nm, greater than or equal to 300 nm, greater than or equal to 400 nm, or greater than or equal to 500 nm and less than 5.0 μm, less than or equal to 4.5 μm, less than or equal to 4.0 μm, less than or equal to 3.5 μm, less than or equal to 3.0 μm, less than or equal to 2.5 μm, less than or equal to 2.0 μm, less than or equal to 1.5 μm, or less than or equal to 1.0 μm.

There is no limitation on the top-view shapes of the opening 141 and the opening 143, and the top-view shapes can each be a circle, an ellipse, a polygon such as a triangle, a quadrangle (including a rectangle, a rhombus, and a square), a pentagon, or a star polygon, or any of these polygons whose corners are rounded, for example. Note that the polygon may be a concave polygon (a polygon at least one of the interior angles of which is greater than 180°) or a convex polygon (a polygon all the interior angles of which are less than or equal to) 180°. For example, the top-view shapes of the opening 141 and the opening 143 are preferably circles as illustrated in FIG. 3A. When the top-view shapes of the openings are circles, processing accuracy at the time of formation of the openings can be high, whereby the openings can be formed to have minute sizes. Note that in this specification and the like, a circle is not necessarily a perfect circle.

In this specification and the like, the top-view shape of the opening 141 refers to the shape of an end portion of the top surface of the insulating layer 110 on the opening 141 side. The top-view shape of the opening 143 refers to the shape of an end portion of the bottom surface of the conductive layer 112b on the opening 143 side.

As illustrated in FIG. 3A, the opening 141 and the opening 143 can have the same top-view shape or substantially the same top-view shapes, for example. In that case, it is preferable that the end portion of the bottom surface of the conductive layer 112b on the opening 143 side be aligned with or substantially aligned with the end portion of the top surface of the insulating layer 110 on the opening 141 side as illustrated in FIG. 3B, for example. The bottom surface of the conductive layer 112b refers to the surface thereof on the insulating layer 110 side. The top surface of the insulating layer 110 refers to the surface thereof on the conductive layer 112b side.

Note that the opening 141 and the opening 143 do not necessarily have the same top-view shape. In the case where the opening 141 and the opening 143 have circular top-view shapes, the opening 141 and the opening 143 may be, but not necessarily, concentrically arranged.

The side surface of the insulating layer 110b on the opening 141 side preferably has a tapered shape or a vertical shape. The angle θ110 between the side surface of the insulating layer 110b on the opening 141 side and the formation surface of the insulating layer 110b (which is the top surface of the insulating layer 110a here) is preferably less than or equal to 90°. When the angle θ110 is small, the coverage with the layer provided over the insulating layer 110b (e.g., the semiconductor layer 108) can be increased. The smaller the angle θ110 is, the larger the channel length L100 is. The larger the angle θ110 is, the smaller the channel length L100 is. In the example illustrated in FIG. 1B, FIG. 1C, and FIG. 3B, the side surface of the insulating layer 110b on the opening 141 side has a tapered shape (the angle θ110 is less than) 90°.

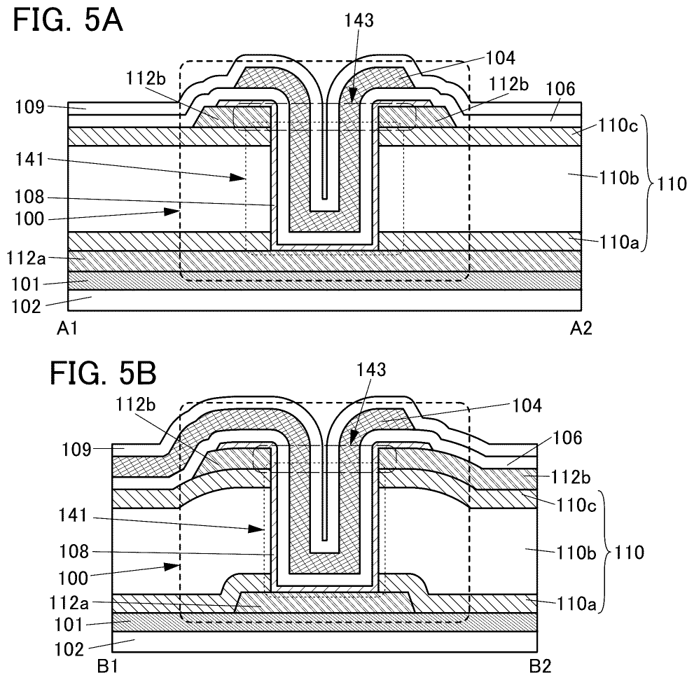

FIG. 5A and FIG. 5B illustrate an example in which the side surface of the insulating layer 110b on the opening 141 side illustrated in FIG. 1B and FIG. 1C has a vertical shape (the angle θ110 is) 90°.

The angle θ110 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than or equal to 90°, less than or equal to 85°, or less than or equal to 80°. The angle θ110 may be less than or equal to 75°, less than or equal to 70°, less than or equal to 65°, or less than or equal to 60°.

In the case where the angle θ110 is greater than or equal to 80° and less than or equal to 90°, the film to cover the insulating layer 110 is preferably formed by a film formation method that enables favorable coverage. For example, it is preferable that the conductive layer 104 be formed by a CVD method and the insulating layer 106 and the semiconductor layer 108 be formed by an ALD method. For another example, it is preferable that the conductive layer 104, the insulating layer 106, and the semiconductor layer 108 be formed by an ALD method. In the case where the angle θ110 is greater than or equal to 60° and less than or equal to 85°, the film to cover the insulating layer 110 may be formed by a film formation method with higher productivity. For example, it is preferable that the semiconductor layer 108 be formed by a sputtering method.

The angle θ110 is defined with reference to the insulating layer 110b here but may be defined with reference to the whole insulating layer 110. In other words, the angle θ110 may be the angle between the side surface of the insulating layer 110 on the opening 141 side and the formation surface of the insulating layer 110 (which is the top surface of the conductive layer 112a here).

### Structure Example 2 of Semiconductor Device

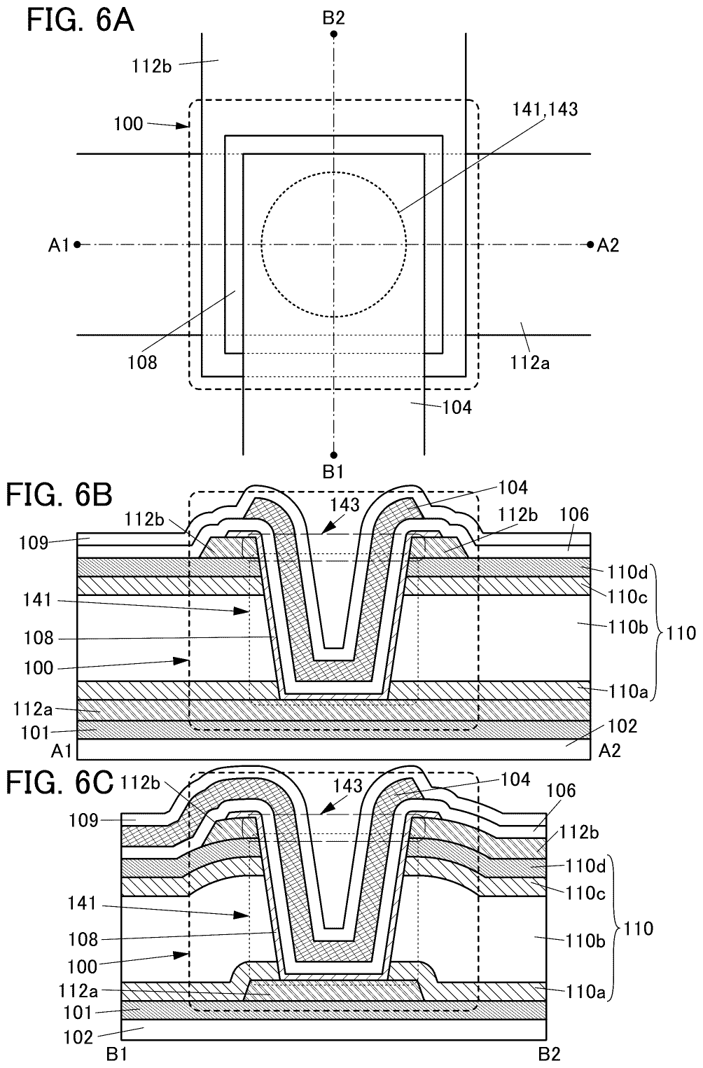

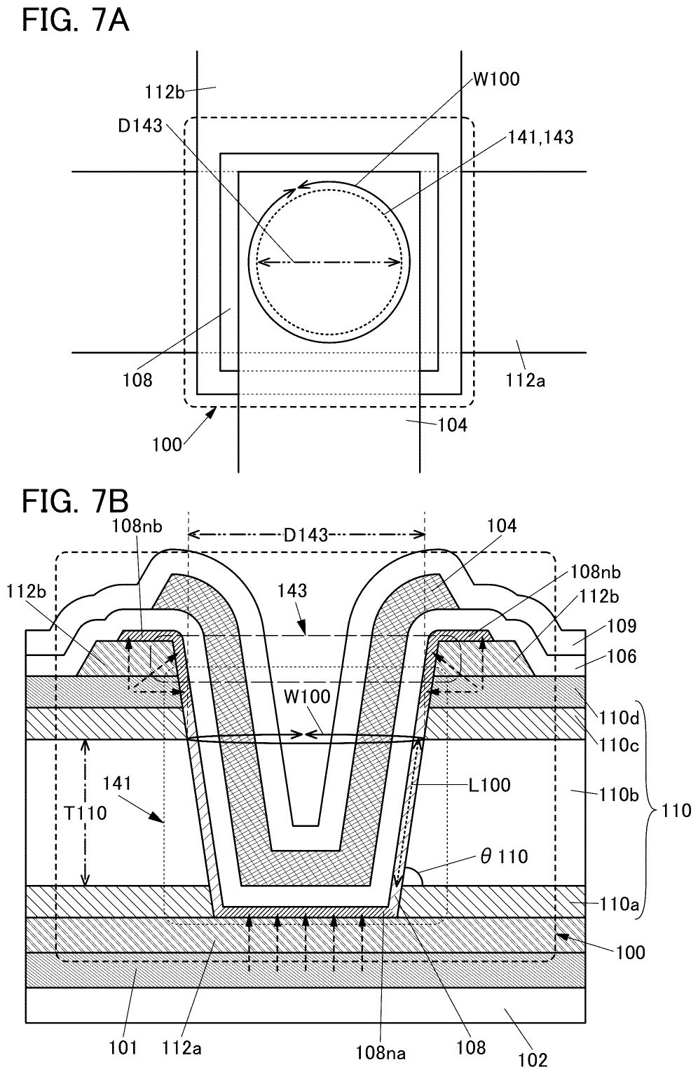

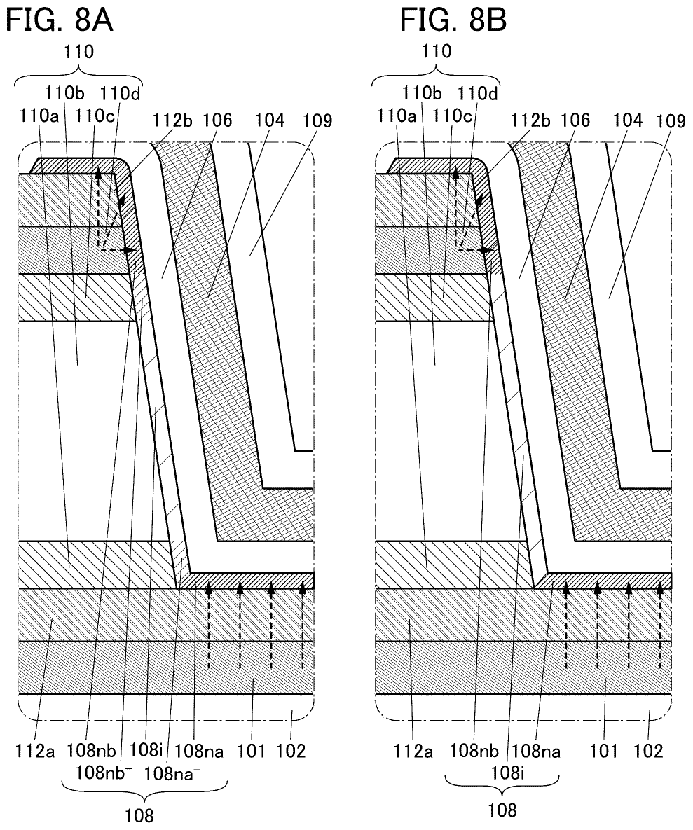

FIG. 6A, FIG. 6B, FIG. 6C, FIG. 7A, FIG. 7B, FIG. 8A, and FIG. 8B are variation examples of the structures illustrated in FIG. 1A, FIG. 1B, FIG. 1C, FIG. 3A, FIG. 3B, FIG. 4A, and FIG. 4B, respectively, and the insulating layer 110 includes an insulating layer 110d over the insulating layer 110c in addition to the insulating layer 110a, the insulating layer 110b over the insulating layer 110a, and the insulating layer 110c over the insulating layer 110b. That is, an example in which the insulating layer 110 has a four-layer stacked structure is illustrated.

The insulating layer 110d can include a region in contact with the bottom surface of the conductive layer 112b. In other words, the conductive layer 112b can include a region in contact with the top surface of the insulating layer 110d.

High contact resistance between the conductive layer 112b and the semiconductor layer 108 may lead to high electrical resistance of the other of the source region and the drain region of the semiconductor layer 108 and a low on-state current of the transistor. Thus, the insulating layer 110d is an insulating layer including hydrogen, and the semiconductor layer 108 is a layer including a material that has reduced resistance when supplied with hydrogen, such as a metal oxide layer. Note that the insulating layer 110d does not necessarily include hydrogen as long as it includes a material that reduces the resistance of the semiconductor layer 108 when supplied to the semiconductor layer 108.

In FIG. 7B, FIG. 8A, and FIG. 8B, not only an example of a state where hydrogen included in the insulating layer 101 is supplied to the semiconductor layer 108 but also an example of a state where hydrogen included in the insulating layer 110d is supplied to the semiconductor layer 108 are indicated by dashed single-headed arrows. As illustrated in FIG. 7B, FIG. 8A, and FIG. 8B, hydrogen included in the insulating layer 110d is transmitted through the conductive layer 112b and is supplied to the region of the semiconductor layer 108 that is in contact with the conductive layer 112b and a region in the vicinity thereof. Thus, the region of the semiconductor layer 108 that is in contact with the conductive layer 112b and a region in the vicinity thereof become a region 108nb, which is a low-resistance region. Note that the region 108nb is also formed in the region of the semiconductor layer 108 that is in contact with the insulating layer 110d and a region in the vicinity thereof.

In FIG. 7B, FIG. 8A, and FIG. 8B, a low-resistance region formed in the region of the semiconductor layer 108 that is in contact with the conductive layer 112a and a region in the vicinity thereof are referred to as a region 108na. The region 108na functions as the one of the source region and the drain region of the transistor 100. The region 108nb functions as the other of the source region and the drain region of the transistor 100.

When the region 108nb, which is a low-resistance region, is formed in the region of the semiconductor layer 108 that is in contact with the conductive layer 112b, the contact resistance between the semiconductor layer 108 and the conductive layer 112b can be reduced. Accordingly, the transistor 100 can have a higher on-state current and favorable electrical characteristics. This allows the semiconductor device to operate at high speed.

For example, the hydrogen content per unit volume of the insulating layer 110d can be substantially the same as the hydrogen content per unit volume of the insulating layer 101. The insulating layer 110d can be formed using a material that can be used for the insulating layer 101. The insulating layer 110d can be formed using one or both of a nitride insulating film and an oxide insulating film and is preferably formed using, for example, one or both of a silicon nitride film and a silicon nitride oxide film.

The insulating layer 110d can include a material that is the same as the material included in the insulating layer 101. For example, the insulating layer 110d can be formed using the same material as the insulating layer 101. In the case where the insulating layer 110d is formed using the same material as the insulating layer 101 and the hydrogen content per unit volume of the insulating layer 101 and the hydrogen content per unit volume of the insulating layer 110d are substantially the same, the insulating layer 101 and the insulating layer 110d can be formed under the same conditions. Like the insulating layer 101, the insulating layer 110d preferably releases hydrogen when heated. Note that when the film formation time of the insulating layer 101 and the film formation time of the insulating layer 110d are made different from each other, for example, the thickness of the insulating layer 101 and the thickness of the insulating layer 110d can be made different from each other.

The thickness of the insulating layer 110d is preferably greater than or equal to 5 nm and less than or equal to 200 nm, further preferably greater than or equal to 5 nm and less than or equal to 150 nm, still further preferably greater than or equal to 10 nm and less than or equal to 150 nm, yet still further preferably greater than or equal to 20 nm and less than or equal to 150 nm, yet still further preferably greater than or equal to 30 nm and less than or equal to 150 nm, yet still further preferably greater than or equal to 30 nm and less than or equal to 120 nm. When the thickness of the insulating layer 110d is large, the hydrogen content of the insulating layer 110d can be high, so that hydrogen can be favorably supplied to the semiconductor layer 108. Meanwhile, when the thickness of the insulating layer 110d is too large, the productivity of the semiconductor device of one embodiment of the present invention decreases; thus, the thickness is preferably set in consideration of the productivity.

In the case where the insulating layer 110 includes the insulating layer 110d, it is preferable that the insulating layer 110b include a region having a higher oxygen content than at least one of the insulating layer 110a, the insulating layer 110c, and the insulating layer 110d. This facilitates oxygen supply to the channel formation region of the semiconductor layer 108 and formation of the channel formation region as an i-type region. As a result, the transistor 100 can have favorable electrical characteristics and increased reliability. Thus, the semiconductor device of one embodiment of the present invention can have increased reliability.

The insulating layer 110c can be formed using a material that does not easily allow diffusion of hydrogen, as described above. In that case, hydrogen included in the insulating layer 110d can be inhibited from being supplied to, for example, the region of the semiconductor layer 108 that is away from the region where the insulating layer 110d and the semiconductor layer 108 are in contact with each other. For example, hydrogen included in the insulating layer 110d can be inhibited from being supplied to the region of the semiconductor layer 108 that is in contact with the insulating layer 110c. It is thus possible to inhibit a reduction in the channel length of the transistor 100 and a reduction in the threshold voltage of the transistor 100, that is, a negative shift of the threshold voltage. This can reduce a cutoff current, so that the transistor can have normally-off characteristics. Thus, the reliability of the transistor 100 can be increased, and the reliability of the semiconductor device of one embodiment of the present invention can be increased.

As described above, the insulating layer 110c can be formed using, for example, a material that is less likely to allow diffusion of hydrogen than the conductive layer 112b or a material that is less likely to allow diffusion of hydrogen than the insulating layer 110b. The insulating layer 110c can be formed using, for example, a material having a lower hydrogen diffusion coefficient than the conductive layer 112b or a material having a lower hydrogen diffusion coefficient than the insulating layer 110b. The hydrogen diffusion coefficient in the insulating layer 110c can be substantially the same as the hydrogen diffusion coefficient in the insulating layer 110a.

The insulating layer 110d includes a region where the hydrogen content is higher than or equal to the hydrogen content of the insulating layer 110c, for example. In other words, the insulating layer 110c includes a region where the hydrogen content is lower than or equal to the hydrogen content of the insulating layer 110d, for example. In this case, the region 108nb-illustrated in FIG. 8A can have lower electrical resistance than the region 108i and higher electrical resistance than the region 108nb.

In the above manner, the channel length of the transistor 100 can be inhibited from being reduced by hydrogen supply to the region that is in contact with the insulating layer 110b, for example, while the contact resistance between the semiconductor layer 108 and the conductive layer 112b is reduced. Thus, the transistor 100 can have a high on-state current and high reliability. The semiconductor device of one embodiment of the present invention can operate at high speed and have high reliability.

Components of the semiconductor device of one embodiment of the present invention other than the insulating layer 101 functioning as the base insulating layer and the insulating layer 110 functioning as the spacer will be described below. For example, materials that can be used for the components will be described.

### [Conductive Layer 112a, Conductive Layer 112b, and Conductive Layer 104]

For the conductive layer 112a, the conductive layer 112b, and the conductive layer 104, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like, or an alloy containing any of these metal elements as its component, for example. A nitride or an oxide of any of the above metals or the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having low electrical resistivity, typified by polycrystalline silicon containing an impurity element such as phosphorus, or silicide such as nickel silicide may be used.

For the conductive layer 112a, the conductive layer 112b, and the conductive layer 104, for example, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or conductive materials that maintain the conductivity even when oxidized.

It is also possible to use a conductive oxide such as indium oxide, zinc oxide, In—Sn oxide, In—Zn oxide, In—W oxide, In—W—Zn oxide, In—Ti oxide, In—Ti—Sn oxide, In—Sn oxide, In—Sn—Si oxide, or Ga—Zn oxide for the conductive layer 112a, the conductive layer 112b, and the conductive layer 104. A conductive oxide containing indium is particularly preferable because of its high conductivity.

Each of the conductive layer 112a and the conductive layer 112b includes a region that is in contact with the semiconductor layer 108. When the semiconductor layer 108 is a metal oxide layer and the conductive layer 112a or the conductive layer 112b is formed using a metal that is likely to be oxidized, an insulating oxide is formed between the conductive layer 112a or the conductive layer 112b and the semiconductor layer 108, which might inhibit continuity between the conductive layer 112a or the conductive layer 112b and the semiconductor layer 108. Therefore, the conductive layer 112a and the conductive layer 112b are preferably formed using a conductive material that is less likely to be oxidized, a conductive material that maintains the conductivity even when oxidized, or an oxide conductive material.

As each of the conductive layer 112a, the conductive layer 112b, and the conductive layer 104, a stack of a plurality of layers including the above conductive material may be used. Here, in the case where the semiconductor layer 108 is a metal oxide layer, oxygen is sometimes supplied from the semiconductor layer 108 to the conductive layer 112a and the conductive layer 112b, each of which includes a region in contact with the semiconductor layer 108. Thus, a conductive material that is less likely to be oxidized, a conductive material that maintains the conductivity even when oxidized, or an oxide conductive material is preferably used for a layer including a region in contact with the semiconductor layer 108, e.g., a layer having the largest contact area with the semiconductor layer 108.

Note that the conductive layer 112a, the conductive layer 112b, and the conductive layer 104 may be formed using the same material or at least one of the conductive layer 112a, the conductive layer 112b, and the conductive layer 104 may be formed using a material different from the material used for the other layer(s).

### [Semiconductor Layer 108]

The semiconductor layer 108 includes a metal oxide exhibiting semiconductor characteristics (also referred to as an oxide semiconductor).

There is no particular limitation on the crystallinity of the semiconductor material used for the semiconductor layer 108, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The band gap of a metal oxide used for the semiconductor layer 108 is preferably greater than or equal to 2.0 eV, further preferably greater than or equal to 2.5 eV.

Examples of the metal oxide that can be used for the semiconductor layer 108 include indium oxide, gallium oxide, and zinc oxide. The metal oxide preferably contains at least indium or zinc. The metal oxide preferably contains two or three selected from indium, an element M, and zinc. The element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably any one or more of the above elements, further preferably one or more selected from aluminum, gallium, tin, and yttrium, still further preferably gallium. In this specification and the like, a metal element and a metalloid element may be collectively referred to as a “metal element”, and a “metal element” described in this specification and the like may encompass a metalloid element.

For example, the semiconductor layer 108 can be formed using indium zinc oxide (also referred to as In—Zn oxide or IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, indium tin oxide containing silicon, gallium tin oxide (Ga—Sn oxide), aluminum tin oxide (Al—Sn oxide), or the like can be used.

By increasing the proportion of the number of indium atoms in the total number of atoms of all the metal elements included in the metal oxide, the field-effect mobility of the transistor can be increased. In addition, the transistor can have a high on-state current.

Note that the metal oxide may contain, instead of or in addition to indium, one or more metal elements with large period numbers in the periodic table of the elements. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Thus, a change in electrical characteristics of the transistor can be inhibited and the reliability of the transistor can be improved.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

The composition of the metal oxide used for the semiconductor layer 108 affects the electrical characteristics and reliability of the transistor. Therefore, by determining the composition of the metal oxide in accordance with the electrical characteristics and reliability required for the transistor, the semiconductor device can have both excellent electrical characteristics and high reliability.

When the metal oxide is an In—M—Zn oxide, the proportion of the number of In atoms is preferably higher than or equal to that of the number of M atoms in the In—M—Zn oxide. Examples of the atomic ratio of the metal elements of such an In—M—Zn oxide include In:M:Zn=1:1:1, In:M:Zn=1:1:1.2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood of any of these atomic ratios. Note that a composition in the neighborhood includes the range of +30% of an intended atomic ratio. By increasing the proportion of the number of indium atoms in the metal oxide, the on-state current, field-effect mobility, or the like of the transistor can be improved.

The proportion of the number of In atoms may be less than that of the number of M atoms in the In—M—Zn oxide. Examples of the atomic ratio of the metal elements in such an In-M-Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

A sputtering method or an atomic layer deposition (ALD) method can be suitably used to form the metal oxide. Note that in the case where the metal oxide is formed by a sputtering method, the composition of the formed metal oxide film may be different from the composition of a target. In particular, the zinc content percentage of the formed metal oxide film may be reduced to approximately 50% of that of the target.

The semiconductor layer 108 may have a stacked-layer structure of two or more metal oxide layers. The two or more metal oxide layers included in the semiconductor layer 108 may have the same composition or substantially the same compositions. When the compositions of the stacked metal oxide layers are the same, they can be formed using the same sputtering target, for example, and the manufacturing cost can thus be reduced.

The two or more metal oxide layers included in the semiconductor layer 108 may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In addition, it is particularly preferable to use gallium, aluminum, or tin as the element M. For another example, a stacked-layer structure of any one selected from indium oxide, indium gallium oxide, and IGZO, and any one selected from IAZO, IAGZO, and ITZO (registered trademark) may be employed.

It is preferable that the semiconductor layer 108 include a metal oxide layer having crystallinity. Examples of the structure of a metal oxide having crystallinity include a CAAC (c-axis aligned crystal) structure, a polycrystalline structure, and a nano-crystal (nc) structure. By using a metal oxide layer having crystallinity as the semiconductor layer 108, the density of defect states in the semiconductor layer 108 can be reduced, which enables the semiconductor device to have high reliability.

The higher the crystallinity of the metal oxide layer used as the semiconductor layer 108 is, the lower the density of defect states in the semiconductor layer 108 can be. By contrast, the use of a metal oxide layer having low crystallinity makes it possible that a high current flows in the transistor.

In the case where the metal oxide layer is formed by a sputtering method, the higher the substrate temperature (the stage temperature) in the formation is, the higher the crystallinity of the formed metal oxide layer can be. Furthermore, the higher the proportion of the flow rate of an oxygen gas in the whole film formation gas (hereinafter also referred to as an oxygen flow rate ratio) used in the formation is, the higher the crystallinity of the formed metal oxide layer can be.

The semiconductor layer 108 may have a stacked-layer structure of two or more metal oxide layers having different crystallinities. For example, a stacked-layer structure of the first metal oxide layer and the second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

The thickness of the semiconductor layer 108 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm.

In the case where the semiconductor layer 108 is formed using an oxide semiconductor, hydrogen contained in the oxide semiconductor reacts with oxygen bonded to a metal atom to be water, and thus sometimes forms an oxygen vacancy (Vo) in the oxide semiconductor. In some cases, a defect that is an oxygen vacancy into which hydrogen enters (VOH) functions as a donor and generates an electron serving as a carrier. In other cases, bonding of part of hydrogen to oxygen bonded to a metal atom generates electrons serving as carriers. Thus, a transistor including an oxide semiconductor that contains a large amount of hydrogen is likely to have normally-on characteristics (i.e., a negative threshold voltage value). Moreover, hydrogen in an oxide semiconductor is easily transferred by a stress such as heat or an electric field; thus, a large amount of hydrogen in an oxide semiconductor might reduce the reliability of a transistor.

In the case where an oxide semiconductor is used for the semiconductor layer 108, the amount of VoH in the semiconductor layer 108 is preferably reduced as much as possible so that the semiconductor layer 108 becomes a highly purified intrinsic or substantially highly purified intrinsic semiconductor layer. In order to obtain such an oxide semiconductor with a sufficiently reduced amount of VoH, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that repairing oxygen vacancies by supplying oxygen to an oxide semiconductor is sometimes referred to as oxygen adding treatment.

When an oxide semiconductor is used for the semiconductor layer 108, the carrier concentration of the oxide semiconductor in the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the oxide semiconductor in the channel formation region is not particularly limited and can be, for example, 1×10⁻⁹ cm⁻³.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be held for a long period. Furthermore, the semiconductor device can have lower power consumption by including the OS transistor.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Other examples of the semiconductor material that can be used for the semiconductor layer 108 include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. These semiconductor materials may contain an impurity as a dopant.

Examples of silicon that can be used for the semiconductor layer 108 include single crystal silicon, polycrystalline silicon, microcrystalline silicon, and amorphous silicon. An example of polycrystalline silicon is low-temperature polysilicon (LTPS).

The transistor including amorphous silicon in the semiconductor layer 108 can be formed over a large-sized glass substrate, thereby reducing the manufacturing cost. The transistor including polycrystalline silicon in the semiconductor layer 108 has high field-effect mobility and can operate at high speed. The transistor including microcrystalline silicon in the semiconductor layer 108 has higher field-effect mobility and can operate at higher speed than the transistor including amorphous silicon.

The semiconductor layer 108 may include a layered substance functioning as a semiconductor. The layered substance generally refers to a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layer 106]

The insulating layer 106 may have a single-layer structure or a stacked-layer structure of two or more layers. The insulating layer 106 preferably includes one or more inorganic insulating films. Examples of the inorganic insulating film include an oxide insulating film and a nitride insulating film. Specific examples of these inorganic insulating films are as described above.

The insulating layer 106 includes a portion that is in contact with the semiconductor layer 108. In the case where the semiconductor layer 108 is formed using an oxide semiconductor, at least the film of the insulating layer 106 that is in contact with the semiconductor layer 108 is preferably any of the above-described oxide insulating films. A film that releases oxygen when heated is further preferably used for the insulating layer 106.

Specifically, in the case where the insulating layer 106 has a single-layer structure, the insulating layer 106 is preferably formed using a silicon oxide film or a silicon oxynitride film.

The insulating layer 106 can have a stacked-layer structure of an oxide insulating film on the side that is in contact with the semiconductor layer 108 and a nitride insulating film on the side that is in contact with the conductive layer 104. As the oxide insulating film, for example, a silicon oxide film or a silicon oxynitride film is preferably used. As the nitride insulating film, a silicon nitride film or a silicon nitride oxide film is preferably used.

A silicon nitride film and a silicon nitride oxide film can be suitably used for the insulating layer 106 because they release fewer impurities (e.g., water and hydrogen) and are less likely to transmit oxygen and hydrogen. Inhibiting diffusion of impurities from the insulating layer 106 to the semiconductor layer 108 results in favorable electrical characteristics and high reliability of the transistor.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Substrate 102]

There is no particular limitation on the properties of the material of the substrate 102 as long as the material has heat resistance high enough to withstand at least heat treatment to be performed later. For example, a glass substrate; a quartz substrate; a sapphire substrate; a ceramic substrate; an organic resin substrate; a single crystal semiconductor substrate or a polycrystalline semiconductor substrate including silicon or silicon carbide as a material; a compound semiconductor substrate of silicon germanium or the like; or an SOI (Silicon On Insulator) substrate can be used as the substrate 102. The substrate 102 may be provided with a semiconductor element. Furthermore, a polarizing plate may be used as the substrate 102. Note that the shape of the semiconductor substrate and an insulating substrate may be a circular shape or a shape with corners.

A flexible substrate may be used as the substrate 102, and the transistor 100 may be formed directly on the flexible substrate, for example. Alternatively, a separation layer may be provided between the substrate 102 and the transistor 100 and the like. The separation layer can be used for separation of part or the whole of a semiconductor device completed thereover from the substrate 102 and transferring the part or the whole of the semiconductor device onto another substrate. In that case, for example, the transistor 100 can be transferred onto a substrate having low heat resistance or a flexible substrate as well.

For the substrate 102, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 102.

### Structure Example 3 of Semiconductor Device

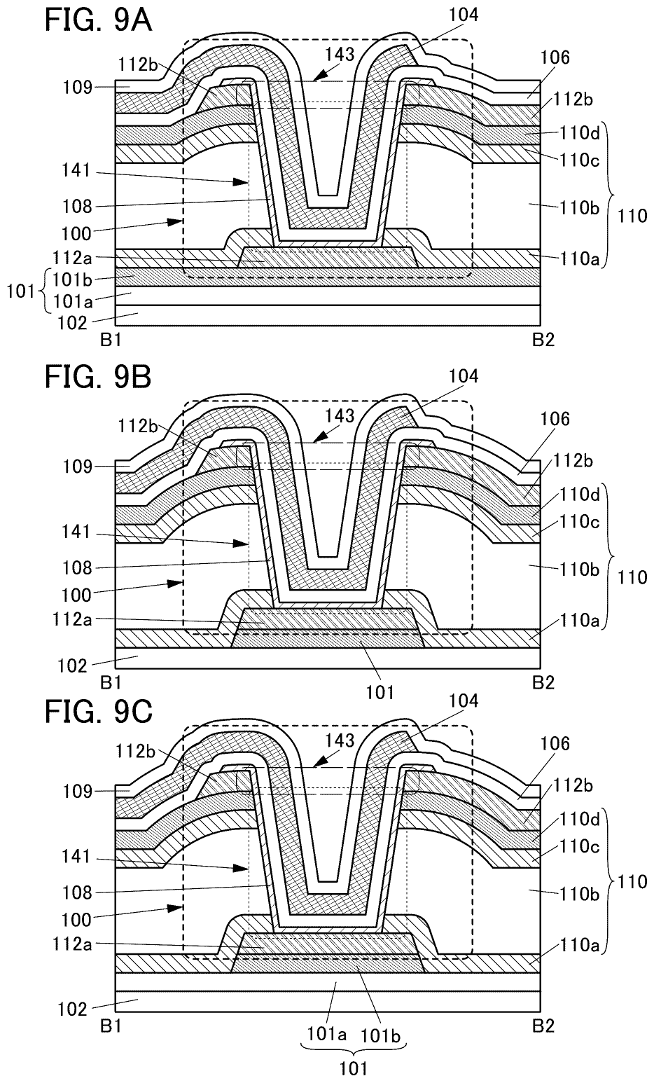

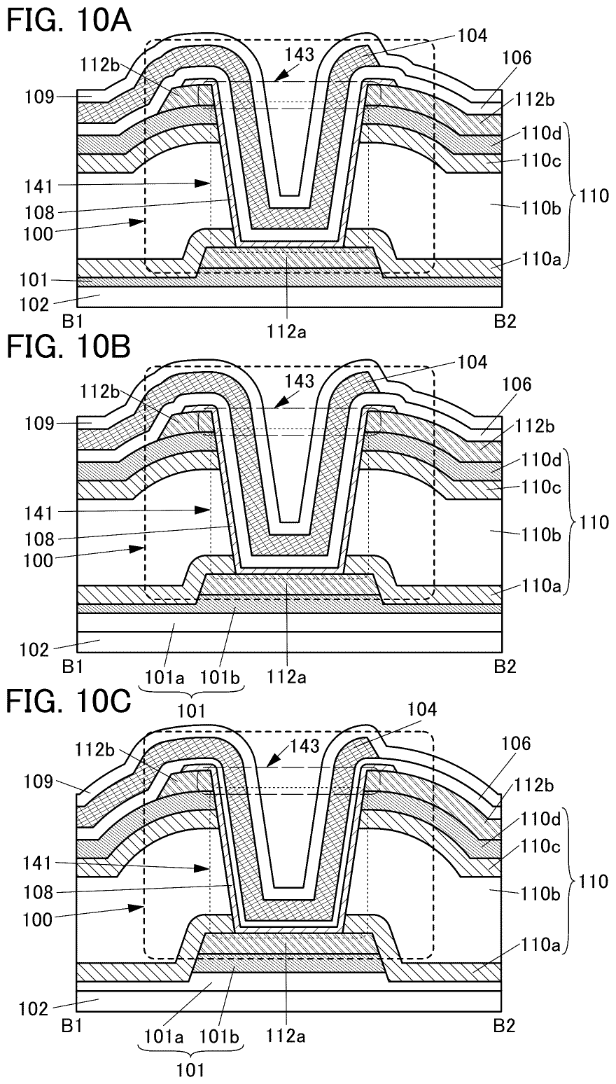

FIG. 9A to FIG. 10C are cross-sectional views illustrating variation examples of the semiconductor device illustrated in FIG. 6C. FIG. 9A illustrates an example in which the insulating layer 101 includes an insulating layer 101a and an insulating layer 101b over the insulating layer 101a. That is, the insulating layer 101 has a stacked-layer structure of two layers in the example illustrated in FIG. 9A.

The insulating layer 101b corresponds to the insulating layer 101 illustrated in FIG. 6C, for example, and can be an insulating layer including hydrogen. The insulating layer 101a can be an insulating layer including a region having a lower hydrogen content than the insulating layer 101b. The insulating layer 101a can be, for example, an insulating layer that does not include hydrogen.

The insulating layer 101a can be formed using a material that can be used for the insulating layer 110. The insulating layer 101a can be formed using an inorganic insulating film, e.g., an oxide insulating film or a nitride insulating film. The insulating layer 101a can be formed using, for example, a silicon oxide film, a silicon oxynitride film, an aluminum oxide film, an aluminum oxynitride film, a silicon nitride film, a silicon nitride oxide film, an aluminum nitride film, or an aluminum nitride oxide film. Note that the insulating layer 101a may have a stacked-layer structure of two or more layers, and the insulating layer 101b may have a stacked-layer structure of two or more layers.

FIG. 9B illustrates an example in which patterning is performed on the insulating layer 101. For example, the conductive layer 112a and the insulating layer 101 illustrated in FIG. 9B can be formed in the following manner: the insulating layer 101 is formed over the substrate 102, a conductive film to be the conductive layer 112a is formed over the insulating layer 101, a resist mask is formed by a photolithography process, and the conductive film and the insulating layer 101 are processed.

In the semiconductor device of one embodiment of the present invention with the structure illustrated in FIG. 9B, the area of the insulating layer 101 including hydrogen in a plan view, or specifically, the area of the insulating layer 101 including a region where the hydrogen content is higher than or equal to the hydrogen content of the insulating layer 110a in a plan view can be smaller than in the semiconductor device illustrated in FIG. 9A. This can inhibit a reduction in the reliability of the semiconductor device of one embodiment of the present invention due to hydrogen contained in the insulating layer 101. For example, hydrogen contained in the insulating layer 101 can be inhibited from being supplied to the channel formation region of the transistor 100, whereby the electrical characteristics of the transistor 100 can be stabilized. Meanwhile, in the semiconductor device illustrated in FIG. 9A, a step generated in the insulating layer 110 can be smaller than in the semiconductor device illustrated in FIG. 9B, and the manufacturing process of the semiconductor device illustrated in FIG. 9A can be simpler than that of the semiconductor device illustrated in FIG. 9B.

FIG. 9C illustrates an example in which the insulating layer 101 includes the insulating layer 101a and the insulating layer 101b over the insulating layer 101a and patterning is performed on the insulating layer 101b. In the example illustrated in FIG. 9C, the insulating layer 101b is preferably formed using a material having high etching selectivity with respect to the insulating layer 101a to inhibit the insulating layer 101a from being partly processed at the time of processing of the insulating layer 101b and from resultantly having a reduced thickness.

FIG. 10A illustrates an example in which the thickness of the insulating layer 101 in a region not overlapping with the conductive layer 112a is smaller than the thickness of the insulating layer 101 in a region overlapping with the conductive layer 112a. When the etching selectivity between the insulating layer 101 and the conductive layer 112a is low, part of the insulating layer 101 may be processed at the time of processing of the conductive film to be the conductive layer 112a, and the thickness of the insulating layer 101 may be reduced as illustrated in FIG. 10A.

FIG. 10B illustrates an example in which the insulating layer 101 includes the insulating layer 101a and the insulating layer 101b over the insulating layer 101a, and the thickness of the insulating layer 101b in a region not overlapping with the conductive layer 112a is smaller than the thickness of the insulating layer 101b in a region overlapping with the conductive layer 112a. When the etching selectivity between the insulating layer 101b and the conductive layer 112a is low, part of the insulating layer 101b may be processed at the time of processing of the conductive film to be the conductive layer 112a, and the thickness of the insulating layer 101b may be reduced as illustrated in FIG. 10B.

FIG. 10C illustrates an example in which the thickness of the insulating layer 101a in a region not overlapping with the insulating layer 101b is smaller than the thickness of the insulating layer 101a in a region overlapping with the insulating layer 101b in the structure illustrated in FIG. 9C. When the etching selectivity between the insulating layer 101a and the insulating layer 101b is low, part of the insulating layer 101a may be processed at the time of processing of the insulating layer 101b, and the thickness of the insulating layer 101a may be reduced as illustrated in FIG. 10C.

### Structure Example 4 of Semiconductor Device

Variation examples of the transistor 100 included in the semiconductor device illustrated in FIG. 6A, FIG. 6B, FIG. 6C, FIG. 7A, and FIG. 7B will be described below.

### [Transistor 100A]

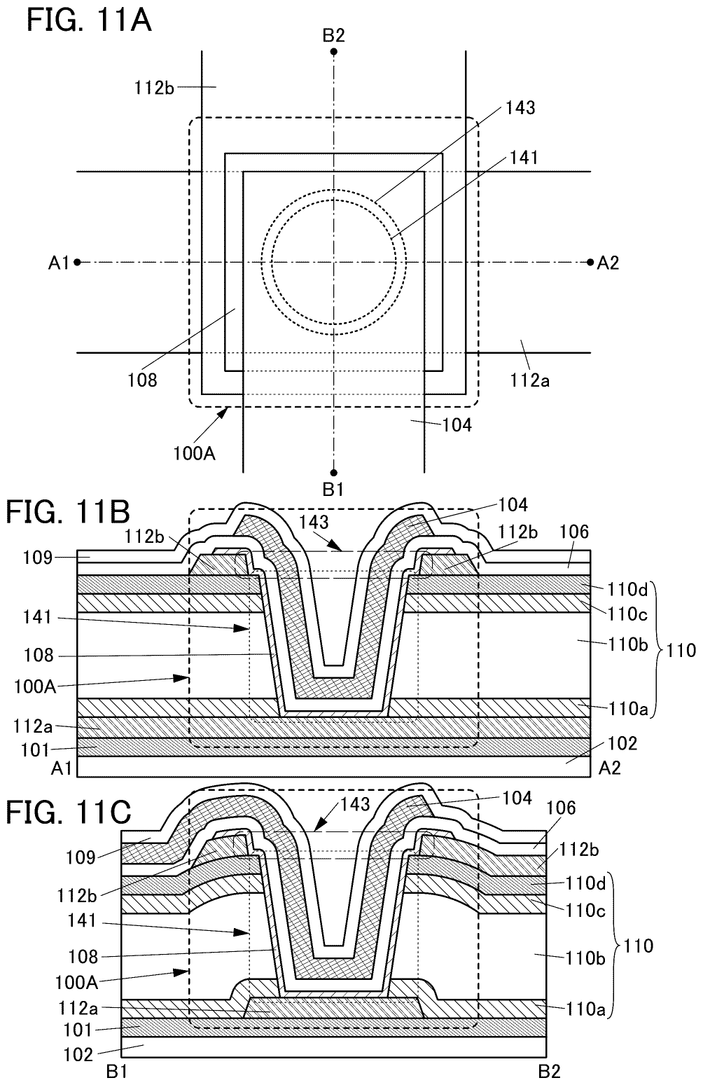

FIG. 11A is a plan view illustrating a structure example of the semiconductor device of one embodiment of the present invention, and illustrates a structure example of a transistor 100A. FIG. 11B is a cross-sectional view taken along dashed-dotted line A1-A2 in FIG. 11A, and FIG. 11C is a cross-sectional view taken along dashed-dotted line B1-B2 in FIG. 11A.

The transistor 100A is different from the transistor 100 mainly in that the opening 143 is larger than the opening 141 in a plan view. In the transistor 100A, the end portion of the conductive layer 112b on the opening 143 side is positioned outward from the end portion of the insulating layer 110 on the opening 141 side. The semiconductor layer 108 can include a region in contact with the top surface of the insulating layer 110 in the opening 143.

### [Transistor 100B]

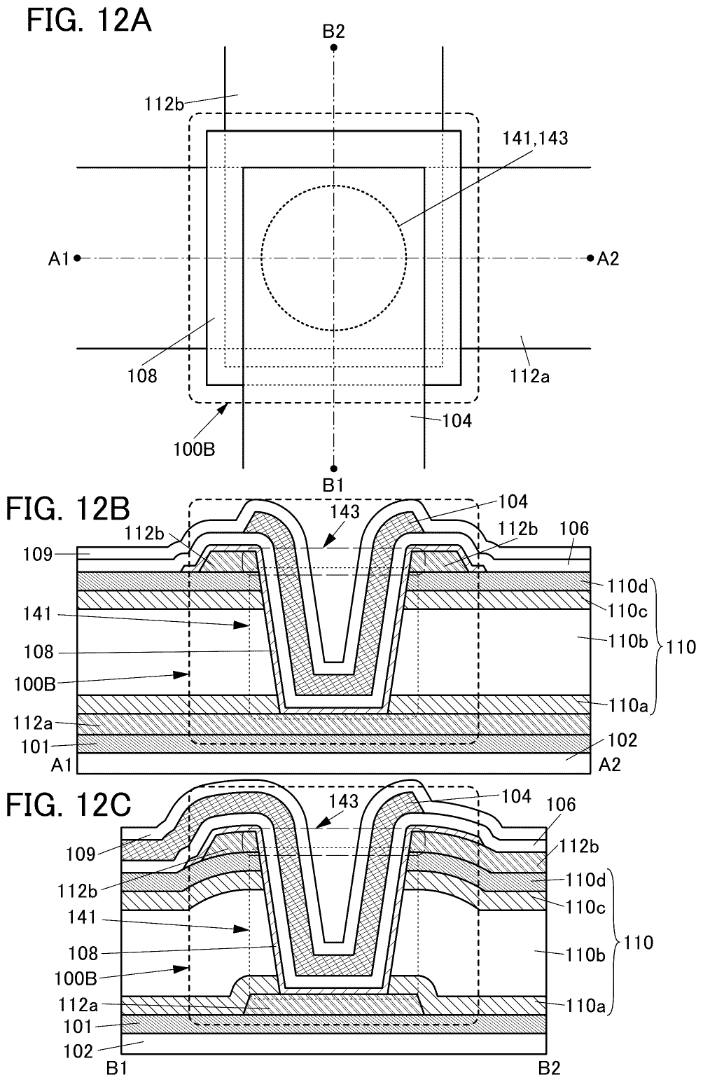

FIG. 12A is a plan view illustrating a structure example of the semiconductor device of one embodiment of the present invention, and illustrates a structure example of a transistor 100B. FIG. 12B is a cross-sectional view taken along dashed-dotted line A1-A2 in FIG. 12A, and FIG. 12C is a cross-sectional view taken along dashed-dotted line B1-B2 in FIG. 12A.

The transistor 100B is different from the transistor 100 mainly in that the semiconductor layer 108 includes a region in contact with a side surface of the conductive layer 112b on the side not facing the opening 143 (the side opposite to the opening 143). As illustrated in FIG. 12C, the semiconductor layer 108 of the transistor 100B can cover the side surface of the conductive layer 112b on the side not facing the opening 143. The end portion of the semiconductor layer 108 is positioned outward from the end portion of the conductive layer 112b and is in contact with the top surface of the insulating layer 110. On the left side in FIG. 12C, the end portion of the semiconductor layer 108 covers the end portion of the conductive layer 112b and is in contact with the top surface of the insulating layer 110. On the right side in FIG. 12C, the end portion of the semiconductor layer 108 is in contact with the top surface of the conductive layer 112b.

### [Transistor 100C]

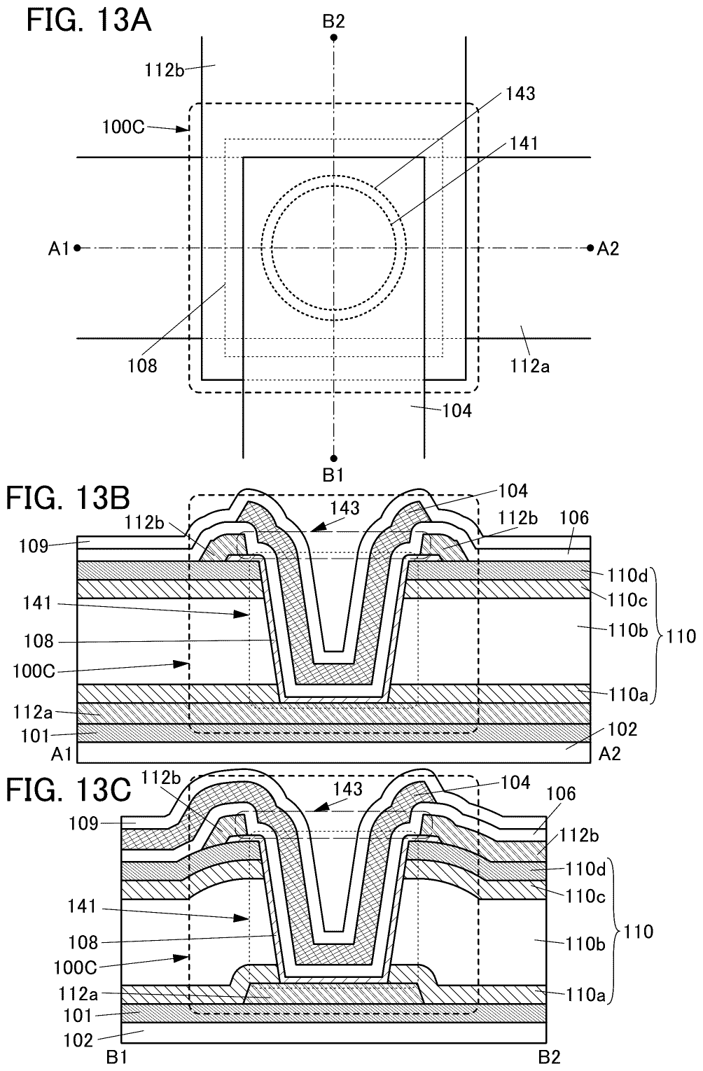

FIG. 13A is a plan view illustrating a structure example of the semiconductor device of one embodiment of the present invention, and illustrates a structure example of a transistor 100C. FIG. 13B is a cross-sectional view taken along dashed-dotted line A1-A2 in FIG. 13A, and FIG. 13C is a cross-sectional view taken along dashed-dotted line B1-B2 in FIG. 13A.

The transistor 100C is a variation example of the transistor 100A and is different from the transistor 100A mainly in that the conductive layer 112b is provided over the semiconductor layer 108. The transistor 100C can have a structure in which the conductive layer 112b covers at least part of the top surface and at least part of a side surface of the semiconductor layer 108.

### [Transistor 100D]

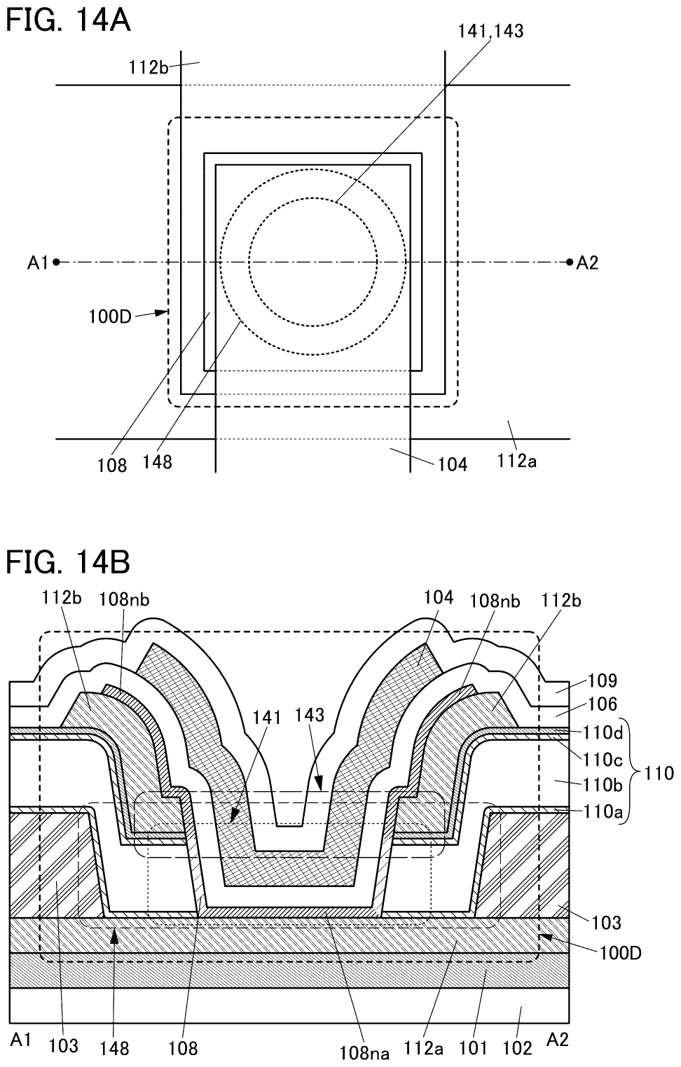

FIG. 14A is a plan view illustrating a structure example of the semiconductor device of one embodiment of the present invention, and illustrates a structure example of a transistor 100D. FIG. 14B is a cross-sectional view taken along dashed-dotted line A1-A2 in FIG. 14A.

The transistor 100D is different from the transistor 100 mainly in that a conductive layer 103 is provided over the conductive layer 112a. The conductive layer 103 is provided to include a region in contact with the top surface of the conductive layer 112a. The conductive layer 103 can function as an auxiliary wiring of the conductive layer 112a. The conductive layer 103 is provided with an opening 148 reaching the conductive layer 112a. The conductive layer 103 is provided to include a region facing the conductive layer 104 with the insulating layer 110, the semiconductor layer 108, and the insulating layer 106 therebetween. Thus, the conductive layer 103 can function as a back gate electrode (also referred to as a second gate electrode) of the transistor 100D. In that case, the insulating layer 110 functions as a back gate insulating layer (also referred to as a second gate insulating layer) of the transistor 100D. Note that in the transistor 100D, the conductive layer 104 is referred to as a front gate electrode, a first gate electrode, or simply a gate electrode, and the insulating layer 106 is referred to as a front gate insulating layer, a first gate insulating layer, or simply a gate insulating layer.

Since the transistor 100D includes the back gate electrode, the potential of the back gate side (also referred to as a back channel) of the semiconductor layer 108 can be fixed. Thus, the saturation of the Id-Vd characteristics of the transistor 100D can be improved.

In this specification and the like, the state where the change in current is small (i.e., the slope is gentle) in a saturation region of the Id-Vd characteristics of a transistor is sometimes described using the expression “favorable saturation”.

Since the transistor 100D includes the back gate electrode, the potential of the back channel of the semiconductor layer can be fixed, so that a negative shift of the threshold voltage can be inhibited. This can reduce a cutoff current, so that the transistor can have normally-off characteristics.

The conductive layer 103 and the conductive layer 112a, which are in contact with each other, are supplied with the same potential. The conductive layer 103, which functions as the back gate electrode, is preferably supplied with the lower of the source potential and the drain potential. Thus, in the case where the transistor 100D is an n-channel transistor, it is preferable that the conductive layer 112a function as a source electrode and the conductive layer 112b function as a drain electrode. In the case where the transistor 100D is a p-channel transistor, it is preferable that the conductive layer 112a function as the drain electrode and the conductive layer 112b function as the source electrode.

There is no limitation on the top-view shape of the opening 148. The top-view shape of the opening 148 refers to the shape of an end portion of the top surface or the shape of an end portion of the bottom surface of the conductive layer 103 on the opening 148 side.

The transistor 100D can include a region where the conductive layer 103, the insulating layer 110, the semiconductor layer 108, the insulating layer 106, and the conductive layer 104 are stacked in this order in one direction with no any other layer provided between these layers. The one direction can be perpendicular to the channel length L100 direction. When the above region is wide, the electric field applied to the back channel of the semiconductor layer 108 can be controlled more reliably.

The conductive layer 103 may have a single-layer structure or a stacked-layer structure of two or more layers. The conductive layer 103 can be formed using a material that can be used for the conductive layer 112a, the conductive layer 112b, or the conductive layer 104.

The conductive layer 103 is preferably formed using a material having higher electrical conductivity than the conductive layer 112a. In that case, the conductive layer 103 can favorably function as the auxiliary wiring of the conductive layer 112a. For the conductive layer 103, one or more of copper, aluminum, titanium, tungsten, and molybdenum or an alloy containing one or more of these metals as its components can be suitably used, for example.

### [Transistor 100E]

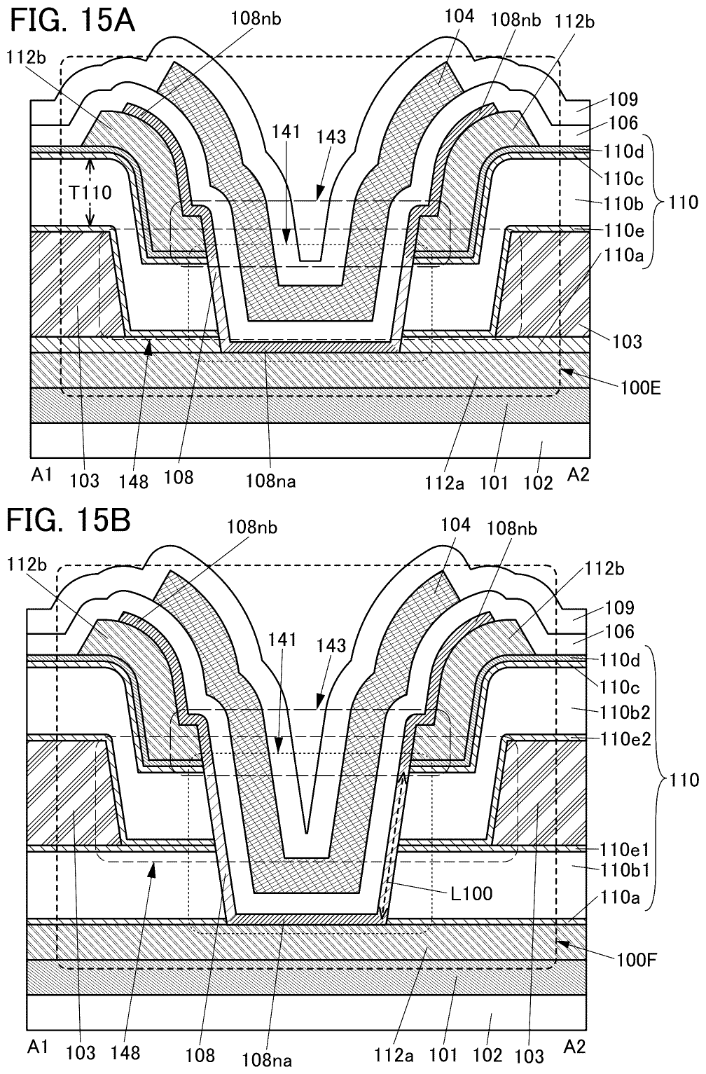

FIG. 15A is a cross-sectional view illustrating a structure example of a transistor 100E. Here, FIG. 14A can be referred to for a plan view of the transistor 100E.

The transistor 100E is different from the transistor 100D mainly in that the conductive layer 103 is electrically insulated from the conductive layer 112a and that the insulating layer 110 has a five-layer structure.

The conductive layer 103 is provided over the insulating layer 110a. The conductive layer 112a and the conductive layer 103 are electrically insulated from each other by the insulating layer 110a. The conductive layer 103 is provided with the opening 148 in a position overlapping with the conductive layer 112a.

In the semiconductor device including the transistor 100E, the insulating layer 110 includes the insulating layer 110a over the conductive layer 112a, an insulating layer 110e over the insulating layer 110a and the conductive layer 103, the insulating layer 110b over the insulating layer 110e, the insulating layer 110c over the insulating layer 110b, and the insulating layer 110d over the insulating layer 110c. The insulating layer 110e covers the top surface and a side surface of the conductive layer 103. The insulating layer 110e is provided to cover part of the opening 148. The insulating layer 110e includes a region in contact with the top surface of the insulating layer 110a in the opening 148.

The insulating layer 110e can include a material that is the same as the material included in the insulating layer 110a and can include a material that is the same as the material included in the insulating layer 110c. The insulating layer 110e is preferably formed using a material that does not easily allow diffusion of oxygen, for example. The insulating layer 110e is preferably formed using a material that does not easily allow diffusion of hydrogen.

FIG. 15A illustrates an example in which the thickness of the insulating layer 110a is uniform regardless of the place. Note that the thickness of the insulating layer 110a in the region that overlaps with the conductive layer 103 is sometimes different from the thickness of the insulating layer 110a in the region not overlapping with the conductive layer 103. For example, the insulating layer 110a in the region not overlapping with the conductive layer 103 is sometimes partly removed to have a reduced thickness at the time of processing of a film to be the conductive layer 103.

### [Transistor 100F]

FIG. 15B is a cross-sectional view illustrating a structure example of the transistor 100E. Here, FIG. 14A can be referred to for a plan view of a transistor 100F.

The transistor 100F is different from the transistor 100F mainly in that the insulating layer 110 has a seven-layer structure.

In the semiconductor device including the transistor 100F, the insulating layer 110 includes the insulating layer 110a over the conductive layer 112a, an insulating layer 110b1 over the insulating layer 110a, an insulating layer 110e1 over the insulating layer 110b1, an insulating layer 110e2 over the insulating layer 110e1 and the conductive layer 103, an insulating layer 110b2 over the insulating layer 110e2, the insulating layer 110c over the insulating layer 110b2, and the insulating layer 110d over the insulating layer 110c.

The structures of the insulating layer 110b1 and the insulating layer 110b2 can each be similar to the structure applicable to the insulating layer 110b. Specifically, it is preferable that each of the insulating layer 110b1 and the insulating layer 110b2 be an insulating layer including oxygen and include a region having a higher oxygen content than at least one of the insulating layer 110a, the insulating layer 110c, the insulating layer 110d, the insulating layer 110e1, and the insulating layer 110e2.

The structures of the insulating layer 110e1 and the insulating layer 110e2 can each be similar to the structure applicable to the insulating layer 110e. Specifically, each of the insulating layer 110e1 and the insulating layer 110e2 is preferably formed using a material that does not easily allow diffusion of oxygen. Each of the insulating layer 110e1 and the insulating layer 110e2 is preferably formed using a material that does not easily allow diffusion of hydrogen.

To each of the insulating layer 110a, the insulating layer 110c, and the insulating layer 110d, the above-described structure can be applied.

In the transistor 100F, the channel length L100 can be the shortest distance between the portion of the semiconductor layer 108 that is in contact with the insulating layer 110a and the portion of the semiconductor layer 108 that is in contact with the insulating layer 110c.

In the semiconductor device including the transistor 100F, the upper part and the lower part of the insulating layer 110 can be symmetric or substantially symmetric with respect to the conductive layer 103. Furthermore, both the insulating layer 110b1 and the insulating layer 110b2 can supply oxygen to the semiconductor layer 108; thus, the transistor can have improved characteristics.

### [Transistor 100G]

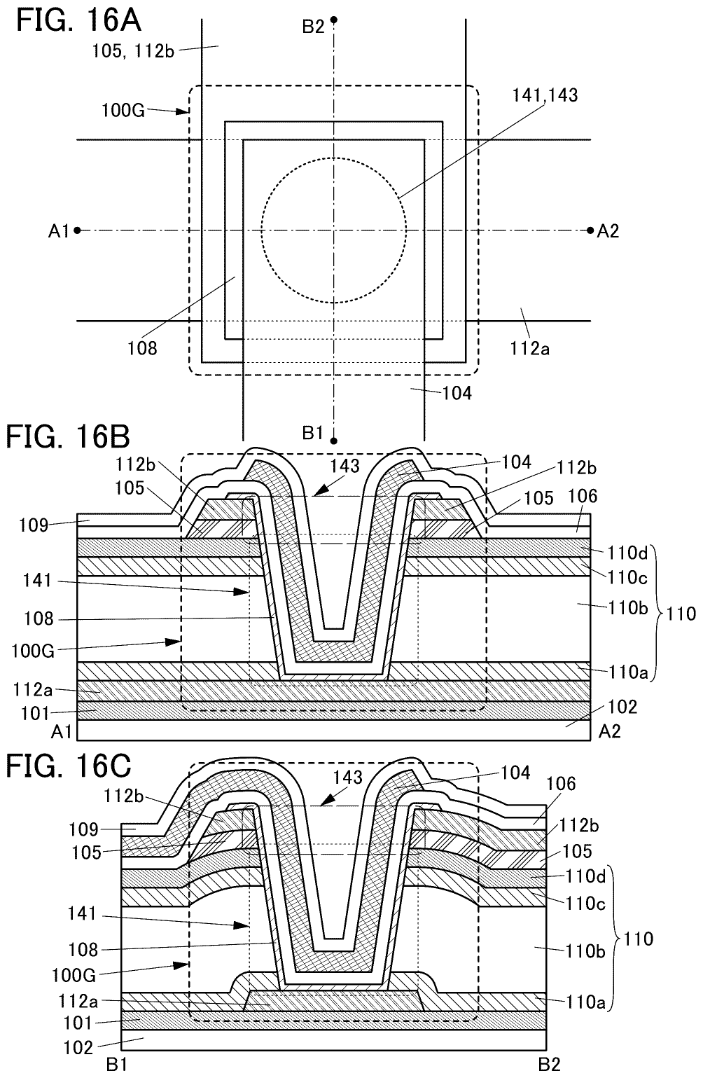

FIG. 16A is a plan view illustrating a structure example of the semiconductor device of one embodiment of the present invention, and illustrates a structure example of a transistor 100G. FIG. 16B is a cross-sectional view taken along dashed-dotted line A1-A2 in FIG. 16A, and FIG. 16C is a cross-sectional view taken along dashed-dotted line B1-B2 in FIG. 16A.

The transistor 100G is different from the transistor 100 mainly in that the transistor 100G includes a conductive layer 105 between the insulating layer 110d and the conductive layer 112b.

The conductive layer 105 is provided over the insulating layer 110, and the conductive layer 112b is provided over the conductive layer 105. The conductive layer 112b includes a region in contact with the top surface of the conductive layer 105. The conductive layer 105 can function as an auxiliary wiring of the conductive layer 112b. The conductive layer 105 is provided with the opening 143.

The semiconductor layer 108 preferably includes a region in contact with a side surface of the conductive layer 105. The semiconductor layer 108 is preferably provided in contact with an end portion of the conductive layer 105 on the opening 143 side.

In the transistor 100G, the conductive layer 105 and the conductive layer 112b function as an upper electrode of the transistor 100G. Here, a structure can be employed in which the semiconductor layer 108 includes a region in contact with the top surface of the conductive layer 112b and does not include a region in contact with the top surface of the conductive layer 105. Thus, the contact area between the semiconductor layer 108 and the conductive layer 112b can be larger than the contact area between the semiconductor layer 108 and the conductive layer 105. Therefore, the conductive layer 112b is preferably formed using a conductive material that is less likely to be oxidized, a conductive material that maintains the conductivity even when oxidized, or an oxide conductive material. Meanwhile, the conductive layer 105 is preferably formed using a material having lower electrical resistivity than the conductive layer 112b. The conductive layer 105 is preferably formed using a metal or an alloy, for example. The conductive layer 105 can be formed using a material that can be used for the conductive layer 103.

Accordingly, the upper electrode of the transistor 100G can have a low electrical resistivity while defective conduction with the semiconductor layer 108 due to oxidation is inhibited.

### [Transistor 100H]

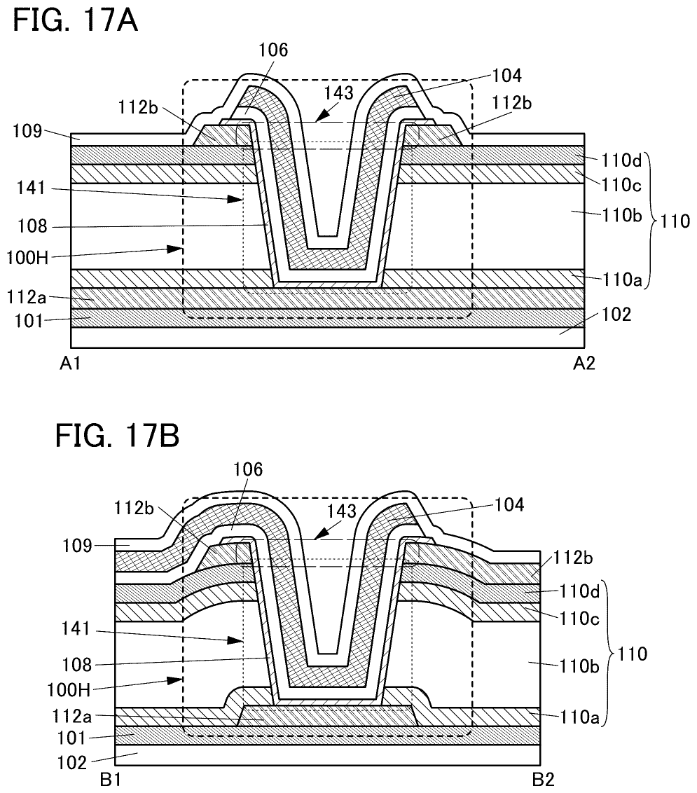

FIG. 17A and FIG. 17B are cross-sectional views illustrating a structure example of a transistor 100H. Here, FIG. 6A can be referred to for a plan view of the transistor 100H. FIG. 17A is a cross-sectional view taken along dashed-dotted line A1-A2 in FIG. 6A, and FIG. 17B is a cross-sectional view taken along dashed-dotted line B1-B2 in FIG. 6A.

The transistor 100H is different from the transistor 100 mainly in that the insulating layer 106 is processed into an island shape, for example. In the example illustrated in FIG. 17A and FIG. 17B, an end portion of the top surface of the insulating layer 106 is aligned or substantially aligned with an end portion of the bottom surface of the conductive layer 104. For example, when the insulating layer 106 is processed with the same pattern as the conductive layer 104, the end portion of the top surface of the insulating layer 106 and the end portion of the bottom surface of the conductive layer 104 can be aligned or substantially aligned with each other. Note that the end portion of the top surface of the insulating layer 106 is not necessarily aligned or substantially aligned with the end portion of the bottom surface of the conductive layer 104. The end portion of the top surface of the insulating layer 106 may be positioned outward from the end portion of the bottom surface of the conductive layer 104, for example.

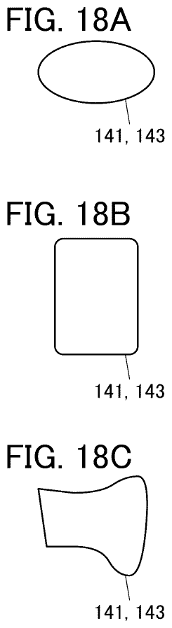

Although the plan-view shapes of the opening 141 and the opening 143 are circular shapes in this embodiment, the plan-view shapes of the opening 141 and the opening 143 are not limited to circular shapes. FIG. 18A, FIG. 18B, and FIG. 18C are plan views illustrating examples of the shapes of the opening 141 and the opening 143. The plan-view shapes of the opening 141 and the opening 143 may be elliptical as illustrated in FIG. 18A or rectangular as illustrated in FIG. 18B. Note that FIG. 18B illustrates a rectangular shape having curved corner portions. The plan-view shapes of the opening 141 and the opening 143 may each include one or both of a linear portion and a curved portion as illustrated in FIG. 18C.

### Structure Example 5 of Semiconductor Device

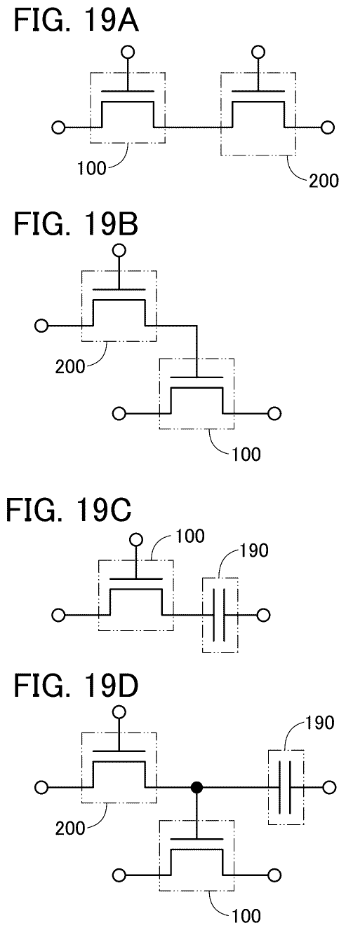

FIG. 19A to FIG. 19D are circuit diagrams illustrating structure examples of the semiconductor device of one embodiment of the present invention. The semiconductor device illustrated in FIG. 19A and FIG. 19B includes the transistor 100 and a transistor 200. The semiconductor device illustrated in FIG. 19C includes the transistor 100 and a capacitor 190. The semiconductor device illustrated in FIG. 19D includes the transistor 100, the transistor 200, and the capacitor 190. Here, any of the transistor 100A to the transistor 100H described above may be used as the transistor 100 illustrated in FIG. 19A to FIG. 19D.

In the semiconductor device illustrated in FIG. 19A, one of a source and a drain of the transistor 100 is electrically connected to one of a source and a drain of the transistor 200. In the semiconductor device illustrated in FIG. 19B, the one of the source and the drain of the transistor 200 is electrically connected to a gate of the transistor 100. In the semiconductor device illustrated in FIG. 19C, the one of the source and the drain of the transistor 100 is electrically connected to one electrode of the capacitor 190. In the semiconductor device illustrated in FIG. 19D, the gate of the transistor 100 is electrically connected to the one of the source and the drain of the transistor 200 and the one electrode of the capacitor 190.

Although the transistors are shown as n-channel transistors in FIG. 19A to FIG. 19D, one embodiment of the present invention is not limited to these examples. One or both of the transistor 100 and the transistor 200 may be a p-channel transistor(s).

### [Semiconductor Device 10]

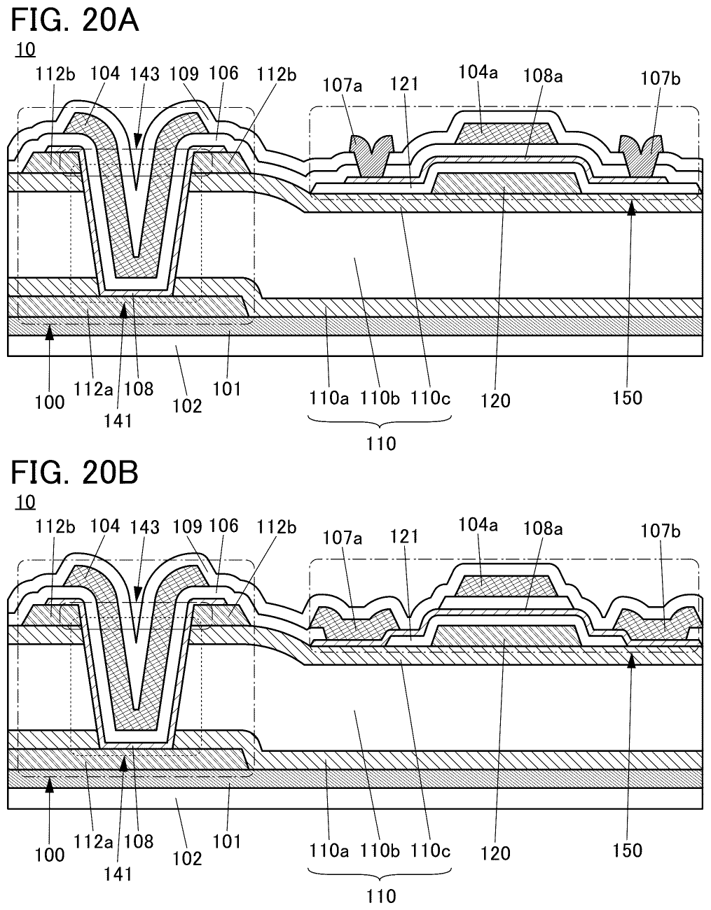

FIG. 20A and FIG. 20B are cross-sectional views illustrating structure examples of a semiconductor device 10 that is the semiconductor device of one embodiment of the present invention. The semiconductor device 10 includes the transistor 100 and a transistor 150. In the semiconductor device 10, any of the gate electrode, the source electrode, and the drain electrode of the transistor 100 can be electrically connected to any of a gate electrode, a source electrode, and a drain electrode of the transistor 150.

The insulating layer 101 is provided over the substrate 102, and the transistor 100 is provided over the insulating layer 101. In the examples illustrated in FIG. 20A and FIG. 20B, the transistor 100 has the structure illustrated in FIG. 1B and FIG. 1C. Note that in the semiconductor device 10, the insulating layer 101 may have the structure illustrated in any of FIG. 9A to FIG. 10C.

The transistor 150 includes a conductive layer 120, an insulating layer 121, a semiconductor layer 108a, the insulating layer 106, a conductive layer 107a, a conductive layer 107b, and a conductive layer 104a. The layers included in the transistor 150 may each have a single-layer structure or a stacked-layer structure.

The conductive layer 120 functions as a back gate electrode of the transistor 150. Here, the back gate electrode of the transistor 150 may be formed using the same material in the same step as the conductive layer 112b. The transistor 150 does not necessarily include the conductive layer 120.

The insulating layer 121 is provided to cover the top surface and a side surface of the conductive layer 120. The insulating layer 121 functions as a back gate insulating layer of the transistor 150. The insulating layer 121 is a layer including a region in contact with a channel formation region in the semiconductor layer 108a and thus is preferably an insulating layer including oxygen. The insulating layer 121 can be formed using a material that can be used for the insulating layer 110b, for example.

The semiconductor layer 108a is provided over the insulating layer 121. The semiconductor layer 108a includes a region overlapping with the conductive layer 120 with the insulating layer 121 therebetween.

An end portion of the semiconductor layer 108a is positioned on the top surface of the insulating layer 121 in the example illustrated in FIG. 20A, and the semiconductor layer 108a covers the top surface and a side surface of the insulating layer 121 in the example illustrated in FIG. 20B.

The semiconductor layer 108a can be formed using the same material in the same step as the semiconductor layer 108.

Here, the semiconductor layer 108 and the semiconductor layer 108a may be formed using the same material. For the semiconductor layer 108 and the semiconductor layer 108a, materials with different compositions may be used. For example, In—Ga—Zn oxides having the same composition may be used for the semiconductor layer 108 and the semiconductor layer 108a. In—Ga—Zn oxides may be used for the semiconductor layer 108 and the semiconductor layer 108a; the proportion of the number of In atoms in one of the metal oxides may be higher than that in the other. In—Ga—Zn oxide may be used for one of the semiconductor layer 108 and the semiconductor layer 108a, and In—Zn oxide may be used for the other. The material used for the semiconductor layer 108 may be different from the material used for the semiconductor layer 108a. When the semiconductor layer 108 and the semiconductor layer 108a are formed in different steps, for example, the material included in the semiconductor layer 108 and the material included in the semiconductor layer 108a can be different from each other.

The insulating layer 106 is provided to cover the insulating layer 121 and the semiconductor layer 108a. The insulating layer 106 functions as a gate insulating layer of the transistor 150.

The conductive layer 104a is provided over the insulating layer 106. The conductive layer 104a includes a region overlapping with the semiconductor layer 108a with the insulating layer 106 therebetween. The conductive layer 104a functions as the gate electrode of the transistor 150. The conductive layer 104a can be formed using the same material in the same step as the conductive layer 104.

In FIG. 20A, the insulating layer 109 is provided to cover the conductive layer 104a, and the conductive layer 107a and the conductive layer 107b are provided over the insulating layer 109. The conductive layer 107a and the conductive layer 107b include regions in contact with the semiconductor layer 108a in openings provided in the insulating layer 106 and the insulating layer 109.

FIG. 20B illustrates an example in which the conductive layer 107a and the conductive layer 107b are formed using the same material in the same step as the conductive layer 104a and the conductive layer 104. The conductive layer 107a and the conductive layer 107b include regions in contact with the semiconductor layer 108a in openings provided in the insulating layer 106.

One of the conductive layer 107a and the conductive layer 107b functions as the source electrode and the other functions as the drain electrode of the transistor 150.

The transistor 150 is what is called a top-gate transistor including the gate electrode above the semiconductor layer 108a. For example, when an impurity element is added to the semiconductor layer 108a with the conductive layer 104a, which serves as the gate electrode, used as a mask, a source region and a drain region can be formed in a self-aligned manner. The transistor 150 can be referred to as a TGSA (Top Gate Self-Aligned) transistor.

The channel length of the transistor 150 can be controlled by the width of the conductive layer 104a in the channel length direction. Accordingly, the channel length of the transistor 150 is greater than or equal to the definition limit of a light exposure apparatus used for manufacturing the transistor. The transistor with a large channel length can have favorable saturation characteristics.

In manufacturing the semiconductor device 10, the transistor 100 with a small channel length and the transistor 150 with a large channel length can be formed over the same substrate by the formation steps some of which are shared. For example, when the transistor 100 is used as the transistor required to have a high on-state current and the transistor 150 is used as the transistor required to have favorable saturation characteristics, the semiconductor device can achieve high performance.

### [Semiconductor Device 10A]

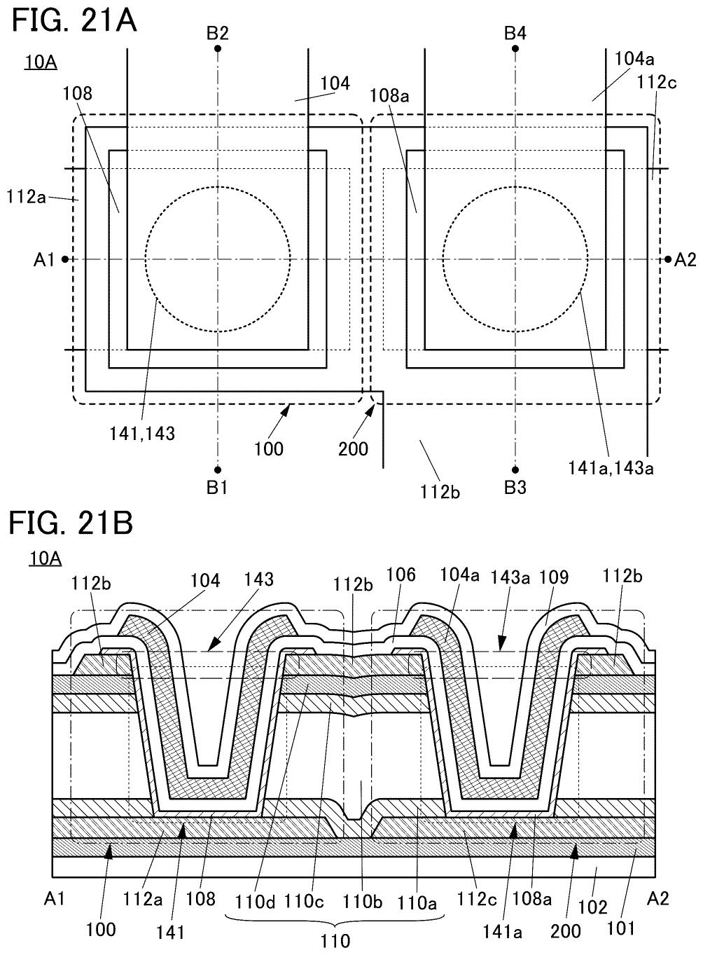

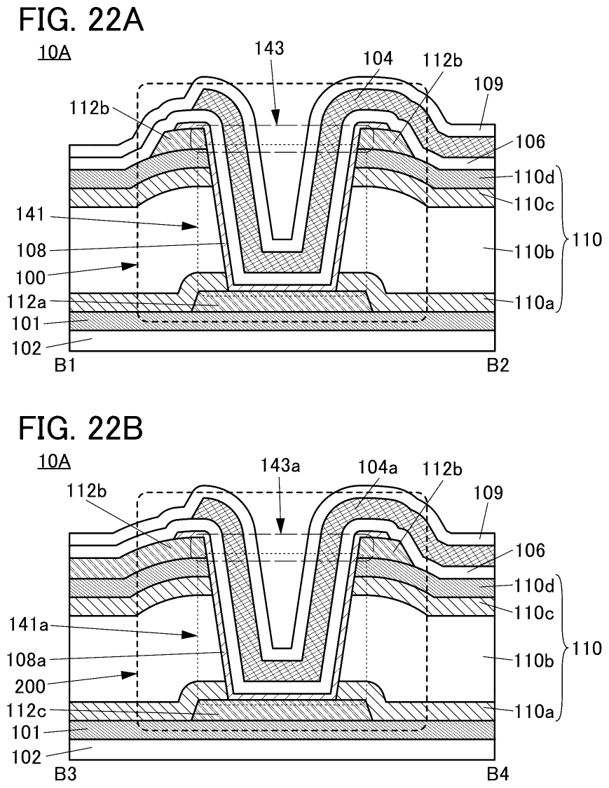

FIG. 21A is a plan view illustrating a structure example of a semiconductor device 10A of one embodiment of the present invention. FIG. 21B is a cross-sectional view along dashed-dotted line A1-A2 in FIG. 21A, FIG. 22A is a cross-sectional view along dashed-dotted line B1-B2 in FIG. 21A, and FIG. 22B is a cross-sectional view along dashed-dotted line B3-B4 in FIG. 21A. The semiconductor device 10A has the circuit structure illustrated in FIG. 19A. In the example illustrated in FIG. 21A, FIG. 21B, and FIG. 22A, the transistor 100 has the structure illustrated in FIG. 6A to FIG. 6C. Note that in the semiconductor device 10A, the insulating layer 101 may have the structure illustrated in any of FIG. 9A to FIG. 10C. The insulating layer 110 may have the structure illustrated in FIG. 1A to FIG. 1C.

The transistor 200 included in the semiconductor device 10A includes a conductive layer 112c, the semiconductor layer 108a, the conductive layer 112b, the insulating layer 106, and the conductive layer 104a.

The conductive layer 112c functions as one of a source electrode and a drain electrode of the transistor 200. The conductive layer 112c can be formed using the same material in the same step as the conductive layer 112a.

In the semiconductor device 10A, the insulating layer 110 is provided with an opening 141a reaching the conductive layer 112c, and the conductive layer 112b is provided with an opening 143a including a region overlapping with the opening 141a. The semiconductor layer 108a, the insulating layer 106, and the conductive layer 104a are each provided to include a region positioned in the opening 141a and a region positioned in the opening 143a.

The semiconductor layer 108a can be formed using the same material in the same step as the semiconductor layer 108. Alternatively, the semiconductor layer 108 and the semiconductor layer 108a may be formed using different materials in different steps. For the structures of the semiconductor layer 108 and the semiconductor layer 108a, the description of the semiconductor layer of the semiconductor device 10 can be referred to.

The conductive layer 112b functions as the other of the source electrode and the drain electrode of the transistor 100 and the other of the source electrode and the drain electrode of the transistor 200. Since the transistor 100 and the transistor 200 share the conductive layer 112b, the semiconductor device occupies a smaller area.

The conductive layer 104a functions as a gate electrode of the transistor 200. The conductive layer 104a can be formed using the same material in the same step as the conductive layer 104.

The shape of the opening 141a can be similar to the shape that the opening 141 can have. The shape of the opening 143a can be similar to the shape that the opening 143 can have. The shape and size (e.g., diameter) of the opening 141 provided in the insulating layer 110 may be the same as or different from those of the opening 141a provided in the insulating layer 110. Likewise, the shape and size (e.g., diameter) of the opening 143 provided in the conductive layer 112b may be the same as or different from those of the opening 143a provided in the conductive layer 112b.

### [Semiconductor Device 10B]

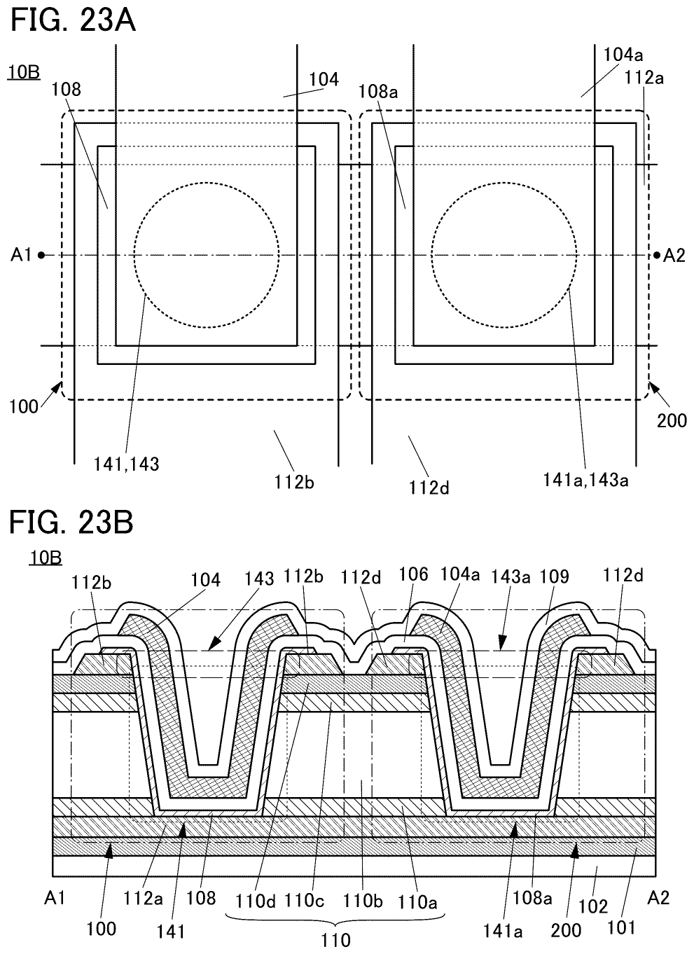

FIG. 23A is a plan view illustrating a structure example of a semiconductor device 10B of one embodiment of the present invention. FIG. 23B is a cross-sectional view along dashed-dotted line A1-A2 in FIG. 23A. The semiconductor device 10B has the circuit structure illustrated in FIG. 19A. In the example illustrated in FIG. 23A and FIG. 23B, the transistor 100 has the structure illustrated in FIG. 6A to FIG. 6C. Note that in the semiconductor device 10B, the insulating layer 101 may have the structure illustrated in any of FIG. 9A to FIG. 10C. The insulating layer 110 may have the structure illustrated in FIG. 1A to FIG. 1C.

The transistor 200 included in the semiconductor device 10B includes the conductive layer 112a, the semiconductor layer 108a, a conductive layer 112d, the insulating layer 106, and the conductive layer 104a.

The conductive layer 112a functions as the one of the source electrode and the drain electrode of the transistor 100 and the one of the source electrode and the drain electrode of the transistor 200. Since the transistor 100 and the transistor 200 share the conductive layer 112a, the semiconductor device occupies a smaller area.

The conductive layer 112d functions as the other of the source electrode and the drain electrode of the transistor 200. The conductive layer 112d can be formed using the same material in the same step as the conductive layer 112b.

The conductive layer 104a functions as the gate electrode of the transistor 200. The conductive layer 104a can be formed using the same material in the same step as the conductive layer 104.

In each of the examples illustrated in FIG. 21A, FIG. 21B, FIG. 22B, FIG. 23A, and FIG. 23B, the transistor 200 has a structure similar to that of the transistor 100. Note that the transistor 200 may have a structure similar to that of any of the transistor 100A to the transistor 100H described above. The structure of the transistor 200 described above can also be applied to the transistor 200 illustrated in FIG. 19B.

### <Manufacturing Method Example of Semiconductor Device>

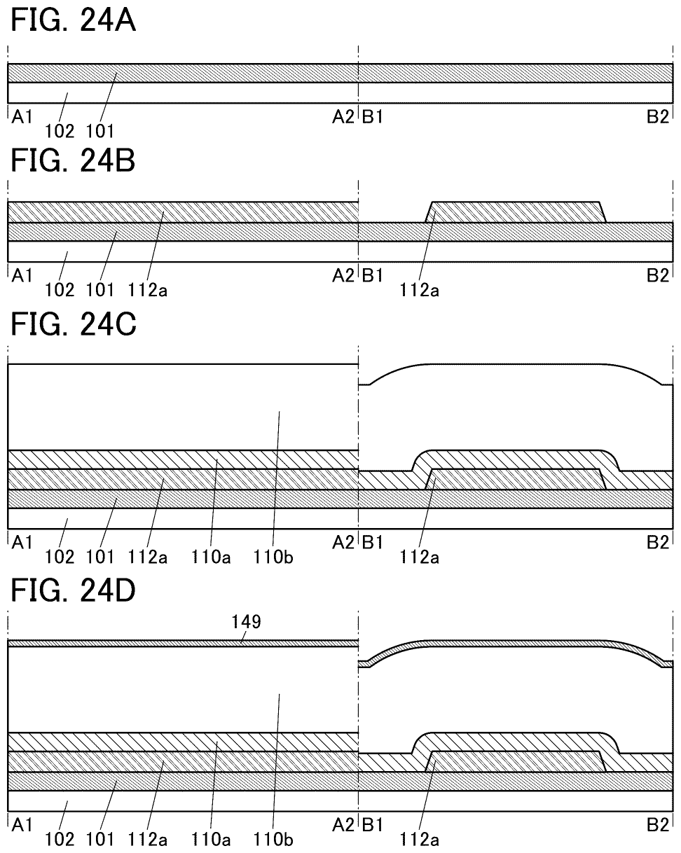

An example of a method for manufacturing the semiconductor device illustrated in FIG. 6B and FIG. 6C will be described below with reference to FIG. 24A to FIG. 27B. FIG. 24A to FIG. 27B each illustrate a cross-sectional view along dashed-dotted line A1-A2 and a cross-sectional view along dashed-dotted line B1-B2 in FIG. 6A side by side.

Thin films included in the semiconductor device (e.g., insulating films, semiconductor films, and conductive films) can be formed by a sputtering method, a CVD method, a vacuum evaporation method, a pulsed laser deposition (PLD) method, an ALD method, or the like. Examples of a CVD method include a PECVD method and a thermal CVD method. An example of the thermal CVD method is a metal organic chemical vapor deposition (MOCVD: Metal Organic CVD) method.

Thin films included in the semiconductor device (e.g., insulating films, semiconductor films, and conductive films) can be formed by a wet film-formation method such as a spin coating method, a dip coating method, a spray coating method, an ink-jet method, dispensing, screen printing, offset printing, a doctor knife method, slit coating, roll coating, curtain coating, or knife coating.

The thin films can be processed by, for example, etching of the thin films in accordance with a pattern of a resist mask that has been formed by a photolithography method. Alternatively, a nanoimprinting method, a sandblasting method, a lift-off method, or the like may be used for the processing of the thin films. Alternatively, island-shaped thin films may be directly formed by a film formation method using a shielding mask such as a metal mask. A photosensitive thin film can be processed by light exposure and development. That is, the photosensitive thin film can be processed by a photolithography method.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. EUV light, X-rays, or an electron beam is preferably used to enable extremely minute processing. Note that a photomask is not needed when light exposure is performed by scanning with a beam such as an electron beam.

For etching of thin films, a dry etching method, a wet etching method, or the like can be used.

First, the insulating layer 101 is formed over the substrate 102 (FIG. 24A). As described above, the insulating layer 101 includes hydrogen. The insulating layer 101 is formed to include a region where the hydrogen content is higher than or equal to the hydrogen content of the insulating layer 110a formed in a later step, for example. The insulating layer 101 and the insulating layer 110a can be formed by a CVD method, for example, or specifically, a PECVD method. Note that the insulating layer 101 and the insulating layer 110a can also be formed by a sputtering method, for example.

For each of the insulating layer 101 and the insulating layer 110a, a nitride insulating film can be formed as described above, for example; specifically, a silicon nitride film or a silicon nitride oxide film can be formed. When a nitride insulating film is used for each of the insulating layer 101 and the insulating layer 110a, the region that is included in the conductive layer 112a formed in a later step and that is in contact with the insulating layer 101, a region in the vicinity thereof, the region that is included in the conductive layer 112a and that is in contact with the insulating layer 110a, and a region in the vicinity thereof can be inhibited from being oxidized and having high resistance.

The proportion of molecules containing hydrogen in a film formation gas for the insulating layer 101 is preferably higher than or equal to the proportion of molecules containing hydrogen in a film formation gas for the insulating layer 110a. For example, in the case where a NH₃ gas is used as a nitrogen source included in each of the film formation gas for the insulating layer 101 and the film formation gas for the insulating layer 110a, the proportion of the flow rate of the NH₃ gas in the film formation gas for the insulating layer 101 is preferably higher than or equal to the proportion of the flow rate of the NH₃ gas in the film formation gas for the insulating layer 110a. The film formation gas for the insulating layer 110a does not necessarily contain a NH₃ gas. For example, in the case where an insulating film other than a nitride insulating film, such as an oxide insulating film, is formed for the insulating layer 110a, the film formation gas for the insulating layer 110a does not necessarily contain a NH₃ gas.

When the insulating layer 101 is formed under the conditions where the proportion of the flow rate of, for example, a NH₃ gas in the whole film formation gas is high, the insulating layer 101 can have a high hydrogen content. In that case, the amount of hydrogen in the insulating layer 101 to be released by heating can be increased.

The amount of hydrogen in the insulating layer 101 to be released by heating can be adjusted by making the film formation conditions for the insulating layer 101 different from those for the insulating layer 110a. Specifically, the film formation conditions for the insulating layer 101 may be different from those for the insulating layer 110a in any one or more of film formation power (film formation power density), a film formation pressure, the kind of a film formation gas, the flow rate ratio of a film formation gas, a film formation temperature, and the distance between the substrate and an electrode.

The substrate temperature at the time of forming the insulating layer 101 and the substrate temperature at the time of forming the insulating layer 110a are each preferably higher than or equal to 150° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., and are each typically 350° C. When the substrate temperature at the time of forming the insulating layer 101 and the substrate temperature at the time of forming the insulating layer 110a are in the above range, the amount of hydrogen released from the insulating layer 101 and the amount of hydrogen released from the insulating layer 110a can be favorably controlled, for example. This can inhibit supply of an excessively large amount of hydrogen from the insulating layer 101 to the semiconductor layer 108 and supply of an excessively large amount of hydrogen from the insulating layer 110a to the semiconductor layer 108, for example, and a reduction in the threshold voltage of the transistor 100, that is, a negative shift of the threshold voltage. This can reduce a cutoff current, so that the transistor can have normally-off characteristics. Thus, the reliability of the transistor 100 can be increased, and the reliability of the semiconductor device of one embodiment of the present invention can be increased.

Next, the conductive layer 112a is formed over the insulating layer 101 (FIG. 24B). For example, the conductive film to be the conductive layer 112a is formed over the insulating layer 101 and processed, so that the conductive layer 112a can be formed. The conductive film to be the conductive layer 112a can be formed by a sputtering method, for example. After a resist mask is formed over the conductive film by a photolithography step, the conductive film is processed using one or both of a wet etching method and a dry etching method, for example, so that the conductive layer 112a can be formed. As the conductive layer 112a, a conductive layer having a stacked-layer structure of a layer including copper and a layer thereover including indium tin oxide containing silicon can be formed, for example.

Next, the insulating layer 110a is formed over the conductive layer 112a and the insulating layer 101. For example, the insulating layer 110a is formed to include a region in contact with the top surface of the insulating layer 101, a region in contact with the top surface of the conductive layer 112a, and a region in contact with the side surface of the conductive layer 112a. After that, the insulating layer 110b is formed over the insulating layer 110a (FIG. 24C).

For example, the film formation conditions for the insulating layer 110a are as described above. The insulating layer 110a is formed to include a region where the hydrogen content is lower than or equal to the hydrogen content of the insulating layer 101, for example. It is preferable that the proportion of molecules containing hydrogen in the film formation gas for the insulating layer 110a be, for example, lower than or equal to the proportion of molecules containing hydrogen in the film formation gas for the insulating layer 101. For example, in the case where a NH₃ gas is used as a nitrogen source included in each of the film formation gas for the insulating layer 101 and the film formation gas for the insulating layer 110a, the proportion of the flow rate of the NH₃ gas in the film formation gas for the insulating layer 110a is preferably lower than or equal to the proportion of the flow rate of the NH₃ gas in the film formation gas for the insulating layer 101.

The insulating layer 110a can be formed under conditions such that the insulating layer 110a is less likely to allow hydrogen diffusion than the conductive layer 112a and can be formed under conditions such that the insulating layer 110a is less likely to allow hydrogen diffusion than the insulating layer 110b. The insulating layer 110a can be formed under conditions such that the insulating layer 110a has a lower hydrogen diffusion coefficient than the conductive layer 112a and can be formed under conditions such that the insulating layer 110a has a lower hydrogen diffusion coefficient than the insulating layer 110b, for example.

The insulating layer 110b can be formed by a CVD method, for example, or specifically, a PECVD method. Note that the insulating layer 110b can also be formed by a sputtering method, for example. For the insulating layer 110b, an oxide insulating film can be formed as described above, for example; specifically, a silicon oxide film or a silicon oxynitride oxide film can be formed.

It is preferable that the insulating layer 110b be formed in a vacuum successively after the formation of the insulating layer 110a, without exposure of a surface of the insulating layer 110a to the air. When the insulating layer 110a and the insulating layer 110b are successively formed, impurities derived from the air can be inhibited from being attached to the surface of the insulating layer 110a. Examples of the impurities include water and organic substances.

The substrate temperature at the time of forming the insulating layer 110b is preferably in the above-described range of substrate temperatures at the time of forming the insulating layer 110a. In that case, the amount of impurities (e.g., water and hydrogen) released from the insulating layer 110b can be reduced, so that diffusion of impurities to the channel formation region of the semiconductor layer 108 can be inhibited. Consequently, the transistor can be manufactured to have favorable electrical characteristics and high reliability.

Note that since the insulating layer 101, the insulating layer 110a, and the insulating layer 110b are formed earlier than the semiconductor layer 108, there is no need to consider the probability of oxygen release from the semiconductor layer 108 due to heat applied thereto at the time of forming the insulating layer 101, the insulating layer 110a, and the insulating layer 110b.

After the insulating layer 110b is formed, treatment for supplying oxygen to the insulating layer 110b is preferably performed. In that case, a large amount of oxygen can be supplied to the semiconductor layer 108 by heat treatment performed later. Thus, the amounts of oxygen vacancies and VoH in the semiconductor layer 108 can be reduced, whereby the transistor can be manufactured to have favorable electrical characteristics and high reliability. Oxygen can be supplied to the insulating layer 110b by, for example, performing plasma treatment in an oxygen-containing atmosphere after the formation of the insulating layer 110b, without exposure to the air (in-situ). For example, N₂O plasma treatment is preferably performed.

Next, a metal oxide layer 149 is preferably formed over the insulating layer 110b (FIG. 24D). The formation of the metal oxide layer 149 enables oxygen supply to the insulating layer 110b.

There is no limitation on the conductivity of the metal oxide layer 149. For the metal oxide layer 149, at least one of an insulating film, a semiconductor film, and a conductive film can be used. For the metal oxide layer 149, aluminum oxide, hafnium oxide, hafnium aluminate, indium oxide, indium tin oxide, or indium tin oxide containing silicon can be used, for example.

An oxide material containing one or more elements contained in the semiconductor layer 108 is preferably used for the metal oxide layer 149. It is particularly preferable to use a metal oxide material that can be used for the semiconductor layer 108.

At the time of forming the metal oxide layer 149, a larger amount of oxygen can be supplied into the insulating layer 110b with a higher proportion of the oxygen flow rate to the total flow rate of the film formation gas introduced into a treatment chamber of a film formation apparatus (i.e., with a higher oxygen flow rate ratio), or with a higher oxygen partial pressure in the treatment chamber. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 149 is formed by a sputtering method in an oxygen-containing atmosphere in the above manner, oxygen can be supplied to the insulating layer 110b and release of oxygen from the insulating layer 110b can be prevented during the formation of the metal oxide layer 149. As a result, a large amount of oxygen can be enclosed in the insulating layer 110b. Moreover, a large amount of oxygen can be supplied to the semiconductor layer 108 by heat treatment performed later. Thus, the amounts of oxygen vacancies and VoH in the semiconductor layer 108 can be reduced, whereby the transistor can be manufactured to have favorable electrical characteristics and high reliability.

Heat treatment is preferably performed after the metal oxide layer 149 is formed. By the heat treatment performed after the formation of the metal oxide layer 149, oxygen can be favorably supplied from the metal oxide layer 149 to the insulating layer 110b.

The temperature of the heat treatment is preferably higher than or equal to 150° C. and lower than the strain point of the substrate, further preferably higher than or equal to 150° C. and lower than or equal to 450° C., still further preferably higher than or equal to 150° C. and lower than or equal to 350° C., yet still further preferably higher than or equal to 200° C. and lower than or equal to 300° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of each of hydrogen, water, and the like in the atmosphere is preferably as low as possible. As the atmosphere, a high-purity gas with a dew point lower than or equal to −60° C. is preferably used, and a high-purity gas with a dew point lower than or equal to −100° C. is further preferably used. With use of an atmosphere where the content of each of hydrogen, water, and the like is as low as possible, entry of hydrogen, water, and the like into the insulating layer 110b and the like can be prevented as much as possible. An oven, a rapid thermal annealing (RTA) apparatus, or the like can be used for the heat treatment. With the RTA apparatus, the heat treatment time can be shortened.

After the formation of the metal oxide layer 149 or the above-described heat treatment, oxygen may be further supplied to the insulating layer 110b through the metal oxide layer 149. Oxygen can be supplied by, for example, an ion implantation method, an ion doping method, a plasma immersion ion implantation method, or plasma treatment. For the plasma treatment in the method for manufacturing the semiconductor device of one embodiment of the present invention, an apparatus in which an oxygen gas is made to be plasma by high-frequency power can be suitably used. Examples of an apparatus in which a gas is made to be plasma by high-frequency power include a plasma etching apparatus and a plasma ashing apparatus.

Heat treatment may be performed after the formation of the insulating layer 101, the insulating layer 110a, and the insulating layer 110b but before the formation of the metal oxide layer 149. The temperature of the heat treatment is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 350° C. and lower than or equal to 450° C. By performing the heat treatment, water and hydrogen can be released from the surface and inside of the insulating layer 110b. Consequently, the transistor can be manufactured to have favorable electrical characteristics and high reliability.

Then, the metal oxide layer 149 is removed.

There is no particular limitation on a method for removing the metal oxide layer 149, and a wet etching method can be suitably used. When a wet etching method is used, the insulating layer 110b can be inhibited from being etched at the time of the removal of the metal oxide layer 149. In that case, a reduction in the thickness of the insulating layer 110b can be inhibited and the thickness of the insulating layer 110b can be uniform.

The treatment for supplying oxygen to the insulating layer 110b is not necessarily performed in the above-described manner. For example, an ion doping method, an ion implantation method, or plasma treatment can be employed to supply an oxygen radical, an oxygen atom, an oxygen atomic ion, an oxygen molecular ion, or the like to the insulating layer 110b. Furthermore, a film that suppresses oxygen release may be formed over the insulating layer 110b and then, oxygen may be supplied to the insulating layer 110b through the film. After the supply of oxygen, the film is preferably removed. The film that suppresses oxygen release can be a conductive film or a semiconductor film including one or more of indium, zinc, gallium, tin, aluminum, chromium, tantalum, titanium, molybdenum, nickel, iron, cobalt, and tungsten.

The formation and removal of the metal oxide layer 149 are not necessarily performed. For example, in the case where oxygen can be sufficiently supplied to the insulating layer 110b by the above method, the formation and removal of the metal oxide layer 149 are not necessarily performed.

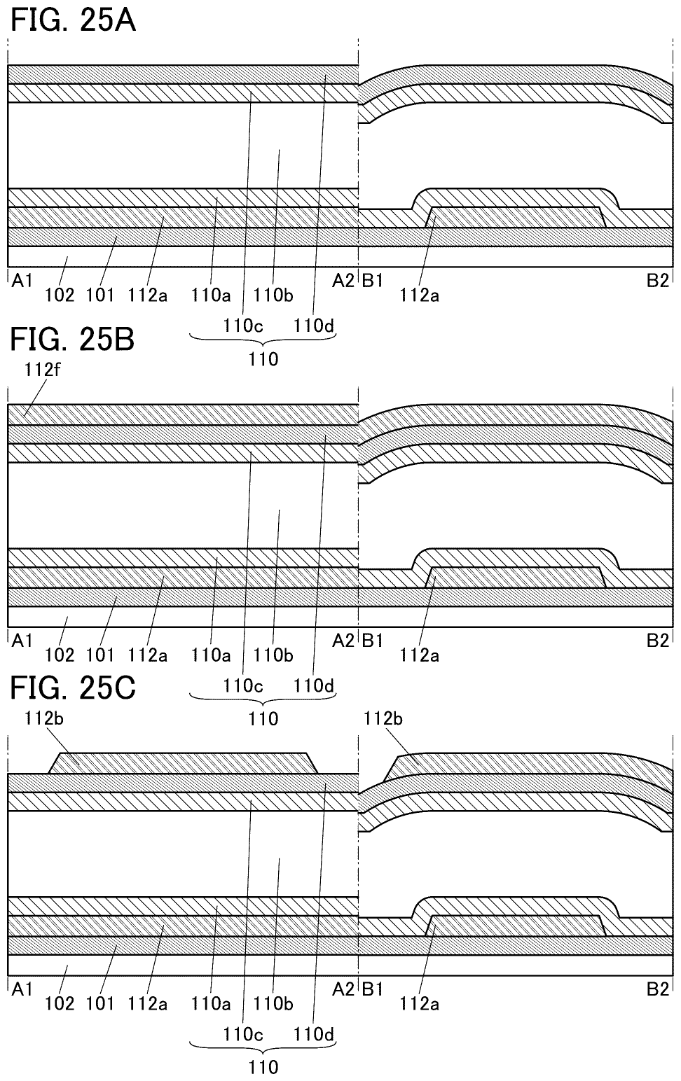

Next, the insulating layer 110c is formed over the insulating layer 110b. After that, the insulating layer 110d is formed over the insulating layer 110c (FIG. 25A). Accordingly, the insulating layer 110 including the insulating layer 110a, the insulating layer 110b, the insulating layer 110c, and the insulating layer 110d is formed. The insulating layer 110c and the insulating layer 110d can be formed by a CVD method, for example, or specifically, a PECVD method. Note that the insulating layer 110c and the insulating layer 110d can also be formed by a sputtering method, for example.

The insulating layer 110c can be formed under conditions such that the insulating layer 110c is less likely to allow hydrogen diffusion than the conductive layer 112b formed in a later step and can be formed under conditions such that the insulating layer 110c is less likely to allow hydrogen diffusion than the insulating layer 110b. The insulating layer 110c can be formed under conditions such that the insulating layer 110c has a lower hydrogen diffusion coefficient than the conductive layer 112b and can be formed under conditions such that the insulating layer 110c has a lower hydrogen diffusion coefficient than the insulating layer 110b, for example.

The insulating layer 110d includes hydrogen as described above. The insulating layer 110d is formed to include a region where the hydrogen content is higher than or equal to the hydrogen content of the insulating layer 110c, for example.

The insulating layer 110c can be formed to include a material that is the same as the material included in the insulating layer 110a. For example, the insulating layer 110c can be formed using the same material as the insulating layer 110a. In that case, the insulating layer 110c can be formed under the same conditions as the insulating layer 110a. Note that when the film formation time of the insulating layer 110c and the film formation time of the insulating layer 110a are made different from each other, for example, the thickness of the insulating layer 110c and the thickness of the insulating layer 110a can be made different from each other.

The insulating layer 110d can include a material that is the same as the material included in the insulating layer 101. For example, the insulating layer 110d can be formed using the same material as the insulating layer 101. In the case where the insulating layer 110d is formed using the same material as the insulating layer 101 and the hydrogen content per unit volume of the insulating layer 101 and the hydrogen content per unit volume of the insulating layer 110d are substantially the same, the insulating layer 110d can be formed under the same conditions as the insulating layer 110c. Note that when the film formation time of the insulating layer 110d and the film formation time of the insulating layer 101 are made different from each other, for example, the thickness of the insulating layer 110d and the thickness of the insulating layer 101 can be made different from each other.

For each of the insulating layer 110c and the insulating layer 110d, a nitride insulating film can be formed as described above, for example; specifically, a silicon nitride film or a silicon nitride oxide film can be formed. When a nitride insulating film is used for each of the insulating layer 110c and the insulating layer 110d, the region that is included in the conductive layer 112b formed in a later step and that is in contact with the insulating layer 110c, a region in the vicinity thereof, the region that is included in the conductive layer 112b and that is in contact with the insulating layer 110d, and a region in the vicinity thereof can be inhibited from being oxidized and having high resistance.

The proportion of molecules containing hydrogen in a film formation gas for the insulating layer 110d is preferably higher than or equal to the proportion of molecules containing hydrogen in a film formation gas for the insulating layer 110c. For example, in the case where a NH₃ gas is used as a nitrogen source included in each of the film formation gas for the insulating layer 110c and the film formation gas for the insulating layer 110d, the proportion of the flow rate of the NH₃ gas in the film formation gas for the insulating layer 110d is preferably higher than or equal to the proportion of the flow rate of the NH₃ gas in the film formation gas for the insulating layer 110c. The film formation gas for the insulating layer 110c does not necessarily contain a NH₃ gas. For example, in the case where an insulating film other than a nitride insulating film, such as an oxide insulating film, is formed for the insulating layer 110c, the film formation gas for the insulating layer 110c does not necessarily contain a NH₃ gas.

When the insulating layer 110d is formed under the conditions where the proportion of the flow rate of, for example, a NH₃ gas in the whole film formation gas is high, the insulating layer 110d can have a high hydrogen content. In that case, the amount of hydrogen in the insulating layer 110d to be released by heating can be increased.

The amount of hydrogen in the insulating layer 110d to be released by heating can be adjusted by making the film formation conditions for the insulating layer 110d different from those for the insulating layer 110c. Specifically, the film formation conditions for the insulating layer 110d may be different from those for the insulating layer 110c in any one or more of film formation power (film formation power density), a film formation pressure, the kind of a film formation gas, the flow rate ratio of a film formation gas, a film formation temperature, and the distance between the substrate and an electrode.

The substrate temperature at the time of forming the insulating layer 110c and the substrate temperature at the time of forming the insulating layer 110d can be respectively in the above-described possible range of substrate temperatures at the time of forming the insulating layer 110a and the above-described possible range of substrate temperatures at the time of forming the insulating layer 101. In that case, the reliability of the transistor 100 can be increased, and the reliability of the semiconductor device of one embodiment of the present invention can be increased.

Next, a conductive film 112f to be the conductive layer 112b is formed over the insulating layer 110d (FIG. 25B). For example, the conductive film 112f is formed to include a region in contact with the top surface of the insulating layer 110d. For the formation of the conductive film 112f, for example, a sputtering method is suitable. Then, the conductive film 112f is processed into a desired shape, so that the conductive layer 112b is formed over the insulating layer 110d (FIG. 25C). For example, the conductive layer 112b is formed to include a region in contact with the top surface of the insulating layer 110d.

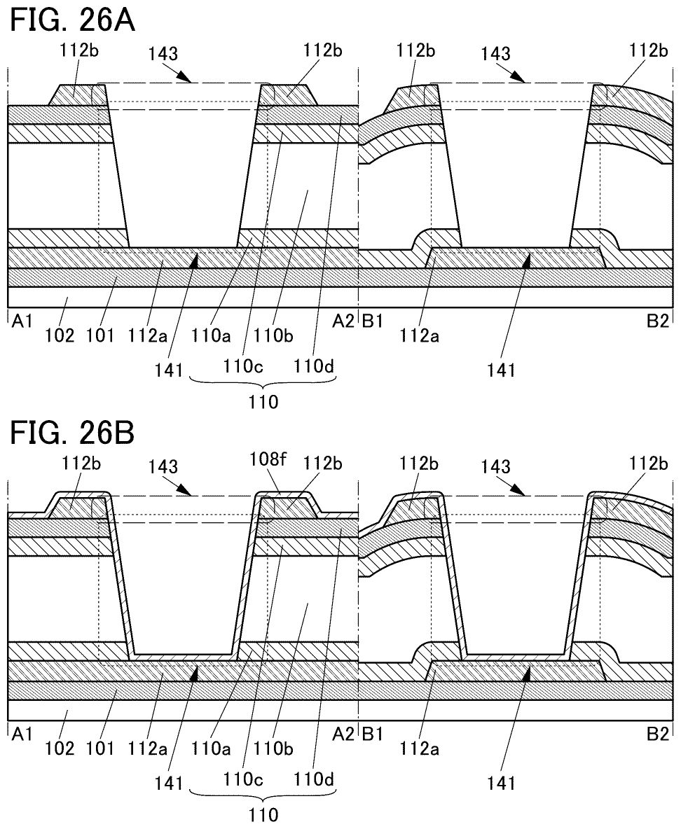

Then, the conductive layer 112b is processed to form the opening 143 (FIG. 26A). The opening 143 is formed to include a region overlapping with the conductive layer 112a. Note that the conductive layer 112b provided with the opening 143 may be formed in the following manner: the opening 143 is formed in the conductive film 112f, and then, the conductive film 112f is processed into a desired shape.

Next, the insulating layer 110d, the insulating layer 110c, the insulating layer 110b, and the insulating layer 110a are processed to form the opening 141 (FIG. 26A). The opening 141 is formed to include a region overlapping with the opening 143 and to reach the conductive layer 112a. The formation of the opening 141 exposes the region of the conductive layer 112a that overlaps with the opening 141 and the opening 143.

The conductive film 112f can be processed by one or both of a wet etching method and a dry etching method. A wet etching method is particularly suitable for the formation of the opening 143.

For the formation of the opening 141, one or both of a wet etching method and a dry etching method can be used, and for example, a dry etching method can be suitably used.

The opening 141 can be formed using, for example, the resist mask used for the formation of the opening 143. For example, after the conductive layer 112b is formed, a resist mask is formed over the conductive layer 112b, and the conductive layer 112b is partly removed using the resist mask to form the opening 143. Then, the insulating layer 110d, the insulating layer 110c, the insulating layer 110b, and the insulating layer 110a are partly removed using the resist mask, so that the opening 141 can be formed. The opening 141 and the opening 143 may be formed using different resist masks.

Subsequently, a semiconductor film 108f to be the semiconductor layer 108 is formed to cover the opening 141 and the opening 143 (FIG. 26B). The semiconductor film 108f is formed to include a region in contact with the top surface of the conductive layer 112a, a region in contact with the side surface of the insulating layer 110, a region in contact with the side surface of the conductive layer 112b, a region in contact with the top surface of the conductive layer 112b, and a region in contact with the top surface of the insulating layer 110.

The semiconductor film 108f is preferably formed to have a thickness as uniform as possible, at the side surface of the insulating layer 110 on the opening 141 side and the side surface of the conductive layer 112b on the opening 143 side. The semiconductor film 108f can be formed by, for example, a sputtering method or an ALD method.

The semiconductor film 108f is preferably formed by a sputtering method using a metal oxide target.

The semiconductor film 108f is preferably a dense film with as few defects as possible. The semiconductor film 108f is preferably a high-purity film in which impurities containing hydrogen elements are reduced as much as possible. It is particularly preferable to use a metal oxide film having crystallinity as the semiconductor film 108f.

In forming the semiconductor film 108f, an oxygen gas is preferably used. In the case of using an oxygen gas at the time of forming the semiconductor film 108f, oxygen can be favorably supplied into the insulating layer 110. For example, in the case where an oxide is used for the insulating layer 110b, oxygen can be favorably supplied into the insulating layer 110b.

The oxygen supply to the insulating layer 110b enables the semiconductor layer 108 to be supplied with oxygen in a later step, so that the amounts of oxygen vacancies and VoH in the semiconductor layer 108 can be reduced.

In forming the semiconductor film 108f, an oxygen gas and an inert gas (such as a helium gas, an argon gas, or a xenon gas) may be mixed. Note that when the proportion of an oxygen gas in the whole film formation gas (an oxygen flow rate ratio) is higher at the time of forming the semiconductor film 108f, the crystallinity of the semiconductor film 108f can be higher and the transistor can have higher reliability. By contrast, when the oxygen flow rate ratio is lower, the crystallinity of the semiconductor film 108f is lower and the transistor can have a higher on-state current.

When the substrate temperature is higher at the time of forming the semiconductor film 108f, a metal oxide film with higher crystallinity and higher density can be obtained. By contrast, when the substrate temperature is lower, the semiconductor film 108f can have lower crystallinity and higher electric conductivity.

The substrate temperature during the formation of the semiconductor film 108f is preferably higher than or equal to room temperature and lower than or equal to 250° C., further preferably higher than or equal to room temperature and lower than or equal to 200° C., still further preferably higher than or equal to room temperature and lower than or equal to 140° C. For example, the substrate temperature is preferably set to be higher than or equal to room temperature and lower than or equal to 140° C. to increase the productivity. When the semiconductor film 108f is formed with the substrate temperature set at room temperature or without heating the substrate, the semiconductor film 108f can have low crystallinity.

In the case of employing an ALD method, a film formation method such as a thermal ALD method or PEALD (Plasma Enhanced ALD) is preferably employed. A thermal ALD method is preferable because it offers extremely high step coverage. A PEALD method is preferable because it can form a film at low temperatures in addition to offering high step coverage.

The semiconductor film 108f can be formed by an ALD method using an oxidizing agent and a precursor that contains a metal element to constitute the semiconductor film 108f, for example.

Examples of a precursor containing indium include trimethylindium, triethylindium, tris(2,2,6,6-tetramethyl-3,5-heptanedionato)indium, cyclopentadienylindium, indium(III) chloride, and (3-(dimethylamino)propyl)dimethylindium.

Examples of the precursor containing gallium include trimethylgallium, triethylgallium, tris(dimethylamido)gallium, gallium(III) acetylacetonate, tris(2,2,6,6-tetramethyl-3,5-heptanedionato)gallium, dimethylchlorogallium, diethylchlorogallium, and gallium(III) chloride.

Examples of a precursor containing tin include tetramethyltin, tetraethyltin, tetraethenyltin, tetraallyltin, tributylvinyltin, allyltributyltin, tributylstannylacetylene, tributylphenyltin, chlorotrimethyltin, chlorotriethyltin, and tin(IV) chloride.

Examples of a precursor containing zinc include dimethylzinc, diethylzinc, bis(2,2,6,6-tetramethyl-3,5-heptanedionato)zinc, and zinc chloride.

In the case of forming a film of In—Ga—Zn oxide, for example, three precursors of a precursor containing indium, a precursor containing gallium, and a precursor containing zinc can be used. Alternatively, two precursors of a precursor containing indium and a precursor containing gallium and zinc may be used.

Examples of the oxidizing agent include ozone, oxygen, and water.

As an example of a method for controlling the composition of a film to be formed, adjusting the flow rate ratio between the source gases, the flowing time of the source gases, the order in which the source gases flow, or the like is given. By adjusting such conditions, a film whose composition is continuously changed can be formed. Furthermore, films having different compositions can be formed successively.

Before the formation of the semiconductor film 108f, at least one of treatment for desorbing water, hydrogen, an organic substance, and the like adsorbed on a surface of the insulating layer 110, and treatment for supplying oxygen into the insulating layer 110 is preferably performed. For example, heat treatment can be performed at a temperature higher than or equal to 70° C. and lower than or equal to 200° C. in a reduced-pressure atmosphere. Alternatively, plasma treatment in an oxygen-containing atmosphere may be performed. Alternatively, oxygen may be supplied to the insulating layer 110 by performing plasma treatment in an atmosphere containing an oxidizing gas such as dinitrogen monoxide (N₂O). When plasma treatment is performed using a dinitrogen monoxide gas, an organic substance on the surface of the insulating layer 110 can be favorably removed and oxygen can be supplied to the insulating layer 110. The semiconductor film 108f is preferably formed successively after such treatment without exposure of the surface of the insulating layer 110 to the air.

In the case where the semiconductor layer 108 has a stacked-layer structure, it is preferable that after the metal oxide film formed earlier is formed, the next metal oxide film be formed successively without exposure of a surface of the metal oxide film formed earlier to the air

In the case where the semiconductor layer 108 has a stacked-layer structure, all the layers included in the semiconductor layer 108 may be formed by the same film formation method (e.g., a sputtering method or an ALD method) or the layers may be formed by different film formation methods. For example, a first metal oxide film may be formed by a sputtering method and a second metal oxide film may be formed by an ALD method.

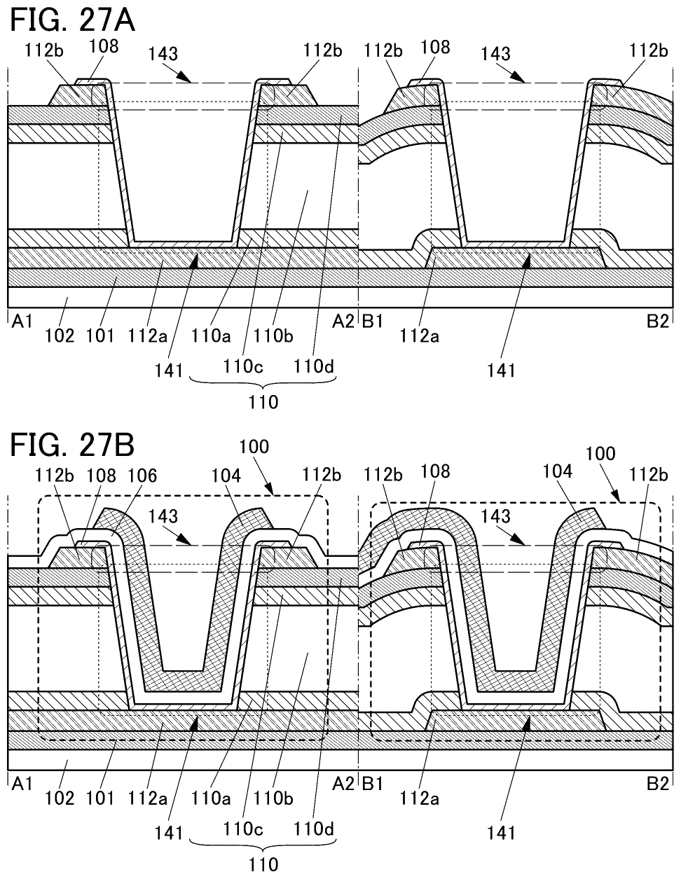

Next, the semiconductor film 108f is processed into an island shape to form the semiconductor layer 108 (FIG. 27A). The semiconductor layer 108 can be formed to include a region positioned in the opening 141 and a region positioned in the opening 143. The semiconductor layer 108 can be formed to include a region in contact with the top surface of the conductive layer 112a, a region in contact with the side surface of the insulating layer 110, a region in contact with the top surface of the conductive layer 112b, and a region in contact with the side surface of the conductive layer 112b.

For the formation of the semiconductor layer 108, one or both of a wet etching method and a dry etching method can be used, and for example, a wet etching method can be suitably used. At this time, part of the conductive layer 112b in the region that does not overlap with the semiconductor layer 108 is etched and thinned in some cases. In a similar manner, part of the insulating layer 110 in the region that does not overlap with the semiconductor layer 108 or the conductive layer 112b is etched and thinned in some cases. For example, in some cases, the insulating layer 110d of the insulating layer 110 is removed by etching and a surface of the insulating layer 110c is exposed. Note that in etching of the semiconductor film 108f, a reduction in the thickness of the insulating layer 110d can be inhibited when the insulating layer 110d is formed using a material having high etching selectivity with respect to the semiconductor film 108f.

It is preferable that heat treatment be performed after the semiconductor film 108f is formed or after the semiconductor film 108f is processed into the semiconductor layer 108. By the heat treatment, hydrogen or water contained in the semiconductor film 108f or the semiconductor layer 108 or adsorbed on a surface of the semiconductor film 108f or the semiconductor layer 108 can be removed. Furthermore, the film quality of the semiconductor film 108f or the semiconductor layer 108 is improved (e.g., the number of defects is reduced or the crystallinity is increased) by the heat treatment in some cases. It is further preferable that the heat treatment be performed before the semiconductor film 108f is processed into the semiconductor layer 108.

It is preferable that the heat treatment cause oxygen supply from the insulating layer 110b to at least part of the semiconductor film 108f or at least part of the semiconductor layer 108. The region of the semiconductor layer 108 that is in contact with the insulating layer 110b and the vicinity of the region function as the channel formation region. Oxygen supply to the region reduces the amount of oxygen vacancies in the channel formation region and lowers the carrier concentration therein. In other words, the channel formation region can be an i-type (intrinsic) or substantially i-type region. Accordingly, the transistor can have stable electrical characteristics.

By the heat treatment, the hydrogen included in the insulating layer 101 is transmitted through the conductive layer 112a and can be supplied to the region of the semiconductor film 108f or the semiconductor layer 108 that is in contact with the conductive layer 112a and a region in the vicinity thereof. This can reduce the contact resistance between the semiconductor layer 108 and the conductive layer 112a. By the heat treatment, the hydrogen included in the insulating layer 110d is transmitted through the conductive layer 112b and can be supplied to the region of the semiconductor film 108f or the semiconductor layer 108 that is in contact with the conductive layer 112b and a region in the vicinity thereof. This can reduce the contact resistance between the semiconductor layer 108 and the conductive layer 112b. Accordingly, the transistor can be manufactured to have a high on-state current and favorable electrical characteristics. Thus, the semiconductor device can be manufactured to operate at high speed.

The temperature of the heat treatment is preferably higher than or equal to 150° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., and is typically 350° C. For the other heat treatment conditions, the description of the heat treatment after the formation of the metal oxide layer 149 can be referred to.

Note that the heat treatment is not necessarily performed when not needed. The heat treatment is not necessarily performed in this step, and heat treatment performed in a later step may also serve as the heat treatment in this step. In some cases, treatment at high temperatures (e.g., a film formation step) in a later step serves as the heat treatment in this step.

Then, the insulating layer 106 is formed to cover the semiconductor layer 108, the conductive layer 112b, and the insulating layer 110 (FIG. 27B). The insulating layer 106 can be formed over the semiconductor layer 108 to include a region positioned in the opening 141 and a region positioned in the opening 143. The insulating layer 106 can be formed along the side wall of the opening 141 and the side wall of the opening 143 with the semiconductor layer 108 between the insulating layer 106 and the side walls. For the formation of the insulating layer 106, for example, a PECVD method or an ALD method is suitable.

In the case where the semiconductor layer 108 is a metal oxide layer, the insulating layer 106 preferably functions as a barrier film that inhibits diffusion of oxygen. The insulating layer 106 having a function of inhibiting diffusion of oxygen inhibits diffusion of oxygen to the conductive layer 104 from above the insulating layer 106 and thus can inhibit oxidation of the conductive layer 104. Consequently, the transistor can be manufactured to have favorable electrical characteristics and high reliability.

Note that in this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

When the temperature at the time of forming the insulating layer 106 functioning as the gate insulating layer is increased, defects in the insulating layer 106 can be reduced. However, a high temperature at the time of forming the insulating layer 106 sometimes allows release of oxygen from the semiconductor layer 108, which increases the amounts of oxygen vacancies and VoH in the semiconductor layer 108. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, the transistor can be manufactured to have favorable electrical characteristics and high reliability.

Before the formation of the insulating layer 106, a surface of the semiconductor layer 108 may be subjected to plasma treatment. By the plasma treatment, impurities such as water adsorbed on the surface of the semiconductor layer 108 can be reduced. Accordingly, impurities at the interface between the semiconductor layer 108 and the insulating layer 106 can be reduced, enabling formation of a highly reliable transistor. The plasma treatment is particularly favorable in the case where the surface of the semiconductor layer 108 is exposed to the air after the formation of the semiconductor layer 108 but before the formation of the insulating layer 106. The plasma treatment can be performed in an atmosphere of oxygen, ozone, nitrogen, dinitrogen monoxide, argon, or the like. The plasma treatment and the formation of the insulating layer 106 are preferably performed successively without exposure to the air.

A film including a large amount of oxygen is preferably used for the insulating layer 106, in which case oxygen can be supplied from the insulating layer 106 to the semiconductor layer 108. A film that releases oxygen when heated is further preferably used for the insulating layer 106. When the insulating layer 106 releases oxygen by being heated during the manufacturing process of the transistor, the oxygen can be supplied to the semiconductor layer 108. The oxygen supply from the insulating layer 106 to the semiconductor layer 108, particularly to the channel formation region of the semiconductor layer 108, reduces the amount of oxygen vacancies in the semiconductor layer 108, so that the transistor can be manufactured to have favorable electrical characteristics and high reliability.

Then, the conductive layer 104 is formed over the insulating layer 106 (FIG. 27B). Thus, the transistor 100 is formed. The conductive layer 104 can be formed to include a region positioned in the opening 141 and a region facing the semiconductor layer 108 with the insulating layer 106 between the region and the semiconductor layer 108 in the opening 143.

For the formation of a conductive film to be the conductive layer 104, a sputtering method, a thermal CVD method (including an MOCVD method), or an ALD method is suitable, for example. A resist mask is formed over the conductive film by a photolithography process and then, the conductive film is processed, so that the conductive layer 104 with an island shape, which functions as the gate electrode, can be formed.

Next, the insulating layer 109 is formed to cover the conductive layer 104 and the insulating layer 106 (FIG. 6B and FIG. 6C). The insulating layer 109 can be formed by a CVD method, for example, or specifically, a PECVD method. Note that the insulating layer 109 can also be formed by a sputtering method, for example.

Through the above steps, the semiconductor device of one embodiment of the present invention can be manufactured.

This embodiment can be combined with any of the other embodiments or the examples as appropriate. In this specification, in the case where a plurality of structure examples are described in one embodiment, the structure examples can be combined as appropriate.

### Embodiment 2

In this embodiment, display devices of embodiments of the present invention will be described.

The display device of this embodiment can be a high-definition display device or a large-sized display device. Accordingly, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

The display device of this embodiment may have a function of a touch panel. For example, the display device can employ any of a variety of sensing elements (also referred to as sensor elements) that can sense proximity or touch of a sensing target such as a finger.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The mutual capacitive type is preferably used, in which case multiple points can be detected simultaneously.

Examples of a touch panel include an out-cell touch panel, an on-cell touch panel, and an in-cell touch panel. Note that an in-cell touch panel has a structure in which an electrode included in a sensing element is provided on one or both of a substrate supporting a display element and a counter substrate.

### [Display Device 50A]

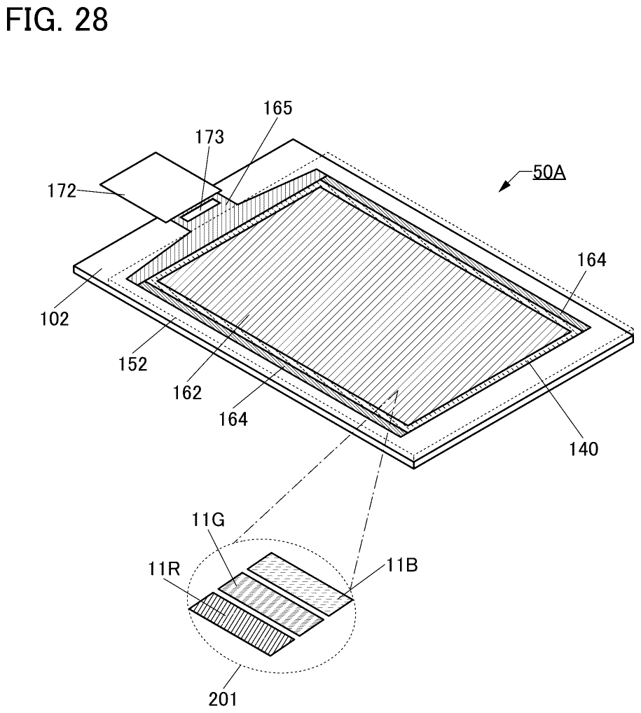

FIG. 28 is a perspective view of a display device 50A.

In the display device 50A, a substrate 152 and the substrate 102 are bonded to each other. In FIG. 28, the substrate 152 is indicated by a dashed line.

The display device 50A includes a display portion 162, a connection portion 140, a circuit portion 164, a conductive layer 165, and the like. FIG. 28 illustrates an example where an IC 173 and an FPC 172 are implemented onto the display device 50A. Thus, the structure illustrated in FIG. 28 can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 28 illustrates an example where the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or from the IC 173.

FIG. 28 illustrates an example where the IC 173 is provided on the substrate 102 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method, for example.

The semiconductor device of one embodiment of the present invention can be used for one or both of the display portion 162 and the circuit portion 164 of the display device 50A, for example.

When the semiconductor device of one embodiment of the present invention is used for a pixel circuit of a display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel, for example. Since the semiconductor device of one embodiment of the present invention has favorable electrical characteristics, a display device can have increased reliability by including the semiconductor device.

The display portion 162 of the display device 50A is a region where an image is to be displayed, and includes a plurality of pixels 201 that are periodically arranged. FIG. 28 illustrates an enlarged view of one of the pixels 201.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 201 illustrated in FIG. 28 includes a subpixel 11R that emits red light, a subpixel 11G that emits green light, and a subpixel 11B that emits blue light. There is no particular limitation on the number of subpixels included in one pixel.

The subpixel 11R, the subpixel 11G, and the subpixel 11B each include a display element and a circuit for controlling the driving of the display element.

Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

Examples of a display device that includes a liquid crystal element include a transmissive liquid crystal display device, a reflective liquid crystal display device, and a transflective liquid crystal display device.

Examples of the mode that can be applied to the display device including a liquid crystal element include a vertical alignment (VA) mode, an FFS (Fringe Field Switching) mode, an IPS (In-Plane-Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of light-emitting elements are self-luminous type light-emitting elements such as an LED (Light Emitting Diode), an OLED (Organic LED), and a semiconductor laser. As the LED, for example, a mini LED, a micro LED, or the like can be used.

Examples of a light-emitting substance included in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of a pair of electrodes of the light-emitting element functions as an anode, and the other electrode functions as a cathode.

The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

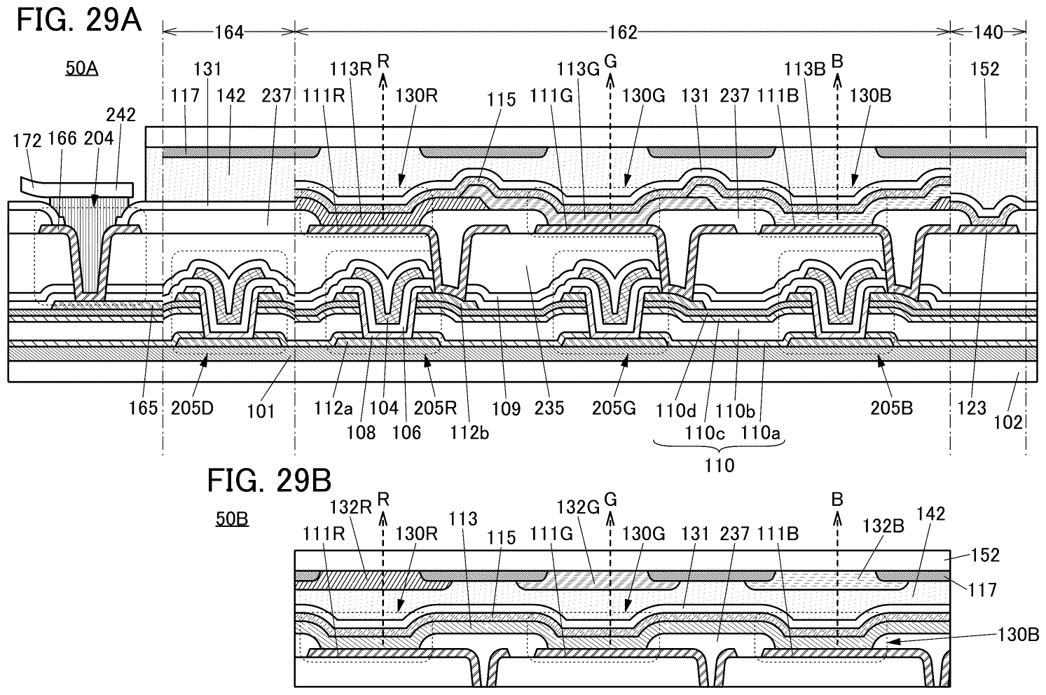

FIG. 29A illustrates an example of cross sections of part of a region including the FPC 172, part of the circuit portion 164, part of the display portion 162, part of the connection portion 140, and part of a region including the end portion of the display device 50A.

The display device 50A illustrated in FIG. 29A includes a transistor 205D, a transistor 205R, a transistor 205G, and a transistor 205B, a light-emitting element 130R, a light-emitting element 130G, a light-emitting element 130B, and the like between the substrate 102 and the substrate 152. The circuit portion 164 is provided with the transistor 205D, for example, and the display portion 162 is provided with the transistor 205R, the transistor 205G, the transistor 205B, the light-emitting element 130R, the light-emitting element 130G, the light-emitting element 130B, and the like.

The light-emitting element 130R is a display element included in the subpixel 11R that emits red light. The light-emitting element 130G is a display element included in the subpixel 11G that emits green light. The light-emitting element 130B is a display element included in the subpixel 11B that emits blue light.

The display device 50A employs an SBS structure. The SBS structure can optimize materials and structures of light-emitting elements and thus can extend the freedom of choice of materials and structures, whereby the luminance and the reliability can be easily improved.

The display device 50A has a top-emission structure. The aperture ratio of pixels in a top-emission structure can be higher than that of pixels in a bottom-emission structure because, for example, a transistor can be provided to overlap with a light-emitting region of a light-emitting element in the top-emission structure.

The insulating layer 101 including hydrogen is provided over the substrate 102, for example, and the transistor 205D, the transistor 205R, the transistor 205G, and the transistor 205B are provided over the insulating layer 101. These transistors can be manufactured using the same material through the same process.

This embodiment describes an example where OS transistors are used as the transistor 205D, the transistor 205R, the transistor 205G, and the transistor 205B. Any of the transistors of embodiments of the present invention can be used as the transistor 205D, the transistor 205R, the transistor 205G, and the transistor 205B. In other words, the display device 50A includes any of the transistors of embodiments of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention. For example, any of the transistor 100, the transistor 100A to the transistor 100H, and the transistor 150 described in the above embodiment can be used as each of the transistor 205D, the transistor 205R, the transistor 205G, and the transistor 205B.

Specifically, the transistor 205D, the transistor 205R, the transistor 205G, and the transistor 205B each include the conductive layer 112a functioning as the one of the source electrode and the drain electrode, the conductive layer 112b functioning as the other of the source electrode and the drain electrode, the semiconductor layer 108 including the channel formation region, the insulating layer 106 functioning as the gate insulating layer, and the conductive layer 104 functioning as the gate electrode. The insulating layer 110 is provided over the insulating layer 101 and the conductive layer 112a, and an opening reaching the conductive layer 112a is provided in the insulating layer 110. The semiconductor layer 108, the insulating layer 106, and the conductive layer 104 are provided in this order to include a region positioned in the opening.

In the example illustrated in FIG. 29A, the insulating layer 110 includes the insulating layer 110a, the insulating layer 110b over the insulating layer 110a, the insulating layer 110c over the insulating layer 110b, and the insulating layer 110d over the insulating layer 110c. That is, the insulating layer 110 has a four-layer stacked structure of the insulating layer 110a to the insulating layer 110d in the example illustrated in FIG. 29A. The insulating layer 110 has a four-layer stacked structure of the insulating layer 110a to the insulating layer 110d also in examples illustrated in the subsequent drawings in this embodiment.

In FIG. 29A, a plurality of layers obtained by processing the same conductive film are illustrated with the same hatching pattern. The same applies to the subsequent drawings in this embodiment.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include one or more of a planar transistor, a staggered transistor, and an inverted staggered transistor. A transistor included in the display device of this embodiment may have a top-gate structure or a bottom-gate structure. Gates may be provided above and below a semiconductor layer where a channel is formed.

A transistor including silicon in its channel formation region (hereinafter referred to as a Si transistor) may be included in the display device of this embodiment.

To increase the emission luminance of the light-emitting element included in the pixel circuit, it is necessary to increase the amount of current flowing through the light-emitting element. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Thus, with the use of an OS transistor as the driving transistor included in the pixel circuit, the amount of current flowing through the light-emitting element can be increased, resulting in an increase in emission luminance of the light-emitting element.

When transistors operate in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be set minutely by a change in gate-source voltage; hence, the amount of current flowing through the light-emitting element can be controlled. Therefore, the number of gray levels in the pixel circuit can be increased.

In addition, regarding saturation characteristics of a current flowing when a transistor operates in a saturation region, a current (saturation current) can flow more stably in an OS transistor than in a Si transistor even when the source-drain voltage gradually increases. Thus, with the use of an OS transistor as the driving transistor, a current can be made to flow stably through the light-emitting element, for example, even when a variation in current-voltage characteristics of the light-emitting element occurs. In other words, when the OS transistor operates in the saturation region, the source-drain current hardly changes with a change in the source-drain voltage; hence, the emission luminance of the light-emitting element can be stable.

The transistor included in the circuit portion 164 and the transistor included in the display portion 162 may have the same structure or different structures. One structure or two or more kinds of structures may be employed for a plurality of transistors included in the circuit portion 164. Similarly, one structure or two or more kinds of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. As a favorable example, a structure is given in which an OS transistor is used as a transistor functioning as a switch for controlling electrical continuity and discontinuity between wirings and an LTPS transistor is used as a transistor for controlling a current.

For example, one transistor included in the display portion 162 functions as a transistor for controlling a current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

The insulating layer 109 is provided to cover the transistor 205D, the transistor 205R, the transistor 205G, and the transistor 205B, and an insulating layer 235 is provided over the insulating layer 109.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. In that case, formation of a depressed portion in the insulating layer 235 can be inhibited in processing a pixel electrode 111R, a pixel electrode 111G, a pixel electrode 111B, and the like. Alternatively, a depressed portion may be formed in the insulating layer 235 in processing the pixel electrode 111R, the pixel electrode 111G, the pixel electrode 111B, and the like.

The light-emitting element 130R, the light-emitting element 130G, and the light-emitting element 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 29A emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 29A emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 29A emits blue light (B). The EL layer 113B includes a light-emitting layer that emits blue light.

Although the EL layer 113R, the EL layer 113G, and the EL layer 113B have the same thickness in FIG. 29A, the present invention is not limited thereto. The EL layer 113R, the EL layer 113G, and the EL layer 113B may have different thicknesses. For example, the thicknesses of the EL layer 113R, the EL layer 113G, and the EL layer 113B are preferably set to match an optical path length that intensifies light emitted from each EL layer. In that case, a microcavity structure is achieved, and the color purity of light emitted from each light-emitting element can be improved.

The pixel electrode 111R is electrically connected to the conductive layer 112b included in the transistor 205R through an opening provided in the insulating layer 106, the insulating layer 109, and the insulating layer 235. In a similar manner, the pixel electrode 111G is electrically connected to the conductive layer 112b included in the transistor 205G, and the pixel electrode 111B is electrically connected to the conductive layer 112b included in the transistor 205B.

End portions of the pixel electrode 111R, the pixel electrode 111G, and the pixel electrode 111B are covered with an insulating layer 237. The insulating layer 237 functions as a partition. The insulating layer 237 can have a single-layer structure or a stacked-layer structure including one or both of an inorganic insulating material and an organic insulating material. A material that can be used for the insulating layer 109 and a material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display device 50A.

The common electrode 115 is one continuous film shared by the light-emitting element 130R, the light-emitting element 130G, and the light-emitting element 130B. The common electrode 115 shared by the light-emitting elements is electrically connected to a conductive layer 123 provided in the connection portion 140. As the conductive layer 123, a conductive layer formed using the same material in the same step as the pixel electrode 111R, the pixel electrode 111G, and the pixel electrode 111B is preferably used.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element that belongs to Group 1 or Group 2 of the periodic table and that is not listed above as an example (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element preferably includes an electrode having properties of transmitting and reflecting visible light (a transflective electrode), and the other preferably includes an electrode having a property of reflecting visible light (a reflective electrode). When the light-emitting element has a microcavity structure, light obtained from the light-emitting layer can be resonated between the electrodes, whereby light emitted from the light-emitting element can be intensified.

A transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layer 113R, the EL layer 113G, and the EL layer 113B are each provided to have an island shape. In FIG. 29A, an end portion of the EL layer 113R and an end portion of the EL layer 113G adjacent to each other overlap with each other, an end portion of the EL layer 113G and an end portion of the EL layer 113B adjacent to each other overlap with each other, and an end portion of the EL layer 113R and an end portion of the EL layer 113B adjacent to each other overlap with each other. When island-shaped EL layers are formed using a fine metal mask, end portions of the EL layers adjacent to each other may overlap with each other as illustrated in FIG. 29A; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layer 113R, the EL layer 113G, and the EL layer 113B includes at least a light-emitting layer. The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may include one or more kinds of organic compounds (e.g., a host material or an assist material) in addition to the light-emitting substance (a guest material). As the one or more kinds of organic compounds, one or both of a substance with a good hole-transport property (a hole-transport material) and a substance with a good electron-transport property (an electron-transport material) can be used. As the one or more kinds of organic compounds, a substance with a bipolar property (a substance with a good electron-transport property and a good hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a good hole-injection property (a hole-injection layer), a layer including a hole-transport material (a hole-transport layer), a layer including a substance having a good electron-blocking property (an electron-blocking layer), a layer including a substance having a good electron-injection property (an electron-injection layer), a layer including an electron-transport material (an electron-transport layer), and a layer including a substance having a good hole-blocking property (a hole-blocking layer). The EL layer may further include one or both of a substance with a bipolar property and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure may be referred to as a stack structure.

In the case of using a tandem light-emitting element in FIG. 29A, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting element 130R, the light-emitting element 130G, and the light-emitting element 130B. The protective layer 131 and the substrate 152 are bonded to each other with an adhesive layer 142. The substrate 152 is provided with a light-blocking layer 117. For example, a solid sealing structure or a hollow sealing structure can be employed to seal the light-emitting elements. In FIG. 29A, a solid sealing structure is employed, in which a space between the substrate 152 and the substrate 102 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting elements. Furthermore, the space may be filled with a resin other than the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is preferable that the protective layer 131 be provided to extend to the end portion of the display device 50A. Meanwhile, a connection portion 204 has a portion not provided with the protective layer 131 so that the FPC 172 and a conductive layer 166 are electrically connected to each other.

By providing the protective layer 131 over the light-emitting element 130R, the light-emitting element 130G, and the light-emitting element 130B, the reliability of the light-emitting elements can be increased.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

For the protective layer 131, any of inorganic insulating films such as an oxide insulating film and a nitride insulating film can be used, for example. Specific examples of these inorganic insulating films are as described above. In particular, the protective layer 131 preferably includes a nitride insulating film, and further preferably includes a nitride insulating film.

An inorganic film including ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further include nitrogen.

When light emitted from the light-emitting element is extracted through the protective layer 131, the protective layer 131 preferably has a good visible-light-transmitting property. For example, ITO, IGZO, and aluminum oxide are preferable because they are inorganic materials having a good visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layers.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 204 is provided in a region of the substrate 102 not overlapping with the substrate 152. In the connection portion 204, the conductive layer 165 is electrically connected to the FPC 172 through the conductive layer 166 and a connection layer 242. The conductive layer 165 can be a conductive layer obtained by processing the same conductive film as the conductive layer 112b. The conductive layer 166 can be a conductive layer obtained by processing the same conductive film as the pixel electrode 111R, the pixel electrode 111G, and the pixel electrode 111B. On the top surface of the connection portion 204, the conductive layer 166 is exposed. Thus, the connection portion 204 and the FPC 172 can be electrically connected to each other through the connection layer 242.

The display device 50A has a top-emission structure. Light from the light-emitting element is emitted toward the substrate 152. For the substrate 152, a material having a good visible-light-transmitting property is preferably used. The pixel electrode 111R, the pixel electrode 111G, and the pixel electrode 111B include a material that reflects visible light, and the counter electrode (the common electrode 115) includes a material that transmits visible light.

The light-blocking layer 117 is preferably provided on the surface of the substrate 152 on the substrate 102 side. The light-blocking layer 117 can be provided over a region between adjacent light-emitting elements, in the connection portion 140, in the circuit portion 164, and the like.

A coloring layer such as a color filter may be provided on the surface of the substrate 152 on the substrate 102 side or over the protective layer 131. When the color filter is provided to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, and the like can be used. Each coloring layer can be formed using one or more of a metal material, a resin material, a pigment, and a dye. Each coloring layer is formed in a desired position by a printing method, an ink-jet method, an etching method using a photolithography method, or the like.

For the substrate 152, a material that can be used for the substrate 102 can be used. Moreover, a variety of optical members can be provided on the outer surface of the substrate 152 (the surface opposite to the substrate 102). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, a glass layer or a silica layer (SiOₓ layer) is preferably provided as the surface protective layer to inhibit the surface contamination and damage. For the surface protective layer, DLC (diamond-like carbon), aluminum oxide (AlOₓ), a polyester-based material, a polycarbonate-based material, or the like may be used. The surface protective layer is preferably formed using a material having high visible light transmittance. The surface protective layer is preferably formed using a material with high hardness.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene-vinyl acetate) resin. In particular, a material with low moisture permeability, such as an epoxy resin, is preferable. A two-component-mixture-type resin may be used. An adhesive sheet may be used, for example.

As the connection layer 242, an anisotropic conductive film (ACF), an anisotropic conductive paste (ACP), or the like can be used.

### [Display Device 50B]

FIG. 29B illustrates an example of a cross section of the display portion 162 of a display device 50B. The display device 50B is different from the display device 50A mainly in that the subpixels of different colors include respective coloring layers and the light-emitting elements that share an EL layer 113. The structure illustrated in FIG. 29B can be combined with the structure of the region including the FPC 172, the circuit portion 164, the stacked-layer structure from the substrate 102 to the insulating layer 235 in the display portion 162, the connection portion 140, and the end portion, which is illustrated in FIG. 29A. Note that in the following description of display devices, the description of portions similar to those of the above-described display device may be omitted.

In the display device 50B illustrated in FIG. 29B, the light-emitting element 130R, the light-emitting element 130G, the light-emitting element 130B, a coloring layer 132R transmitting red light, a coloring layer 132G transmitting green light, a coloring layer 132B transmitting blue light, and the like are provided.

The light-emitting element 130R includes the pixel electrode 111R, the EL layer 113 over the pixel electrode 111R, and the common electrode 115 over the EL layer 113. Light emitted from the light-emitting element 130R is extracted as red light to outside the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to outside the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to outside the display device 50B through the coloring layer 132B.

The EL layer 113 and the common electrode 115 are shared by the light-emitting element 130R, the light-emitting element 130G, and the light-emitting element 130B. The number of manufacturing steps can be smaller in the structure where the EL layer 113 is provided to be shared by the subpixels of different colors than in the structure where the subpixels of different colors are provided with different EL layers.

The light-emitting element 130R, the light-emitting element 130G, and the light-emitting element 130B illustrated in FIG. 29B emit white light, for example. When white light emitted from the light-emitting element 130R, the light-emitting element 130G, and the light-emitting element 130B passes through the coloring layer 132R, the coloring layer 132G, and the coloring layer 132B, light of desired colors can be obtained.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer including a light-emitting substance that emits blue light and a light-emitting layer including a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are provided in this order; and a three-unit tandem structure in which a light-emitting unit that emits blue light, a light-emitting unit that emits yellow, yellow-green, or green light and red light, and a light-emitting unit that emits blue light are provided in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Note that in the case where the light-emitting element emitting white light has a microcavity structure, light with a specific wavelength such as red, green, or blue is sometimes intensified to be emitted.

Alternatively, the light-emitting element 130R, the light-emitting element 130G, and the light-emitting element 130B illustrated in FIG. 29B emit blue light, for example. In this case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, by providing a color conversion layer between the light-emitting element 130R or the light-emitting element 130G and the substrate 152, blue light emitted from the light-emitting element 130R or the light-emitting element 130G can be converted into light with a longer wavelength, and red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and the color purity of light exhibited by a subpixel can be improved.

### [Display Device 50C]

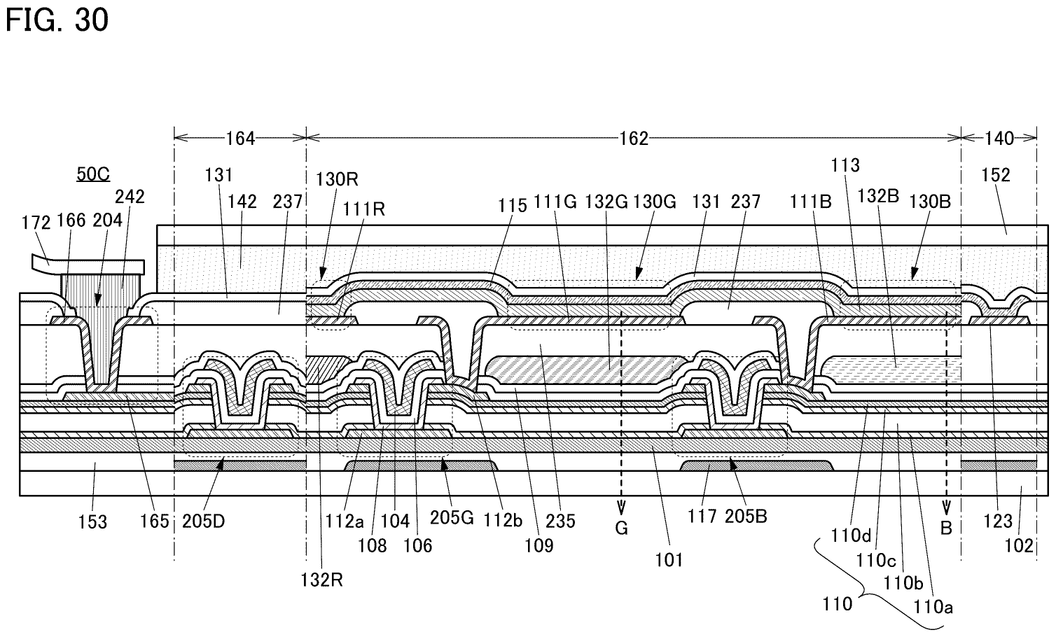

A display device 50C illustrated in FIG. 30 is different from the display device 50B mainly in having a bottom-emission structure.

Light from the light-emitting element is emitted toward the substrate 102. For the substrate 102, a material having a good visible-light-transmitting property is preferably used. By contrast, there is no limitation on the light-transmitting property of a material used for the substrate 152.

The light-blocking layer 117 is preferably formed between the substrate 102 and the transistor. In the example illustrated in FIG. 30, the light-blocking layers 117 are provided over the substrate 102, an insulating layer 153 is provided over the light-blocking layers 117, and the insulating layer 101 is provided over the insulating layer 153. In addition, the coloring layer 132R, the coloring layer 132G, and the coloring layer 132B are provided over the insulating layer 109, and the insulating layer 235 is provided over the coloring layer 132R, the coloring layer 132G, and the coloring layer 132B.

The light-emitting element 130R overlapping with the coloring layer 132R includes the pixel electrode 111R, the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a good visible-light-transmitting property is used for each of the pixel electrode 111R, the pixel electrode 111G, and the pixel electrode 111B. A material that reflects visible light is preferably used for the common electrode 115. In the display device having a bottom-emission structure, the common electrode 115 can be formed using a metal with low electrical resistance, for example; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50D]

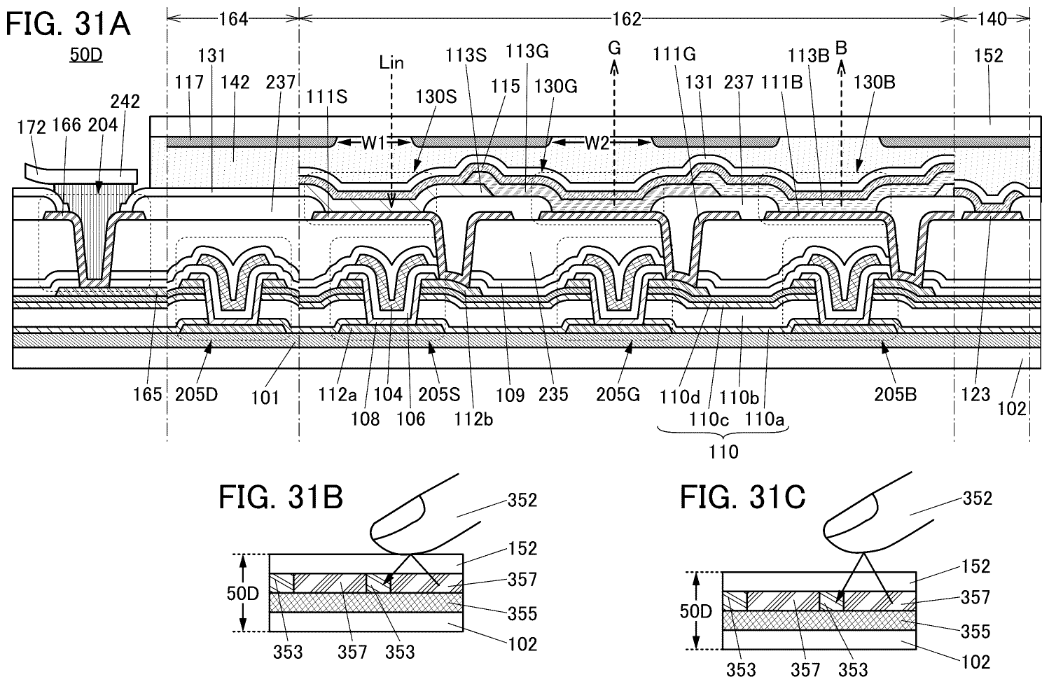

A display device 50D illustrated in FIG. 31A is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiode can be formed over the same substrate. Thus, the organic photodiode can be incorporated in a display device including the organic EL elements.

In the display device 50D including the light-emitting elements and the light-receiving element in the pixel, the pixel has a light-receiving function; thus, the display device can detect the touch or proximity of an object while displaying an image. Accordingly, the display portion 162 has one or both of an image capturing function and a sensing function in addition to a function of displaying an image. For example, an image can be displayed by using all the subpixels included in the display device 50D; alternatively, light can be emitted by some of the subpixels as a light source, light can be detected by some other subpixels, and an image can be displayed by using the remaining subpixels.

Accordingly, a light-receiving portion and a light source do not need to be provided separately from the display device 50D; hence, the number of components of an electronic device can be reduced. For example, a biometric authentication device or a capacitive touch panel for scroll operation or the like does not need to be provided separately in the electronic device. Thus, with the use of the display device 50D, the electronic device can be manufactured at lower costs.

When the light-receiving element is used for an image sensor, the display device 50D can capture an image using the light-receiving element. For example, image capturing for personal authentication with the use of a fingerprint, a palm print, the iris, the shape of a blood vessel (including the shape of a vein and the shape of an artery), a face, or the like is possible by using the image sensor.

Moreover, the light-receiving element can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect the object even when the object is not in contact with the display device.

The light-receiving element 130S includes a pixel electrode 111S over the insulating layer 235, a functional layer 113S over the pixel electrode 111S, and the common electrode 115 over the functional layer 113S. Light Lin from outside the display device 50D enters the functional layer 113S.

The pixel electrode 111S is electrically connected to the conductive layer 112b included in a transistor 205S through an opening provided in the insulating layer 106, the insulating layer 109, and the insulating layer 235. The transistor 205S can have a structure similar to the structure that the transistor 205D, the transistor 205R, the transistor 205G, and the transistor 205B can have. For example, any of the transistor 100, the transistor 100A to the transistor 100H, and the transistor 150 described in the above embodiment can be used as the transistor 205S.

An end portion of the pixel electrode 111S is covered with the insulating layer 237.

The common electrode 115 is one continuous film shared by the light-receiving element 130S, the light-emitting element 130R (not shown), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer including a substance having a good hole-transport property, a substance having a good electron-transport property, a substance having a bipolar property, or the like. Without limitation to the above, the functional layer 113S may further include a layer including a substance having a good hole-injection property, a hole-blocking material, a substance having a good electron-injection property, an electron-blocking material, or the like. The functional layer 113S can be formed using a material that can be used for the light-emitting element, for example.

Either a low molecular compound or a high molecular compound can be used in the light-receiving element, and an inorganic compound may also be included. Each layer included in the light-receiving element can be formed by any of the following methods: an evaporation method (including a vacuum evaporation method), a transfer method, a printing method, an inkjet method, a coating method, and the like.

In the display device 50D illustrated in FIG. 31B and FIG. 31C, a layer 353 including a light-receiving element, a circuit layer 355, and a layer 357 including a light-emitting element are provided between the substrate 102 and the substrate 152.

The layer 353 includes the light-receiving element 130S, for example. The layer 357 includes the light-emitting element 130R, the light-emitting element 130G, and the light-emitting element 130B, for example.

The circuit layer 355 includes a circuit for driving a light-receiving element and a circuit for driving a light-emitting element. The circuit layer 355 includes the transistor 205R, the transistor 205G, and the transistor 205B, for example. The circuit layer 355 can further include one or more of a switch, a capacitor, a resistor, a wiring, a terminal, and the like.

FIG. 31B illustrates an example where the light-receiving element 130S is used as a touch sensor. Light emitted from the light-emitting element in the layer 357 is reflected by a finger 352 that touches the display device 50D as illustrated in FIG. 31B; then, the light-receiving element in the layer 353 detects the reflected light. Thus, the touch of the finger 352 on the display device 50D can be detected.

FIG. 31C illustrates an example where the light-receiving element 130S is used as a contactless sensor. Light emitted from the light-emitting element in the layer 357 is reflected by the finger 352 that is close to (i.e., that does not touch) the display device 50D as illustrated in FIG. 31C; then, the light-receiving element in the layer 353 detects the reflected light.

### [Display Device 50E]

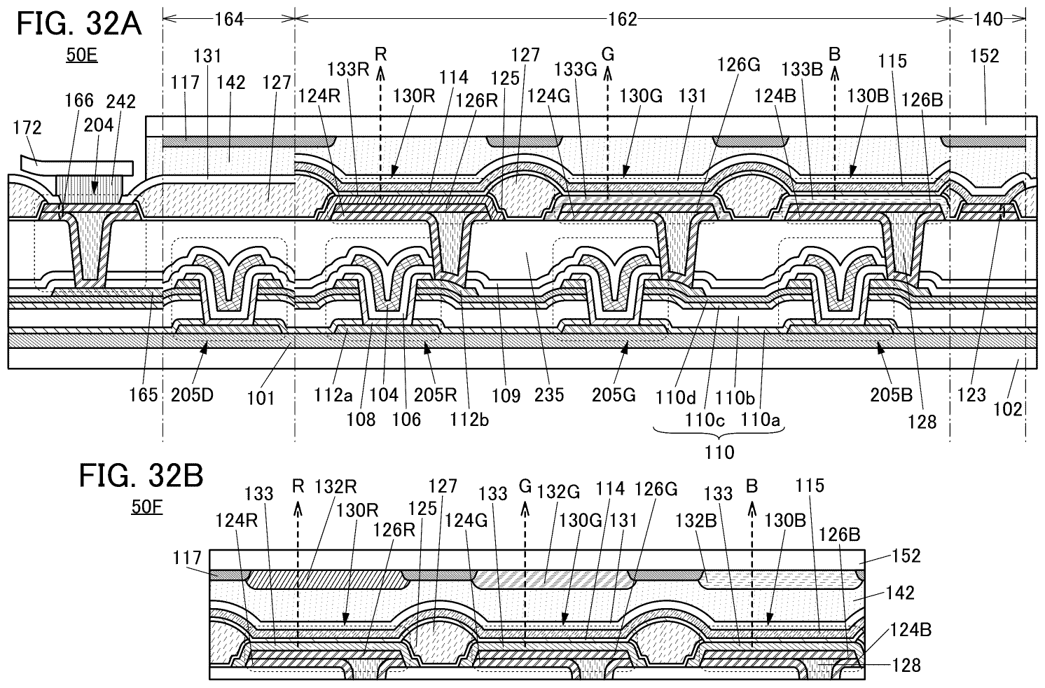

A display device 50E illustrated in FIG. 32A is an example of a display device having an MML (metal maskless) structure. In other words, the display device 50E includes a light-emitting element that is formed without using a fine metal mask.

An island-shaped light-emitting layer of the light-emitting element included in the display device having the MML structure is formed in the following manner: a light-emitting layer is formed on the entire surface, and then, the light-emitting layer is processed by a photolithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. For processing by photolithography, an apparatus that is the same as or similar to an apparatus used for manufacturing a transistor can be used; thus, there is no need to introduce a special apparatus to manufacture the device having the MML structure. The MML structure can reduce the manufacturing cost as described above, and thus is suitable for mass production of devices.

A display device having the MML structure does not require a pseudo improvement in resolution by employing unique pixel arrangement such as PenTile arrangement, for example; thus, the display device can achieve high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

Moreover, providing a sacrificial layer over the light-emitting layer can reduce damage to the light-emitting layer in the manufacturing process of the display device, resulting in an increase in reliability of the light-emitting element.

Employing a film formation step using an area mask and a processing step using a resist mask enables a light-emitting element to be manufactured by a relatively easy process.

The stacked-layer structure from the substrate 102 to the insulating layer 235 and the stacked-layer structure from the protective layer 131 to the substrate 152 are similar to those in the display device 50A; therefore, description thereof is omitted.

In FIG. 32A, the light-emitting element 130R, the light-emitting element 130G, and the light-emitting element 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 32A emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 32A emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 32A emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the light-emitting elements is referred to as the common layer 114. Note that in this specification and the like, only the layer 133R, the layer 133G, and the layer 133B are sometimes referred to as island-shaped EL layers, EL layers formed in an island shape, or the like, in which case the common layer 114 is not included in the EL layer.

The layer 133R, the layer 133G, and the layer 133B are apart from each other. When the EL layer is provided to have an island shape for each light-emitting element, a leakage current between adjacent light-emitting elements can be inhibited. This can prevent crosstalk-induced unintended light emission, so that the display device can achieve extremely high contrast. Although the layer 133R, the layer 133G, and the layer 133B have the same thickness in FIG. 32A, the present invention is not limited thereto. The layer 133R, the layer 133G, and the layer 133B may have different thicknesses.

The conductive layer 124R is electrically connected to the conductive layer 112b included in the transistor 205R through an opening provided in the insulating layer 106, the insulating layer 109, and the insulating layer 235. In a similar manner, the conductive layer 124G is electrically connected to the conductive layer 112b included in the transistor 205G, and the conductive layer 124B is electrically connected to the conductive layer 112b included in the transistor 205B.

The conductive layer 124R, the conductive layer 124G, and the conductive layer 124B are formed to cover the openings provided in the insulating layer 235. A layer 128 is embedded in each of the depressed portions of the conductive layer 124R, the conductive layer 124G, and the conductive layer 124B.

The layer 128 has a function of filling the depressed portions of the conductive layer 124R, the conductive layer 124G, and the conductive layer 124B. The conductive layer 126R, the conductive layer 126G, and the conductive layer 126B electrically connected to the conductive layer 124R, the conductive layer 124G, and the conductive layer 124B, respectively, are provided over the conductive layer 124R, the conductive layer 124G, the conductive layer 124B, and the layer 128. Thus, regions overlapping with the depressed portions of the conductive layer 124R, the conductive layer 124G, and the conductive layer 124B can also be used as the light-emitting regions, increasing the aperture ratio of the pixels. As each of the conductive layer 124R and the conductive layer 126R, a conductive layer functioning as a reflective electrode is preferably used.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although the top surface of the layer 128 includes a flat portion in the example illustrated in FIG. 32A, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may match an end portion of the conductive layer 124R or may cover a side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0° and less than 90°. In the case where an end portion of the pixel electrode has a tapered shape, the layer 133R provided along a side surface of the pixel electrode has an inclined portion. When the side surface of the pixel electrode has a tapered shape, coverage with an EL layer provided along the side surface of the pixel electrode can be favorable.

Since the conductive layer 124G and the conductive layer 124B are similar to the conductive layer 124R, and the conductive layer 126G and the conductive layer 126B are similar to the conductive layer 126R, the detailed description thereof is omitted.

The top surface and a side surface of the conductive layer 126R are covered with the layer 133R. Similarly, the top surface and a side surface of the conductive layer 126G are covered with the layer 133G, and the top surface and a side surface of the conductive layer 126B are covered with the layer 133B. Accordingly, regions provided with the conductive layer 126R, the conductive layer 126G, and the conductive layer 126B can be entirely used as the light-emitting regions of the light-emitting element 130R, the light-emitting element 130G, and the light-emitting element 130B, thereby increasing the aperture ratio of the pixels.

A side surface and part of the top surface of each of the layer 133R, the layer 133G, and the layer 133B are covered with an insulating layer 125 and an insulating layer 127. The common layer 114 is provided over the layer 133R, the layer 133G, the layer 133B, the insulating layer 125, and the insulating layer 127, and the common electrode 115 is provided over the common layer 114. The common layer 114 and the common electrode 115 are each a continuous film provided to be shared by a plurality of light-emitting elements.

In FIG. 32A, the insulating layer 237 illustrated in FIG. 29A, for example, is not provided between the conductive layer 126R and the layer 133R. That is, an insulating layer (also referred to as a partition wall, a bank, a spacer, or the like) being in contact with the pixel electrode and covering an upper end portion of the pixel electrode is not provided in the display device 50E. Thus, the interval between adjacent light-emitting elements can be extremely short. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include a light-emitting layer. The layer 133R, the layer 133G, and the layer 133B each preferably include a light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting element 130R, the light-emitting element 130G, and the light-emitting element 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

Since the side surface (and part of the top surface) of each of the layer 133R, the layer 133G, and the layer 133B are covered with at least one of the insulating layer 125 and the insulating layer 127, the common layer 114 (or the common electrode 115) can be inhibited from being in contact with the side surfaces of the pixel electrodes, the layer 133R, the layer 133G, and the layer 133B, leading to inhibition of a short circuit of the light-emitting elements. Thus, the reliability of the light-emitting elements can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting elements can be increased.

The insulating layer 127 is provided over the insulating layer 125 to fill a depressed portion of the insulating layer 125. The insulating layer 127 preferably covers at least part of a side surface of the insulating layer 125.

The insulating layer 125 and the insulating layer 127 can fill a gap between adjacent island-shaped layers, whereby unevenness with a large level difference on the formation surface of the layers (e.g., the carrier-injection layer and the common electrode) provided over the island-shaped layers can be reduced and the formation surface can be flatter. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 125 and the insulating layer 127, and the coverage with the common layer 114 and the common electrode 115 can be improved. Thus, connection defects caused by step disconnection can be inhibited. In addition, an increase in electrical resistance, which is caused by local thinning of the common electrode 115 due to the step, can be inhibited.

The top surface of the insulating layer 127 preferably has a shape with higher planarity. The top surface of the insulating layer 127 may include at least one of a flat surface, a convex surface, and a concave surface. For example, the top surface of the insulating layer 127 preferably has a convex shape with a large radius of curvature.

The insulating layer 125 can include an inorganic material. For the insulating layer 125, any of inorganic insulating films such as an oxide insulating film and a nitride insulating film can be used, for example. Specific examples of these inorganic insulating films are as described above. The insulating layer 125 may have a single-layer structure or a stacked-layer structure. In particular, aluminum oxide is preferably used because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer, entry of impurities (typically, at least one of water and oxygen) that would be diffused to the light-emitting elements from the outside can be inhibited. With this structure, a highly reliable light-emitting element and a highly reliable display device can be obtained.

The insulating layer 125 preferably has a low impurity concentration. In that case, degradation of the EL layer due to entry of impurities into the EL layer from the insulating layer 125 can be inhibited. In addition, when the impurity concentration is reduced in the insulating layer 125, a barrier property against at least one of water and oxygen can be increased. For example, the insulating layer 125 preferably has a sufficiently low hydrogen concentration or a sufficiently low carbon concentration, and further preferably has both a sufficiently low hydrogen concentration and a sufficiently low carbon concentration.

The insulating layer 127 provided over the insulating layer 125 has a function of reducing unevenness with a large level difference on the insulating layer 125, which is formed between the adjacent light-emitting elements. In other words, the insulating layer 127 has an effect of improving the planarity of the formation surface of the common electrode 115.

As the insulating layer 127, an insulating layer including an organic material can be suitably used. As the organic material, a photosensitive resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymers in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, any of precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved. Since no polarizing plate is required to improve the display quality of the display device, the weight and thickness of the display device can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

### [Display Device 50F]

FIG. 32B illustrates an example of a cross section of the display portion 162 of a display device 50F. The display device 50F is different from the display device 50E mainly in that the subpixels of different colors each include a coloring layer and a light-emitting element including a layer 133. The structure illustrated in FIG. 32B can be combined with the structure of the region including the FPC 172, the circuit portion 164, the stacked-layer structure from the substrate 102 to the insulating layer 235 in the display portion 162, the connection portion 140, and the end portion, which is illustrated in FIG. 32A.

In the display device 50F illustrated in FIG. 32B, the light-emitting element 130R, the light-emitting element 130G, the light-emitting element 130B, the coloring layer 132R transmitting red light, the coloring layer 132G transmitting green light, the coloring layer 132B transmitting blue light, and the like are provided.

Light emitted from the light-emitting element 130R is extracted as red light to outside the display device 50F through the coloring layer 132R. Similarly, light emitted from the light-emitting element 130G is extracted as green light to outside the display device 50F through the coloring layer 132G. Light emitted from the light-emitting element 130B is extracted as blue light to outside the display device 50F through the coloring layer 132B.

The light-emitting element 130R, the light-emitting element 130G, and the light-emitting element 130B each include the layer 133. The three layers 133 are formed using the same material in the same step. The three layers 133 are apart from each other. When the EL layer is provided to have an island shape for each light-emitting element, a leakage current between adjacent light-emitting elements can be inhibited. This can prevent crosstalk-induced unintended light emission, so that the display device can achieve extremely high contrast.

The light-emitting element 130R, the light-emitting element 130G, and the light-emitting element 130B illustrated in FIG. 32B emit white light, for example. When white light emitted from the light-emitting element 130R, the light-emitting element 130G, and the light-emitting element 130B passes through the coloring layer 132R, the coloring layer 132G, and the coloring layer 132B, light of desired colors can be obtained.

Alternatively, the light-emitting element 130R, the light-emitting element 130G, and the light-emitting element 130B illustrated in FIG. 32B emit blue light, for example. In this case, the layer 133 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, by providing a color conversion layer between the light-emitting element 130R or the light-emitting element 130G and the substrate 152, blue light emitted from the light-emitting element 130R or the light-emitting element 130G can be converted into light with a longer wavelength, and red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the intended color can be absorbed by the coloring layer, and the color purity of light exhibited by a subpixel can be improved.

### [Display Device 50G]

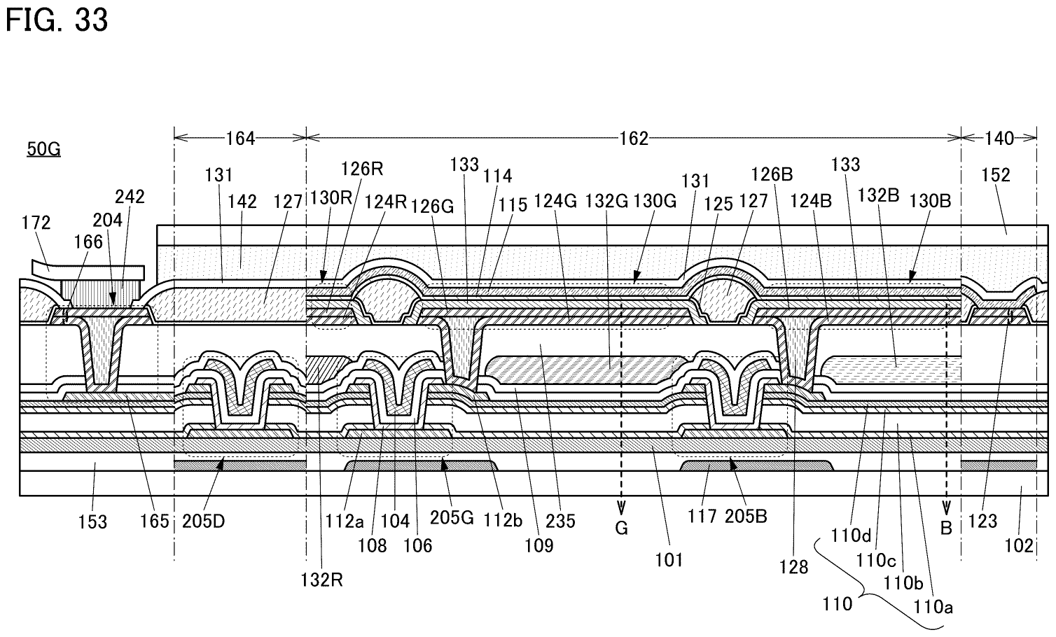

A display device 50G illustrated in FIG. 33 is different from the display device 50F mainly in having a bottom-emission structure.

Light from the light-emitting element is emitted toward the substrate 102. For the substrate 102, a material having a good visible-light-transmitting property is preferably used. By contrast, there is no limitation on the light-transmitting property of a material used for the substrate 152.

The light-blocking layer 117 is preferably formed between the substrate 102 and the transistor. In the example illustrated in FIG. 33, the light-blocking layers 117 are provided over the substrate 102, the insulating layer 153 is provided over the light-blocking layers 117, and the insulating layer 101 is provided over the insulating layer 153. In addition, the coloring layer 132R, the coloring layer 132G, and the coloring layer 132B are provided over the insulating layer 109, and the insulating layer 235 is provided over the coloring layer 132R, the coloring layer 132G, and the coloring layer 132B.

The light-emitting element 130R overlapping with the coloring layer 132R includes the conductive layer 124R, the conductive layer 126R, the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a good visible-light-transmitting property is used for each of the conductive layer 124R, the conductive layer 124G, the conductive layer 124B, the conductive layer 126R, the conductive layer 126G, and the conductive layer 126B. A material that reflects visible light is preferably used for the common electrode 115. In the display device having a bottom-emission structure, the common electrode 115 can be formed using a metal with low electrical resistance, for example; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50H]

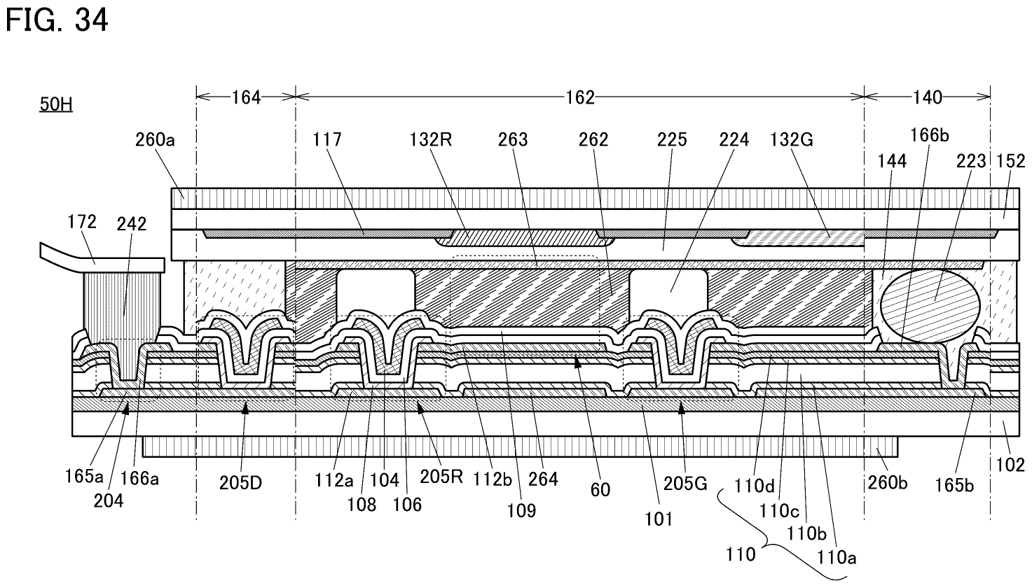

A display device 50H illustrated in FIG. 34 is a liquid crystal display device in a VA mode. FIG. 34 illustrates the transistor 205R and the transistor 205G as transistors provided in the display portion 162.

The display device 50H is provided with a liquid crystal element 60. The liquid crystal element 60 includes the conductive layer 112b, a conductive layer 263, and a liquid crystal 262 interposed therebetween. The conductive layer 112b functions as a pixel electrode of the liquid crystal element 60. The conductive layer 263 functions as a common electrode of the liquid crystal element 60.

The substrate 102 and the substrate 152 are bonded to each other with an adhesive layer 144. The liquid crystal 262 is sealed in a region that is surrounded by the substrate 102, the substrate 152, and the adhesive layer 144.

An insulating layer 224 can be provided between the insulating layer 109 and the conductive layer 263. The insulating layer 224 functions as a spacer, and a structure can be employed where the liquid crystal 262 does not overlap with the insulating layer 224, for example. The insulating layer 224 has a function of controlling the distance between the substrate 102 and the substrate 152 to control the thickness of the liquid crystal 262. The insulating layer 224 is preferably provided to overlap with the transistor, for example, in which case a reduction in the aperture ratio due to the insulating layer 224 can be inhibited.

The coloring layer 132R, the coloring layer 132G, the light-blocking layer 117, an insulating layer 225, the conductive layer 263, and the like are provided on the substrate 152 side.

A polarizing plate 260a is positioned on the outer surface of the substrate 152 (on the side opposite to the liquid crystal 262), and a polarizing plate 260b is positioned on the outer surface of the substrate 102 (on the side opposite to the liquid crystal 262). Although not shown, a backlight can be provided outside the polarizing plate 260a (on the side opposite to the liquid crystal 262) or outside the polarizing plate 260b (on the side opposite to the liquid crystal 262).

A subpixel provided in the display portion 162 of the display device 50H includes a transistor, the liquid crystal element 60, and a coloring layer. For example, a subpixel that emits red light includes the transistor 205R, the liquid crystal element 60, and the coloring layer 132R that transmits red light. A subpixel that emits green light includes the transistor 205G, the liquid crystal element 60, and the coloring layer 132G that transmits green light. Similarly, although not shown, a subpixel that emits blue light includes a transistor, the liquid crystal element 60, and a coloring layer that transmits blue light.

A conductive layer 264, which can be formed using the same material in the same step as the conductive layer 112a, is provided over the insulating layer 101. The conductive layer 264 includes a portion overlapping with the conductive layer 112b with the insulating layer 110 therebetween. The conductive layer 112b, the conductive layer 264, and the insulating layer 110 positioned therebetween form a storage capacitor. Note that one or more insulating layers are provided between the conductive layer 112b and the conductive layer 264. For example, any one, two, or three of the insulating layer 110a to the insulating layer 110d may be removed in a region between the conductive layer 112b and the conductive layer 264.

The insulating layer 225 is provided on the substrate 152 side to cover the coloring layer 132R, the coloring layer 132G, and the light-blocking layer 117. The insulating layer 225 may have a function of a planarization film. The conductive layer 263 can have a substantially flat surface owing to the insulating layer 225, resulting in a uniform alignment state of the liquid crystal 262.

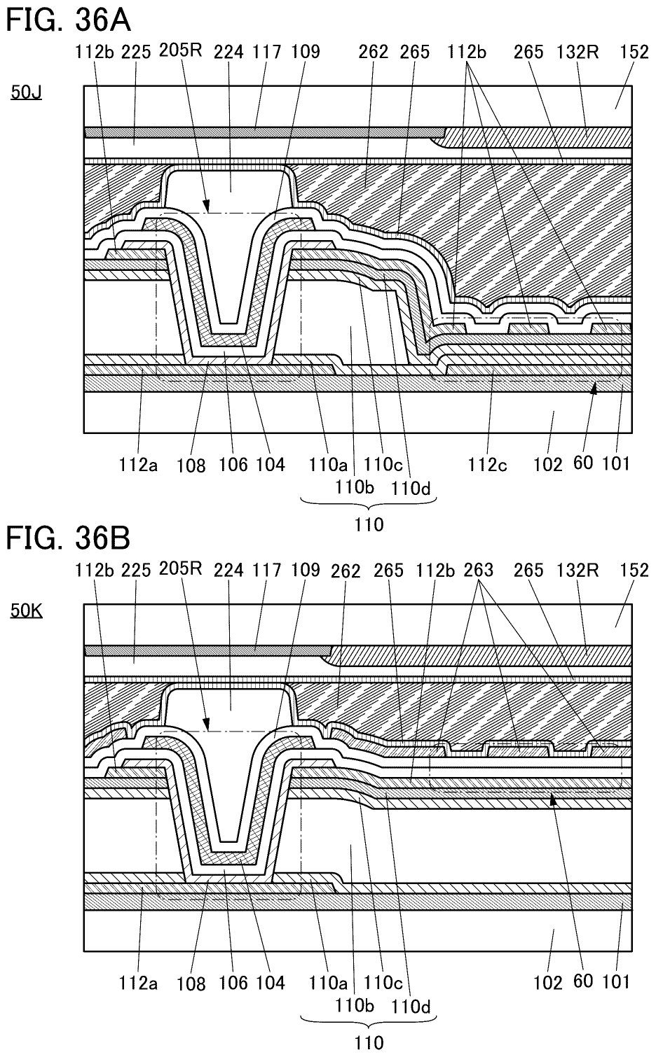

Note that alignment layers for controlling the alignment of the liquid crystal 262 may be provided on the surfaces of the conductive layer 263, the insulating layer 109, and the like that are in contact with the liquid crystal 262 (see alignment layers 265 in FIG. 36A and FIG. 36B).

The conductive layer 112b and the conductive layer 263 transmit visible light. That is, the display device 50H can be a transmissive liquid crystal display device. For example, in the case where a backlight is provided on the substrate 152 side, light from the backlight that is polarized by the polarizing plate 260a passes through the substrate 152, the conductive layer 263, the liquid crystal 262, the conductive layer 112b, and the substrate 102, and then reaches the polarizing plate 260b. In this case, optical modulation of the light can be controlled by controlling the alignment of the liquid crystal 262 with a voltage supplied between the conductive layer 112b and the conductive layer 263. In other words, the intensity of light emitted through the polarizing plate 260b can be controlled. Incident light other than light in a particular wavelength range is absorbed by the coloring layer, and thus, extracted light exhibits a specific color. For example, light transmitted through the coloring layer 132R can be red light. For example, light transmitted through the coloring layer 132G can be green light.

Here, as the polarizing plate 260b, a linear polarizing plate may be used or a circularly polarizing plate can also be used. An example of a circularly polarizing plate is a stack including a linear polarizing plate and a quarter-wave retardation plate. Reflection of external light can be inhibited with a circularly polarizing plate used as the polarizing plate 260b.

Note that in the case where a circularly polarizing plate is used as the polarizing plate 260b, a circularly polarizing plate or a general linear polarizing plate may be used as the polarizing plate 260a. The cell gap, alignment, driving voltage, and the like of the liquid crystal element used as the liquid crystal element 60 are adjusted in accordance with the kinds of polarizing plates used as the polarizing plate 260a and the polarizing plate 260b so that desirable contrast is obtained.

The conductive layer 263 is electrically connected to a conductive layer 166b provided on the substrate 102 side through a connector 223 in the connection portion 140. The conductive layer 166b is electrically connected to a conductive layer 165b through an opening provided in the insulating layer 110. Thus, a potential or a signal can be supplied to the conductive layer 263 from an FPC or an IC (not shown) provided on the substrate 102 side. In the structure example illustrated in FIG. 34, the conductive layer 165b is formed using the same material in the same step as the conductive layer 112a, and the conductive layer 166b is formed using the same material in the same step as the conductive layer 112b.

As the connector 223, a conductive particle can be used, for example. As the conductive particle, a particle of a resin, silica, or the like coated with a metal material can be used. It is preferable to use nickel or gold as the metal material to reduce contact resistance. It is also preferable to use a particle coated with layers of two or more kinds of metal materials, such as a particle coated with nickel and further with gold. As the connector 223, a material capable of elastic deformation or plastic deformation is preferably used. In that case, the conductive particle sometimes has a shape that is vertically crushed. This increases the contact area between the connector 223 and a conductive layer electrically connected to the connector 223, thereby reducing contact resistance and inhibiting generation of defects such as poor connection. The connector 223 is preferably provided to be covered with the adhesive layer 144. For example, the connectors 223 are preferably dispersed in the adhesive layer 144 before curing of the adhesive layer 144.

The connection portion 204 is provided in a region near an end portion of the substrate 102. In the connection portion 204, a conductive layer 166a is electrically connected to the FPC 172 through the connection layer 242. The conductive layer 166a is electrically connected to a conductive layer 165a through an opening provided in the insulating layer 110. In the structure example illustrated in FIG. 34, the conductive layer 165a is formed using the same material in the same step as the conductive layer 112a, and the conductive layer 166a is formed using the same material in the same step as the conductive layer 112b.

### [Display Device 50I]

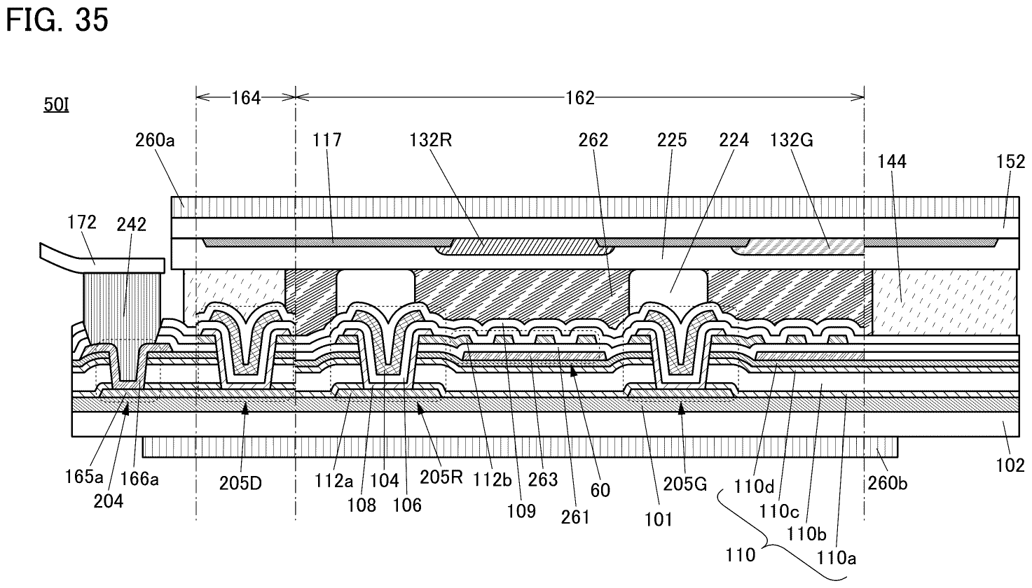

A display device 50I illustrated in FIG. 35 is a liquid crystal display device in an FFS mode. The display device 50I is different from the display device 50H mainly in the structure of the liquid crystal element 60.

In the display device 50I, the conductive layer 263 functioning as the common electrode of the liquid crystal element 60 is provided over the insulating layer 110, and an insulating layer 261 is provided over the conductive layer 263. The conductive layer 112b having a function of the other of the source electrode and the drain electrode of the transistor and a function of the pixel electrode of the liquid crystal element 60 is provided over the insulating layer 261. The insulating layer 109 is provided over the conductive layer 112b.

In a plan view, the conductive layer 112b has a comb-like shape or a shape with a slit. The conductive layer 263 is provided to include a region overlapping with the conductive layer 112b. There is a portion where the conductive layer 112b is not provided over the conductive layer 263 in a region overlapping with the coloring layer.

The conductive layer 112b and the conductive layer 263 are stacked with the insulating layer 261 therebetween, whereby a capacitor is formed. Therefore, it is not necessary to provide a capacitor separately, and the aperture ratio of the pixel can be increased.

Note that in the liquid crystal element 60, both the conductive layer 112b and the conductive layer 263 may have comb-like top-view shapes. Meanwhile, when only one of the conductive layer 112b and the conductive layer 263 in the liquid crystal element 60 has a comb-like top-view shape as in the display device 50I, the conductive layer 112b and the conductive layer 263 partly overlap with each other. This allows the capacitance between the conductive layer 112b and the conductive layer 263 to be used as a storage capacitor; thus, a capacitor does not need to be provided separately, and the aperture ratio of the display device can be increased.

### [Display Device 50J]

In a display device 50J illustrated in FIG. 36A, a portion of the insulating layer 110b that overlaps with the liquid crystal element 60 is removed by etching, for example. The liquid crystal element 60 included in the display device 50J includes a portion where the conductive layer 112c, the insulating layer 110a, the insulating layer 110c, the insulating layer 110d, and the conductive layer 112b are stacked in this order. The liquid crystal element 60 and the insulating layer 110b do not overlap with each other, which enables not only an increase in the light transmittance but also a reduction in the number of interfaces positioned on the path of light from the light source; accordingly, the influences of interface reflection and interface scattering can be inhibited.

In the example illustrated in FIG. 36A, the alignment layers 265 are provided on the surfaces of the insulating layer 109, the insulating layer 224, the insulating layer 225, and the like on the liquid crystal 262 side. The alignment layers 265 have a function of controlling the alignment of the liquid crystal 262.

In the display device 50J, the conductive layer 112b functions as the pixel electrode of the liquid crystal element 60. The conductive layer 112c functions as the common electrode of the liquid crystal element 60. The conductive layer 112c can be formed using the same material in the same step as the conductive layer 112a.

Note that a portion of one or both of the insulating layer 106 and the insulating layer 109 that overlaps with the liquid crystal element 60 may be removed by etching, for example. Alternatively, the insulating layer 109 is not necessarily provided. This facilitates transmission of the electric fields of the conductive layer 112b and the conductive layer 112c to the liquid crystal 262, which enables high-speed operation of the liquid crystal element 60. Furthermore, the light transmittance of a portion overlapping with the liquid crystal element 60 can be increased and the influences of interface reflection and interface scattering can be inhibited. A portion of one or two of the insulating layer 110a, the insulating layer 110c, and the insulating layer 110d that overlaps with the liquid crystal element 60 may be removed by etching, for example. This also facilitates transmission of the electric fields of the conductive layer 112b and the conductive layer 112c to the liquid crystal 262. Furthermore, the capacitance between the conductive layer 112b and the conductive layer 112c can be increased in some cases.

In the liquid crystal element 60, both the conductive layer 112b and the conductive layer 112c may have comb-like top-view shapes. Meanwhile, when only one of the conductive layer 112b and the conductive layer 112c in the liquid crystal element 60 has a comb-like top-view shape as in the display device 50J, the conductive layer 112b and the conductive layer 112c partly overlap with each other. This allows the capacitance between the conductive layer 112b and the conductive layer 112c to be used as a storage capacitor; thus, a capacitor does not need to be provided separately, and the aperture ratio of the display device can be increased.

### [Display Device 50K]

A display device 50K illustrated in FIG. 36B is different from the display device 50I in that the pixel electrode is provided over the common electrode. In the display device 50K, the conductive layer 112b functions as the pixel electrode of the liquid crystal element 60. The insulating layer 106 and the insulating layer 109 are provided over the conductive layer 112b, and the conductive layer 263 is provided over the insulating layer 109. The conductive layer 263 functions as the common electrode of the liquid crystal element 60. In a plan view, the conductive layer 263 has a comb-like shape or a shape with a slit.

This embodiment can be combined with any of the other embodiments or the examples as appropriate. In this specification, in the case where a plurality of structure examples are described in one embodiment, the structure examples can be combined as appropriate.

### Embodiment 3

In this embodiment, electronic devices of embodiments of the present invention will be described.

Electronic devices of this embodiment each include the display device of one embodiment of the present invention in a display portion. The display device of one embodiment of the present invention can be easily increased in resolution and definition and has a high frame frequency. Thus, the display device of one embodiment of the present invention can be used for a display portion of a variety of electronic devices.

The semiconductor device of one embodiment of the present invention can also be applied to any other portion of an electronic device than a display portion. For example, the semiconductor device of one embodiment of the present invention is preferably used for a control portion of an electronic device to enable higher speed and lower power consumption.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the display device of one embodiment of the present invention can have high resolution, and thus can be suitably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280× 720), FHD (number of pixels: 1920×1080), WQHD (number of pixels: 2560×1440), WQXGA (number of pixels: 2560×1600), 4K (number of pixels: 3840× 2160), or 8K (number of pixels: 7680× 4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device of this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

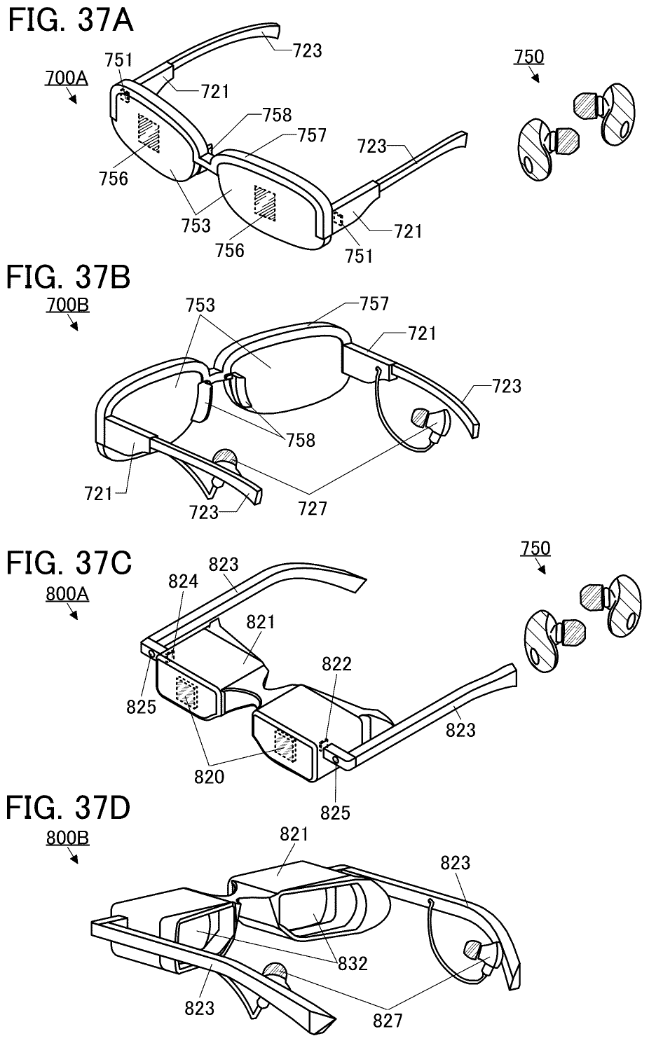

Examples of head-mounted wearable devices will be described with reference to FIG. 37A to FIG. 37D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 37A and an electronic device 700B illustrated in FIG. 37B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The display device of one embodiment of the present invention can be used for the display panels 751. Thus, the electronic device 700A and the electronic device 700B can be electronic devices that are capable of performing ultrahigh-resolution display and that have a high frame frequency.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic device 700A and the electronic device 700B are each provided with a battery, so that they can be charged wirelessly and/or by wire.

A touch sensor module may be provided in the housing 721. The touch sensor module has a function of detecting touch on the outer surface of the housing 721. Detecting a tap operation, a slide operation, or the like by the user with the touch sensor module enables executing various types of processing. For example, a moving image can be paused or restarted by a tap operation, and can be fast-forwarded or fast-reversed by a slide operation. When the touch sensor module is provided in each of the two housings 721, the range of the operation can be expanded.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 37C and an electronic device 800B illustrated in FIG. 37D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic device 800A and the electronic device 800B can be electronic devices that are capable of performing ultrahigh-resolution display and that have a high frame frequency. Such electronic devices can provide an enhanced sense of immersion to the user.

The display portions 820 are positioned inside the housing 821 so as to be seen through the lenses 832. When the pair of display portions 820 display different images, three-dimensional display using parallax can be performed.

Each of the electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic device 800A or the electronic device 800B can be mounted on the user's head with the wearing portions 823. FIG. 37C, for example, illustrates an example where the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Note that although an example where the image capturing portion 825 is included is described here, a range sensor that is capable of measuring the distance to an object (hereinafter such a sensor is also referred to as a sensing portion) is provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more pieces of information can be obtained and a gesture operation with higher accuracy is possible.

The electronic device 800A may include a vibration mechanism that functions as a bone-conduction earphone. For example, any one or more of the display portion 820, the housing 821, and the wearing portion 823 can include the vibration mechanism. In that case, without additionally requiring an audio device such as headphones, earphones, or a speaker, the user can enjoy video and sound only by wearing the electronic device 800A.

The electronic device 800A and the electronic device 800B may each include an input terminal. To the input terminal, for example, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not shown) and have a wireless communication function. The earphones 750 can receive information (e.g., audio data) from the electronic device with the wireless communication function. For example, the electronic device 700A in FIG. 37A has a function of transmitting information to the earphones 750 with the wireless communication function. For another example, the electronic device 800A in FIG. 37C has a function of transmitting information to the earphones 750 with the wireless communication function.

The electronic device may include an earphone portion. The electronic device 700B in FIG. 37B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B in FIG. 37D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type devices (the electronic device 700A, the electronic device 700B, and the like) and the goggles-type devices (the electronic device 800A, the electronic device 800B, and the like) are suitable as the electronic devices of embodiments of the present invention.

The electronic device of one embodiment of the present invention can transmit information to earphones by wire or wirelessly.

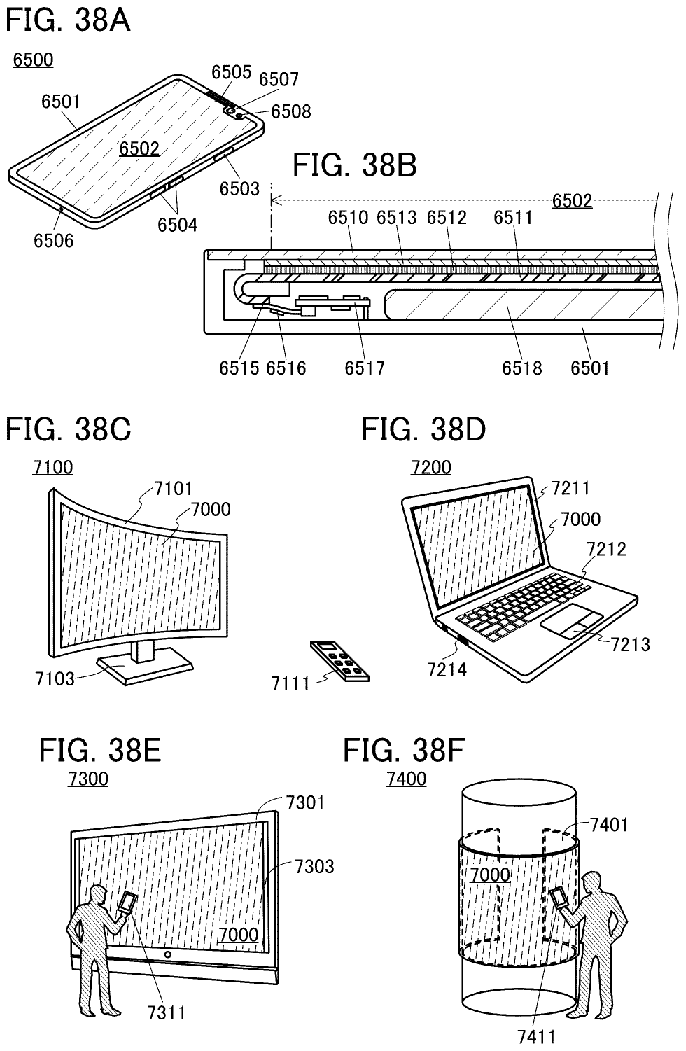

An electronic device 6500 illustrated in FIG. 38A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic device 6500 can be an electronic device that is capable of performing ultrahigh-resolution display and that has a high frame frequency.

FIG. 38B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 38C illustrates an example of a television device. In a television device 7100, a display portion 7000 is incorporated in a housing 7101. Here, the housing 7101 is supported by a stand 7103.

The display device of one embodiment of the present invention can be used in the display portion 7000. Thus, the television device 7100 can be an electronic device that is capable of performing ultrahigh-resolution display and that has a high frame frequency.

Operation of the television device 7100 illustrated in FIG. 38C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 38D illustrates an example of a notebook personal computer. The notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, the notebook personal computer 7200 can be an electronic device that is capable of performing ultrahigh-resolution display and that has a high frame frequency.

FIG. 38E and FIG. 38F illustrate examples of digital signage.

Digital signage 7300 illustrated in FIG. 38E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 38F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIG. 38E and FIG. 38F. Thus, the digital signage 7300 and the digital signage 7400 can be electronic devices that are capable of performing ultrahigh-resolution display and that have a high frame frequency.

The display portion 7000 having a larger area can provide a larger amount of information at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 38E and FIG. 38F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

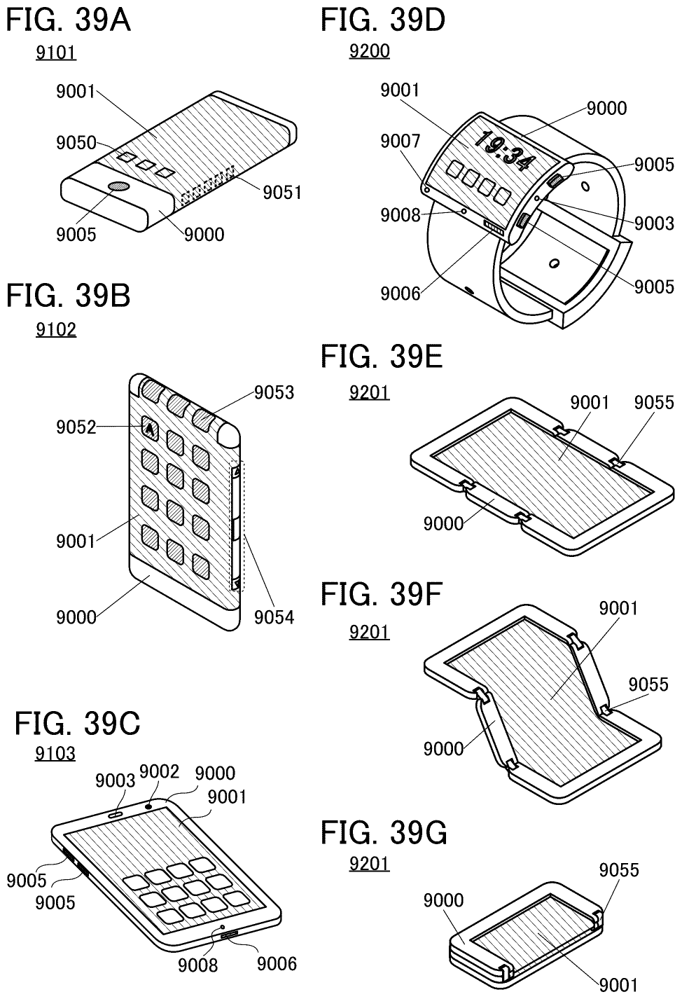

Electronic devices illustrated in FIG. 39A to FIG. 39G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIG. 39A to FIG. 39G, the display device of one embodiment of the present invention can be used in the display portion 9001. It is thus possible to obtain electronic devices that are capable of performing ultrahigh-resolution display and that have a high frame frequency.

The electronic devices illustrated in FIG. 39A to FIG. 39G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera, for example, and have a function of capturing a still image or a moving image, a function of storing the captured image in a storage medium (an external storage medium or a storage medium incorporated in the camera), a function of displaying the captured image on the display portion, and the like.

The electronic devices in FIG. 39A to FIG. 39G will be described in detail below.

FIG. 39A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 39A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 39B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 39C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 39D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 39E to FIG. 39G are perspective views of a foldable portable information terminal 9201. FIG. 39E is a perspective view illustrating the portable information terminal 9201 that is opened. FIG. 39G is a perspective view illustrating the portable information terminal 9201 that is folded. FIG. 39F is a perspective view illustrating the portable information terminal 9201 that is shifted from one of the states in FIG. 39E and FIG. 39G to the other. The portable information terminal 9201 is highly portable in the folded state and is highly browsable in the opened state because of its seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments or the examples as appropriate. In this specification, in the case where a plurality of structure examples are described in one embodiment, the structure examples can be combined as appropriate.

### Example 1

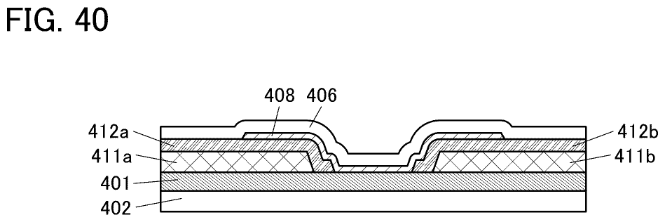

This example describes fabrication and evaluation results of samples in each of which a conductive layer and a metal oxide layer were formed over an insulating layer including hydrogen. FIG. 40 is a cross-sectional view illustrating the structure of the samples fabricated in this example. In this example, first, an insulating layer 401 was formed over a glass substrate 402. In this example, a plurality of samples differing in at least one of the material, thickness, and film formation conditions for the insulating layer 401 were fabricated.

Next, an approximately 300-nm-thick copper film was formed over the insulating layer 401 by a sputtering method and processed to form a conductive layer 411a and a conductive layer 411b. After that, an approximately 100-nm-thick ITSO film was formed over the insulating layer 401, the conductive layer 411a, and the conductive layer 411b by a sputtering method and processed to form a conductive layer 412a covering the conductive layer 411a and a conductive layer 412b covering the conductive layer 411b.

Next, a metal oxide layer 408 was formed over the insulating layer 401, the conductive layer 412a, and the conductive layer 412b. The metal oxide layer 408 was formed to be in contact with part of the top surface of the conductive layer 412a and part of the top surface of the conductive layer 412b. The metal oxide layer 408 was formed to be in contact with the top surface of the insulating layer 401, a side surface of the conductive layer 412a, and a side surface of the conductive layer 412b in a region between the conductive layer 412a and the conductive layer 412b. The metal oxide layer 408 was an approximately 20-nm-thick In—Ga—Zn oxide film. The metal oxide layer 408 was formed by a sputtering method using a metal oxide target whose atomic ratio was In:Ga:Zn=1:1:1 under the conditions where the oxygen flow rate ratio was 10%, the substrate temperature was room temperature, the pressure was 0.6 Pa, and the power supply was 2500 W.

Next, as an insulating layer 406, an approximately 100-nm-thick silicon oxynitride film was formed over the metal oxide layer 408, the conductive layer 412a, and the conductive layer 412b by a PECVD method.

Table 1 shows the carrier concentration [cm⁻³] in the metal oxide layer 408 of each of the samples fabricated in this example. Table 1 also shows the contact resistance [Ω·cm²] between the metal oxide layer 408 and each of the conductive layer 412a and the conductive layer 412b (hereinafter, also simply referred to as contact resistance).

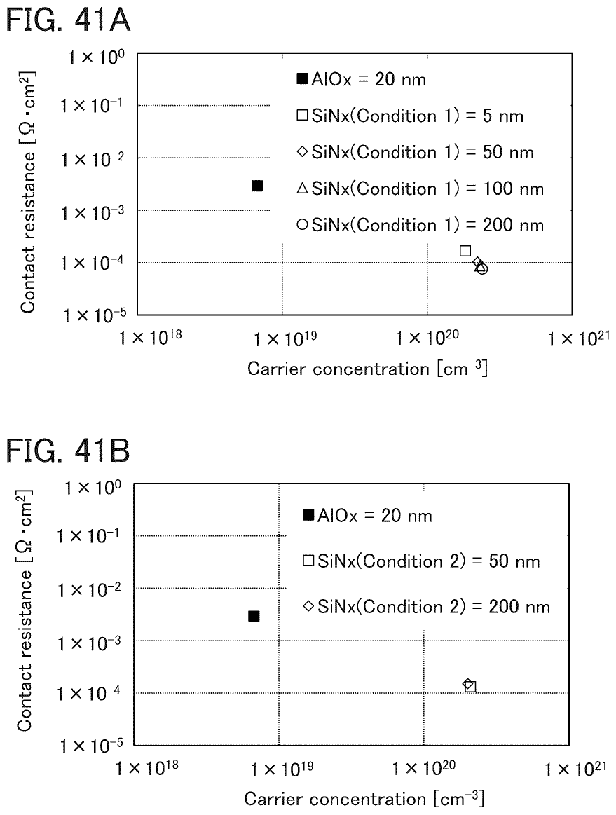

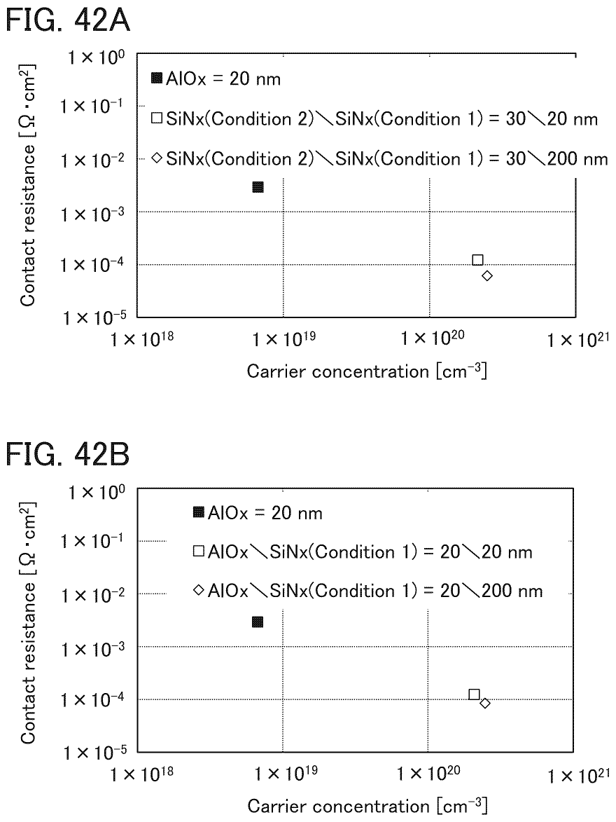

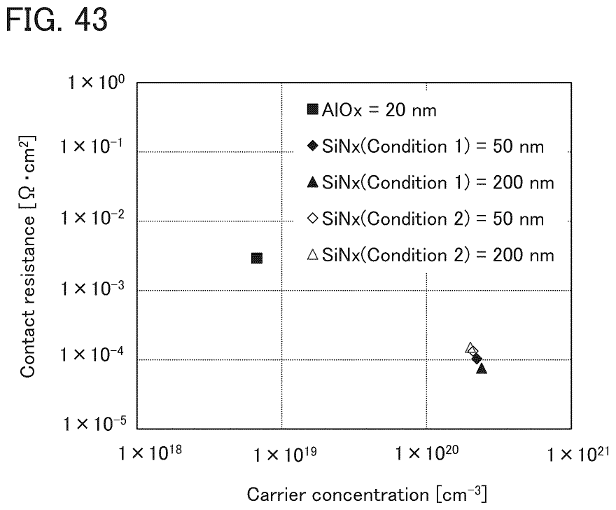

FIG. 41A, FIG. 41B, FIG. 42A, FIG. 42B, and FIG. 43 are graphs in which the horizontal axis represents the carrier concentration [cm⁻³] and the vertical axis represents the contact resistance [Ω·cm²]. In “Sample” in Table 1 and the legends in FIG. 41A to FIG. 43, the material and the thickness of the insulating layer 401 are shown. In “Sample” in Table 1 and the legends in FIG. 41A to FIG. 43, aluminum oxide is denoted as AlOx and silicon nitride is denoted as SiNx.

TABLE 1

| | Carrier | Contact |
|---|---|---|
| | concentration | resistance |
| Sample | [cm⁻³] | [Ω · cm²] |
| AlOx = 20 nm | 6.72 × 10¹⁸ | 2.92 × 10⁻³ |
| SiNx (Condition 1) = 5 nm | 1.83 × 10²⁰ | 1.68 × 10⁻⁴ |
| SiNx (Condition 1) = 50 nm | 2.23 × 10²⁰ | 1.03 × 10⁻⁴ |
| SiNx (Condition 1) = 100 nm | 2.31 × 10²⁰ | 8.69 × 10⁻⁵ |
| SiNx (Condition 1) = 200 nm | 2.40 × 10²⁰ | 7.54 × 10⁻⁵ |
| SiNx (Condition 2) = 50 nm | 2.09 × 10²⁰ | 1.33 × 10⁻⁴ |
| SiNx (Condition 2) = 200 nm | 2.00 × 10²⁰ | 1.51 × 10⁻⁴ |
| SiNx (Condition 2)\SiNx | 2.14 × 10²⁰ | 1.22 × 10⁻⁴ |
| (Condition 1) = 30\20 nm | | |
| SiNx (Condition 2)\SiNx | 2.47 × 10²⁰ | 6.13 × 10⁻⁵ |
| (Condition 1) = 30\200 nm | | |
| AlOx\SiNx | 2.08 × 10²⁰ | 1.24 × 10⁻⁴ |
| (Condition 1) = 20\20 nm | | |
| AlOx\SiNx | 2.47 × 10²⁰ | 8.48 × 10⁻⁵ |
| (Condition 1) = 20\200 nm | | |

In the sample “AlOx”, the insulating layer 401 was formed by a sputtering method using aluminum oxide as a target under the conditions where the oxygen flow rate ratio was 70%, the substrate temperature was room temperature, the pressure was 0.6 Pa, and the power supply was 2500 W. In the sample “SiNx (Condition 1)”, the insulating layer 401 was formed by a PECVD method using a SiH₄ gas at a flow rate of 200 sccm, a N₂ gas at a flow rate of 2000 sccm, and a NH₃ gas at a flow rate of 2000 sccm under the conditions where the pressure was 200 Pa, the power supply was 2000 W, and the substrate temperature was 350° C. In the sample “SiNx (Condition 2)”, the insulating layer 401 was formed by a PECVD method using a SiH₄ gas at a flow rate of 200 sccm, a N₂ gas at a flow rate of 2000 sccm, and a NH₃ gas at a flow rate of 100 sccm under the conditions where the pressure was 100 Pa, the power supply was 2000 W, and the substrate temperature was 350° C. That is, the insulating layer 401 was formed by a PECVD method in a hydrogen-containing atmosphere under each of Condition 1 and Condition 2. The flow rate of NH₃ under Condition 1 was higher than that under Condition 2. Here, Condition 2 assumes film formation conditions similar to the film formation conditions for the insulating layer 110a and the insulating layer 110c described in Embodiment 1.

In the sample “SiNx (Condition 2) \SiNx (Condition 1)”, the insulating layer 401 had a stacked-layer structure of a silicon nitride (SiNx) layer formed under Condition 2 and a silicon nitride layer formed over the silicon nitride layer under Condition 1. In the sample “AlOx\SiNx (Condition 1)”, the insulating layer 401 had a stacked-layer structure of an aluminum oxide (AlOx) layer formed under conditions similar to those for “AlOx” above and a silicon nitride layer formed over the aluminum oxide layer under Condition 1.

As shown in Table 1 and FIG. 41A to FIG. 43, it was confirmed that in the case where the insulating layer 401 included the layer formed in a hydrogen-containing atmosphere (SiNx layer), the carrier concentration in the metal oxide layer 408 was higher and the contact resistance was lower than in the case where the insulating layer 401 did not include the layer (AlOx=20 nm). Specifically, in each of the samples in which the insulating layer 401 included the layer formed in a hydrogen-containing atmosphere, the carrier concentration was higher than or equal to 1×10²⁰ cm⁻³ and the contact resistance was lower than or equal to 1×10⁻³ Ω·cm² in this example. It was also confirmed that the larger the thickness of the SiNx layer was, the higher the carrier concentration in the metal oxide layer 408 was and the lower the contact resistance was. Furthermore, as shown in FIG. 43, it was confirmed that the carrier concentration in the metal oxide layer 408 was higher and the contact resistance was lower under Condition 2 than under Condition 1. That is, it was confirmed that the carrier concentration in the metal oxide layer 408 was higher and the contact resistance was lower under the conditions where the SiNx layer was formed in an atmosphere with NH₃ at a high flow rate.

### Example 2

This example describes manufacture and evaluation results of transistors of one embodiment of the present invention.

In this example, the transistors each corresponding to the structure of the transistor 100 illustrated in FIG. 6A, FIG. 6B, FIG. 6C, and the like were manufactured. For the method for manufacturing the transistors, FIG. 24A to FIG. 27B can be referred to.

First, as the insulating layer 101, an approximately 200-nm-thick silicon nitride film was formed by a PECVD method over the substrate 102, which was a glass substrate. Specifically, the insulating layer 101 was formed using a SiH₄ gas at a flow rate of 200 sccm, a N₂ gas at a flow rate of 2000 sccm, and a NH₃ gas at a flow rate of 2000 sccm under the conditions where the pressure was 200 Pa, the power supply was 2000 W, and the substrate temperature was 350° C. Next, an approximately 300-nm-thick copper film and an approximately 100-nm-thick ITSO film were formed in this order over the insulating layer 101 by a sputtering method and processed, so that the conductive layer 112a was formed.

Then, the insulating layer 110a and the insulating layer 110b were formed in this order over the conductive layer 112a and the insulating layer 101. As the insulating layer 110a, an approximately 100-nm-thick silicon nitride film was formed by a PECVD method. Specifically, the insulating layer 110a was formed using a SiH₄ gas at a flow rate of 200 sccm, a N₂ gas at a flow rate of 2000 sccm, and a NH₃ gas at a flow rate of 100 sccm under the conditions where the pressure was 100 Pa, the power supply was 2000 W, and the substrate temperature was 350° C. As the insulating layer 110b, a 500-nm-thick silicon oxynitride film was formed by a PECVD method. Specifically, the insulating layer 110b was formed using a SiH₄ gas at a flow rate of 200 sccm and a N₂O gas at a flow rate of 6000 sccm under the conditions where the pressure was 200 Pa, the power supply was 1200 W, and the substrate temperature was 350° C.

Here, the thickness of the insulating layer 110b was set to the designed channel length of the transistor. In other words, the designed channel length of the transistor was 0.50 μm.

Next, plasma treatment was performed for 240 seconds in an atmosphere containing a N₂O gas. The power supply was 500 W.

Subsequently, over the insulating layer 110b, an approximately 20-nm-thick In—Ga—Zn oxide film was formed, so that the metal oxide layer 149 was formed. The In—Ga—Zn oxide film was formed by a sputtering method using a metal oxide target whose atomic ratio was In:Ga:Zn=1:1:1 with an oxygen flow rate ratio of 100% at a substrate temperature of room temperature. After the formation of the In—Ga—Zn oxide film, heat treatment was performed at 250° C. for one hour. After that, the metal oxide layer 149 was removed by a wet etching method.

Then, the insulating layer 110c and the insulating layer 110d were formed in this order over the conductive layer 110b. As the insulating layer 110c, an approximately 50-nm-thick silicon nitride film was formed by a PECVD method. Specifically, the insulating layer 110c was formed using a SiH₄ gas at a flow rate of 200 sccm, a N₂ gas at a flow rate of 2000 sccm, and a NH₃ gas at a flow rate of 100 sccm under the conditions where the pressure was 100 Pa, the power supply was 2000 W, and the substrate temperature was 350° C. As the insulating layer 110d, an approximately 100-nm-thick silicon nitride film was formed by a PECVD method. Specifically, the insulating layer 110d was formed using a SiH₄ gas at a flow rate of 200 sccm, a N₂ gas at a flow rate of 2000 sccm, and a NH₃ gas at a flow rate of 2000 sccm under the conditions where the pressure was 200 Pa, the power supply was 2000 W, and the substrate temperature was 350° C.

Next, an approximately 100-nm-thick ITSO film was formed over the insulating layer 110d by a sputtering method and processed, so that the conductive layer 112b was formed.

Then, the conductive layer 112b was processed by a wet etching method, so that the opening 143 was formed in the conductive layer 112b. Furthermore, the insulating layer 110d, the insulating layer 110c, the insulating layer 110b, and the insulating layer 110a were processed by a dry etching method, so that the opening 141 was formed in the insulating layer 110d, the insulating layer 110c, the insulating layer 110b, and the insulating layer 110a.

Next, a metal oxide film was formed as the semiconductor film 108f over the insulating layer 110d and the conductive layer 112b. As the semiconductor film 108f, an approximately 20-nm-thick In—Ga—Zn oxide film was formed. The In—Ga—Zn oxide film was formed by a sputtering method using a metal oxide target whose atomic ratio was In:Ga:Zn=1:1:1 with an oxygen flow rate ratio of 10% at a substrate temperature of room temperature. After the formation of the In—Ga—Zn oxide film, heat treatment was performed at 350° C. in a CDA atmosphere for one hour. After that, the semiconductor film 108f was processed to form a metal oxide layer as the semiconductor layer 108.

Next, the insulating layer 106 was formed over the insulating layer 110d, the conductive layer 112b, and the semiconductor layer 108. As the insulating layer 106, an approximately 50-nm-thick silicon oxynitride film was formed by a PECVD method. Specifically, the insulating layer 106 was formed under the conditions where the flow rates of a SiH₄ gas and a N₂O gas were respectively 50 sccm and 18000 sccm, the pressure was 200 Pa, the power supply was 250 W, and the substrate temperature was 350° C. The insulating layer 106 was formed at a lower film formation rate than the insulating layer 110b.

Then, conductive films to be the conductive layer 104 were formed over the insulating layer 106 and processed, so that the conductive layer 104 was formed. As the conductive films to be the conductive layer 104, an approximately 50-nm-thick titanium film, an approximately 400-nm-thick aluminum film, and an approximately 50-nm-thick titanium film were formed in this order by a sputtering method.

After that, as the insulating layer 109, an approximately 300-nm-thick silicon nitride oxide film was formed by a PECVD method. Subsequently, heat treatment was performed at 300° C. in a CDA atmosphere for one hour. After that, an approximately 1.5-μm-thick polyimide film was formed as a planarization layer (not shown), and heat treatment was performed at 250° C. in a nitrogen atmosphere for one hour.

The transistors manufactured in this example were n-channel transistors, and the designed channel length (L) was 0.50 μm as described above. The designed channel width (W) was 6.30 μm (opening diameter: 2 μmφ).

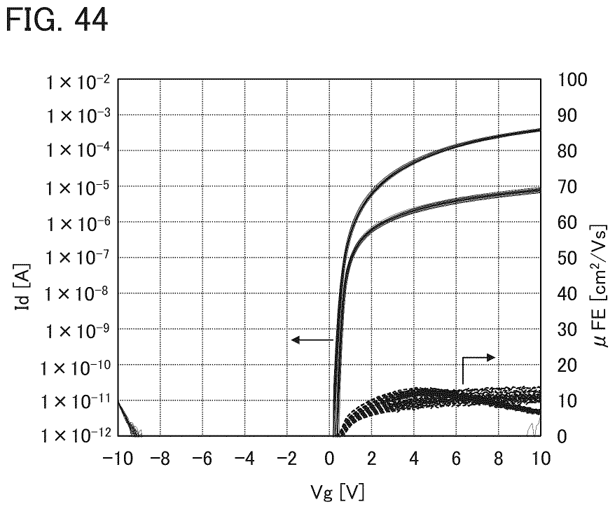

Next, the Id-Vg characteristics of the transistors manufactured in this example were measured. FIG. 44 shows the Id-Vg characteristics of the transistors of the case where the conductive layer 112b was made to function as the source electrode. In FIG. 44, the vertical axes represent the drain current Id [A] and the field-effect mobility μFE [cm²/Vs], and the horizontal axis represents the gate voltage Vg [V]. In FIG. 44, the solid lines indicate the Id-Vg characteristics and the dotted lines indicate the field-effect mobility.

As the measurement conditions of the Id-Vg characteristics of the transistors, the voltage applied to the conductive layer 104 (gate voltage Vg) was changed from −10 V to +10 V in increments of 0.1 V. The voltage applied to the source electrode (source voltage Vs) was 0 V, and the voltage applied to the drain electrode (drain voltage Vd) was 0.1 V or 5.1 V. Note that in FIG. 44, two pieces of data are shown as each of the drain current Id [A] and the field-effect mobility μFE [cm²/Vs]. Among the two pieces of data, the data with a larger value corresponds to the drain voltage Vd=5.1 V, and the data with a smaller value corresponds to the drain voltage Vd=0.1 V.

As shown in FIG. 44, it was confirmed that the transistors manufactured in this example had a high on-state current and favorable switching characteristics. The average value of the threshold voltages of the transistors manufactured in this example was 0.72 V, which is a positive value. Thus, it was confirmed that the transistors with normally-off characteristics were manufactured.

The transistors had an effective channel length of 0.62 μm, which was larger than the designed channel length, 0.50 μm.

In the transistors manufactured in this example, the insulating layer 101 and the insulating layer 110d were formed under the conditions where the flow rate of NH₃ was higher than that for the insulating layer 110a and the insulating layer 110c. This presumably allowed the insulating layer 101 and the insulating layer 110d to have a higher hydrogen content than the insulating layer 110a and the insulating layer 110c. Furthermore, the transistors with a high on-state current were manufactured presumably because hydrogen included in the insulating layer 101 was supplied to the region of the semiconductor layer 108 that was in contact with the conductive layer 112a to reduce the contact resistance between the semiconductor layer 108 and the conductive layer 112a, and hydrogen included in the insulating layer 110d was supplied to the region of the semiconductor layer 108 that was in contact with the conductive layer 112b to reduce the contact resistance between the semiconductor layer 108 and the conductive layer 112b.

The insulating layer 110a, which does not easily allow diffusion of hydrogen, presumably inhibited hydrogen included in the insulating layer 101 from being supplied to, for example, the region of the semiconductor layer 108 that was in contact with the insulating layer 110a and the region of the semiconductor layer 108 that was in contact with the insulating layer 110b. Furthermore, the insulating layer 110c, which does not easily allow diffusion of hydrogen, presumably inhibited hydrogen included in the insulating layer 110d from being supplied to, for example, the region of the semiconductor layer 108 that was in contact with the insulating layer 110c and the region of the semiconductor layer 108 that was in contact with the insulating layer 110b. This presumably made the effective channel lengths of the transistors manufactured in this example larger than the designed channel length. This presumably allowed the manufacture of the transistors having normally-off characteristics and favorable switching characteristics.

### Example 3

This example describes manufacture and evaluation results of transistors of one embodiment of the present invention.

In this example, the transistors each corresponding to the structure of the transistor 100 illustrated in FIG. 6A, FIG. 6B, FIG. 6C, and the like were manufactured. A plurality of the transistors were manufactured over one substrate 102. For the method for manufacturing the transistors, FIG. 24A to FIG. 27B can be referred to.

First, as the insulating layer 101, an approximately 30-nm-thick silicon nitride film was formed by a PECVD method over the substrate 102, which was a glass substrate. Specifically, the insulating layer 101 was formed using a SiH₄ gas at a flow rate of 200 sccm, a N₂ gas at a flow rate of 2000 sccm, and a NH₃ gas at a flow rate of 2000 sccm under the conditions where the pressure was 200 Pa, the power supply was 2000 W, and the substrate temperature was 200° C.

Next, an approximately 10-nm-thick ITSO film and an approximately 100-nm-thick copper film were formed in this order over the insulating layer 101 by a sputtering method and processed. After that, an approximately 100-nm-thick ITSO film was formed by a sputtering method and processed. Thus, the conductive layer 112a was formed.

Then, the insulating layer 110a and the insulating layer 110b were formed in this order over the conductive layer 112a and the insulating layer 101. As the insulating layer 110a, an approximately 200-nm-thick silicon nitride film was formed by a PECVD method. Specifically, the insulating layer 110a was formed using a SiH₄ gas at a flow rate of 200 sccm, a N₂ gas at a flow rate of 2000 sccm, and a NH₃ gas at a flow rate of 100 sccm under the conditions where the pressure was 100 Pa, the power supply was 2000 W, and the substrate temperature was 350° C. As the insulating layer 110b, a 500-nm-thick silicon oxynitride film was formed by a PECVD method. Specifically, the insulating layer 110b was formed using a SiH₄ gas at a flow rate of 200 sccm and a N₂O gas at a flow rate of 6000 sccm under the conditions where the pressure was 200 Pa, the power supply was 1200 W, and the substrate temperature was 350° C.

Here, the thickness of the insulating layer 110b was set to the designed channel length of the transistor. In other words, the designed channel length of the transistor was 0.50 μm.

Subsequently, heat treatment was performed at 400° C. in a nitrogen atmosphere for one hour. Next, plasma treatment was performed for 240 seconds in an atmosphere containing a N₂O gas. The flow rate of the N₂O gas was 3000 sccm, the pressure was 133 Pa, and the power supply was 500 W.

Subsequently, over the insulating layer 110b, an approximately 20-nm-thick In—Ga—Zn oxide film was formed, so that the metal oxide layer 149 was formed. The In—Ga—Zn oxide film was formed by a sputtering method using a metal oxide target whose atomic ratio was In:Ga:Zn=1:1:1 with an oxygen flow rate ratio of 100% at a substrate temperature of room temperature. After the formation of the In—Ga—Zn oxide film, heat treatment was performed at 250° C. for one hour. After that, the metal oxide layer 149 was removed by a wet etching method.

Then, the insulating layer 110c and the insulating layer 110d were formed in this order over the conductive layer 110b. As the insulating layer 110c, an approximately 100-nm-thick silicon nitride film was formed by a PECVD method. Specifically, the insulating layer 110c was formed using a SiH₄ gas at a flow rate of 200 sccm, a N₂ gas at a flow rate of 2000 sccm, and a NH₃ gas at a flow rate of 100 sccm under the conditions where the pressure was 100 Pa, the power supply was 2000 W, and the substrate temperature was 350° C. As the insulating layer 110d, an approximately 100-nm-thick silicon nitride film was formed by a PECVD method. Specifically, the insulating layer 110d was formed using a SiH₄ gas at a flow rate of 200 sccm, a N₂ gas at a flow rate of 2000 sccm, and a NH₃ gas at a flow rate of 2000 sccm under the conditions where the pressure was 200 Pa, the power supply was 2000 W, and the substrate temperature was 350° C.

Next, an approximately 100-nm-thick ITSO film was formed over the insulating layer 110d by a sputtering method and processed, so that the conductive layer 112b was formed.

Then, the conductive layer 112b was processed by a wet etching method, so that the opening 143 was formed in the conductive layer 112b. Furthermore, the insulating layer 110d, the insulating layer 110c, the insulating layer 110b, and the insulating layer 110a were processed by a dry etching method, so that the opening 141 was formed in the insulating layer 110d, the insulating layer 110c, the insulating layer 110b, and the insulating layer 110a.

Next, a metal oxide film was formed as the semiconductor film 108f over the insulating layer 110d and the conductive layer 112b. As the semiconductor film 108f, an approximately 20-nm-thick In—Ga—Zn oxide film was formed. The In—Ga—Zn oxide film was formed by a sputtering method using a metal oxide target whose atomic ratio was In:Ga:Zn=1:1:1 with an oxygen flow rate ratio of 10% at a substrate temperature of room temperature. After the formation of the In—Ga—Zn oxide film, heat treatment was performed at 350° C. in a CDA atmosphere for one hour. After that, the semiconductor film 108f was processed to form a metal oxide layer as the semiconductor layer 108.

Next, the insulating layer 106 was formed over the insulating layer 110d, the conductive layer 112b, and the semiconductor layer 108. As the insulating layer 106, an approximately 50-nm-thick silicon oxynitride film was formed by a PECVD method. Specifically, the insulating layer 106 was formed under the conditions where the flow rates of a SiH₄ gas and a N₂O gas were respectively 50 sccm and 18000 sccm, the pressure was 200 Pa, the power supply was 250 W, and the substrate temperature was 350° C. The insulating layer 106 was formed at a lower film formation rate than the insulating layer 110b.

Then, conductive films to be the conductive layer 104 were formed over the insulating layer 106 and processed, so that the conductive layer 104 was formed. As the conductive films to be the conductive layer 104, an approximately 50-nm-thick titanium film, an approximately 400-nm-thick aluminum film, and an approximately 50-nm-thick titanium film were formed in this order by a sputtering method.

After that, as the insulating layer 109, an approximately 300-nm-thick silicon nitride oxide film was formed by a PECVD method. Subsequently, heat treatment was performed at 300° C. in a CDA atmosphere for one hour. After that, an approximately 1.5-μm-thick polyimide film was formed as a planarization layer (not shown), and heat treatment was performed at 250° C. in a nitrogen atmosphere for one hour.

The transistors manufactured in this example were n-channel transistors, and the designed channel length was 0.50 μm as described above. The designed channel width was 6.30 μm (opening diameter: 2 μmø).

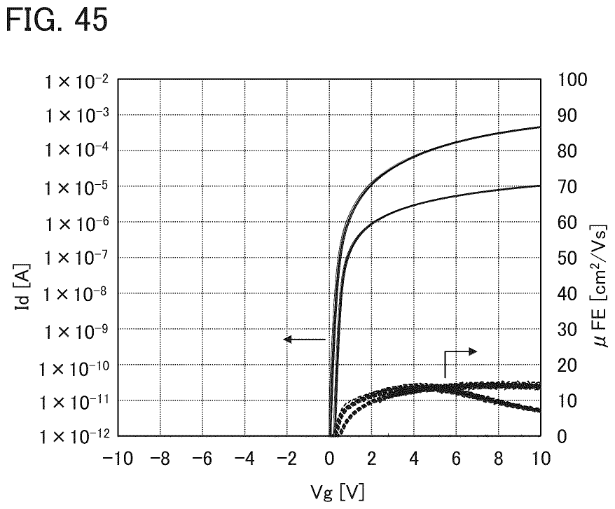

Next, the Id-Vg characteristics of the transistors manufactured in this example were measured. FIG. 45 shows the Id-Vg characteristics of the transistors of the case where the conductive layer 112b was made to function as the source electrode. In FIG. 45, the vertical axes represent the drain current Id [A] and the field-effect mobility μFE [cm²/Vs], and the horizontal axis represents the gate voltage Vg [V]. In FIG. 45, the solid lines indicate the Id-Vg characteristics and the dotted lines indicate the field-effect mobility.

As the measurement conditions of the Id-Vg characteristics of the transistors, the voltage applied to the conductive layer 104 (gate voltage Vg) was changed from −10 V to +10 V in increments of 0.1 V. The voltage applied to the source electrode (source voltage Vs) was 0 V, and the voltage applied to the drain electrode (drain voltage Vd) was 0.1 V or 5.1 V. Note that in FIG. 45, two pieces of data are shown as each of the drain current Id [A] and the field-effect mobility μFE [cm²/Vs]. Among the two pieces of data, the data with a larger value corresponds to the drain voltage Vd=5.1 V, and the data with a smaller value corresponds to the drain voltage Vd=0.1 V.

As shown in FIG. 45, it was confirmed that the transistors manufactured in this example had a high on-state current and favorable switching characteristics. The average value of the threshold voltages of the transistors manufactured in this example was 0.58 V, which is a positive value. Thus, it was confirmed that the transistors with normally-off characteristics were manufactured.

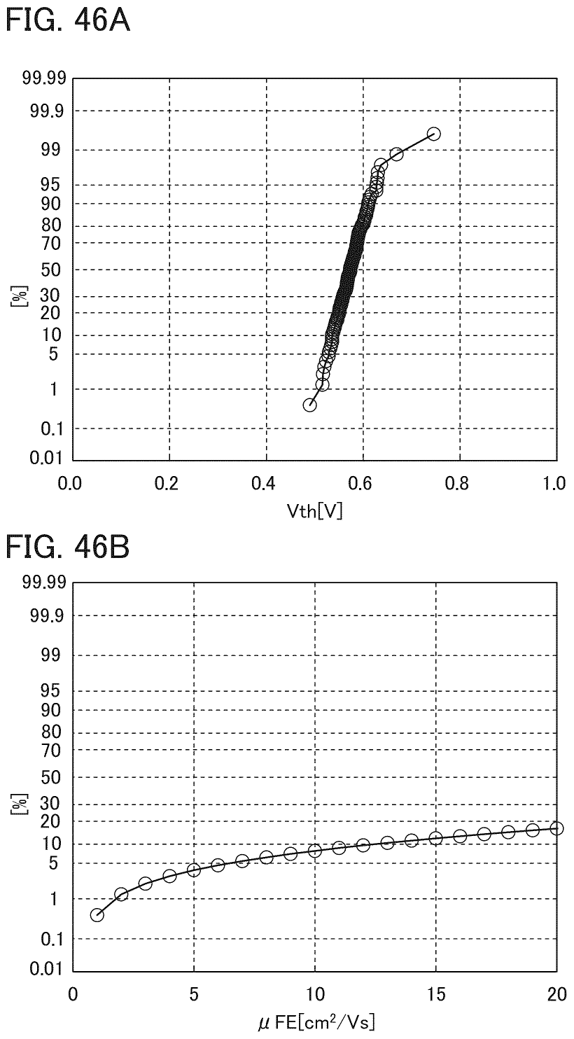

FIG. 46A shows the probability distribution of the threshold voltages Vth of the transistors manufactured in this example. FIG. 46B shows the probability distribution of the field-effect mobility μFE of the transistors manufactured in this example. In FIG. 46A and FIG. 46B, the threshold voltages Vth and the field-effect mobility μFE were measured with the source voltage Vs set to 0 V and the drain voltage Vd set to 0.1 V.

FIG. 46A and FIG. 46B show the cumulative probability of the threshold voltages Vth and the field-effect mobility μFE of 120 of the transistors. In FIG. 46A, the horizontal axis represents the threshold voltage Vth [V], and the vertical axis represents the cumulative probability [%]. In FIG. 46B, the horizontal axis represents the field-effect mobility μFE [cm²/Vs], and the vertical axis represents the cumulative probability [%]. Here, 3σ (σ is a standard deviation) of the threshold voltages Vth was 0.10 V, and 3σ of the field-effect mobility μFE was 1.3 cm²/Vs.

From the above, it was confirmed that all the transistors manufactured in this example had normally-off characteristics and a high on-state current. Furthermore, it was confirmed that a variation in electrical characteristics between the transistors was small.

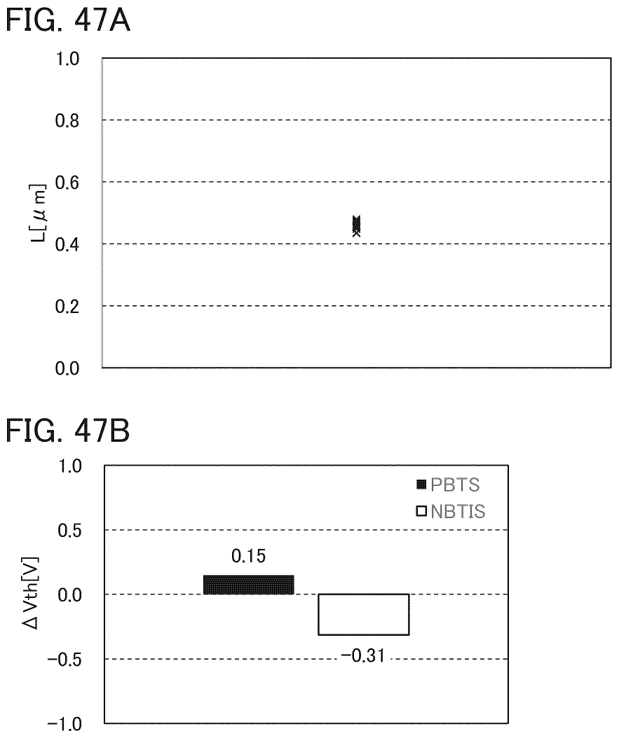

FIG. 47A is a graph showing the effective channel lengths L [μm] of the transistors manufactured in this example. The effective channel lengths L were calculated with reference to FIG. 45. The average value of the effective channel lengths L was 0.46 μm, which was close to the designed channel length, 0.50 μm. In addition, 3σ of the effective channel lengths L was 0.04 μm, which was much smaller than the average value of the effective channel lengths L, 0.46 μm. Thus, it was confirmed that a variation in the effective channel length L between the transistors was extremely small.

Next, the reliability of the transistors manufactured in the above manner was evaluated.

To evaluate the reliability, a GBT (Gate Bias Temperature) stress test was performed. In this example, a PBTS (Positive Bias Temperature Stress) test and an NBTIS (Negative Bias Temperature Illumination Stress) test were performed.

A test in which a state where a positive potential (positive bias) relative to a source potential and a drain potential is supplied to a gate is maintained at high temperatures is referred to as a PBTS test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation with light is performed are respectively referred to as a PBTIS (Positive Bias Temperature Illumination Stress) test and an NBTIS test.

In the PBTS test, the substrate 102 was held at 60° C., and a voltage of 0 V, a voltage of 0.1 V, and a voltage of 10 V were respectively applied to the source, the drain, and the gate of each transistor; this state was maintained for one hour. The test was performed in a dark environment. In the NBTIS test, the substrate 102 was held at 60° C., a voltage of 0 V was applied to the source and the drain of each transistor and a voltage of −10 V was applied to the gate thereof in a state where irradiation with white LED light at 5000 1× was performed; this state was maintained for one hour. The irradiation with white LED light was performed from the substrate 102 side. Here, the transistors had a threshold voltage of 0.25 V before the PBTS test and before the NBTIS test.

FIG. 47B shows the amount of change ΔVth [V] in threshold voltage before and after the PBTS test and the amount of change ΔVth [V] in threshold voltage before and after the NBTIS test. As shown in FIG. 47B, it was confirmed that both the amount of change in threshold voltage before and after the PBTS test and the amount of change in threshold voltage before and after the NBTIS test were small, indicating high reliability.

### Example 4

This example describes manufacture and evaluation results of transistors of one embodiment of the present invention.

In this example, the transistors each corresponding to the structure of the transistor 100 illustrated in FIG. 6A, FIG. 6B, FIG. 6C, and the like were manufactured. A plurality of the transistors were manufactured over one substrate 102. For the method for manufacturing the transistors, FIG. 24A to FIG. 27B can be referred to.

First, the insulating layer 101 and the conductive layer 112a were formed over the substrate 102, which was a glass substrate, under conditions similar to those described in Example 3. Then, the insulating layer 110a and the insulating layer 110b were formed in this order over the conductive layer 112a and the insulating layer 101. As the insulating layer 110a, an approximately 5-nm-thick aluminum oxide film was formed by a sputtering method with an oxygen flow rate ratio of 70% at a substrate temperature of room temperature. The insulating layer 110b was formed under conditions similar to those described in Example 3.

Next, plasma treatment was performed for 240 seconds in an atmosphere containing a N₂O gas. The flow rate of the N₂O gas was 8700 sccm, the pressure was 200 Pa, and the power supply was 500 W. Subsequently, under conditions similar to those described in Example 3, the metal oxide layer 149 was formed over the insulating layer 110b, heat treatment was performed, and then, the metal oxide layer 149 was removed.

Then, the insulating layer 110c and the insulating layer 110d were formed in this order over the conductive layer 110b. As the insulating layer 110c, an approximately 5-nm-thick aluminum oxide film was formed by a sputtering method with an oxygen flow rate ratio of 70% at a substrate temperature of room temperature. The insulating layer 110d was formed under conditions similar to those described in Example 3. Subsequently, the conductive layer 112b was formed under conditions similar to those described in Example 3.

Then, the conductive layer 112b was processed by a wet etching method, so that the opening 143 was formed in the conductive layer 112b. Furthermore, the insulating layer 110d, the insulating layer 110c, the insulating layer 110b, and the insulating layer 110a were processed by a dry etching method, so that the opening 141 was formed in the insulating layer 110d, the insulating layer 110c, the insulating layer 110b, and the insulating layer 110a.

Next, the semiconductor layer 108, the insulating layer 106, the conductive layer 104, the insulating layer 109, and a planarization layer were formed under conditions similar to those described in Example 3.

The transistors manufactured in this example were n-channel transistors, and the designed channel length was 0.50 μm. The designed channel width was 6.30 μm (opening diameter: 2 μmφ)

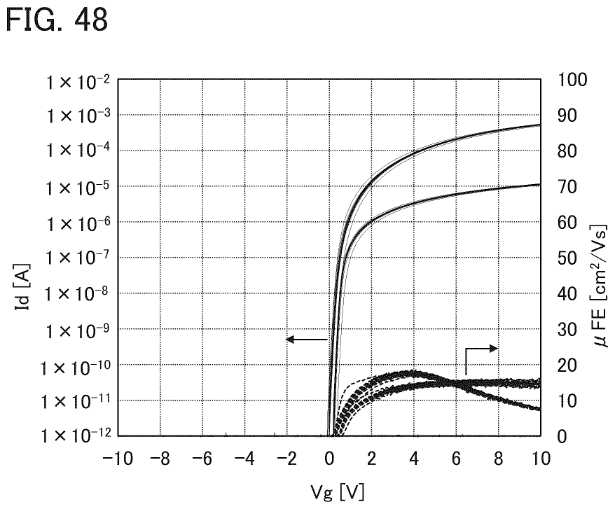

Next, the Id-Vg characteristics of the transistors manufactured in this example were measured. FIG. 48 shows the Id-Vg characteristics of the transistors of the case where the conductive layer 112b was made to function as the source electrode. In FIG. 48, the vertical axes represent the drain current Id [A] and the field-effect mobility μFE [cm²/Vs], and the horizontal axis represents the gate voltage Vg [V]. In FIG. 48, the solid lines indicate the Id-Vg characteristics and the dotted lines indicate the field-effect mobility. The measurement conditions of the Id-Vg characteristics of the transistors were similar to those in Example 3. Note that in FIG. 48, two pieces of data are shown as each of the drain current Id [A] and the field-effect mobility μFE [cm²/Vs] as in FIG. 45. Among the two pieces of data, the data with a larger value corresponds to the drain voltage Vd=5.1 V, and the data with a smaller value corresponds to the drain voltage Vd=0.1 V.

As shown in FIG. 48, it was confirmed that the transistors manufactured in this example had a high on-state current and favorable switching characteristics. The average value of the threshold voltages of the transistors manufactured in this example was 0.55 V, which is a positive value. Thus, it was confirmed that the transistors with normally-off characteristics were manufactured.

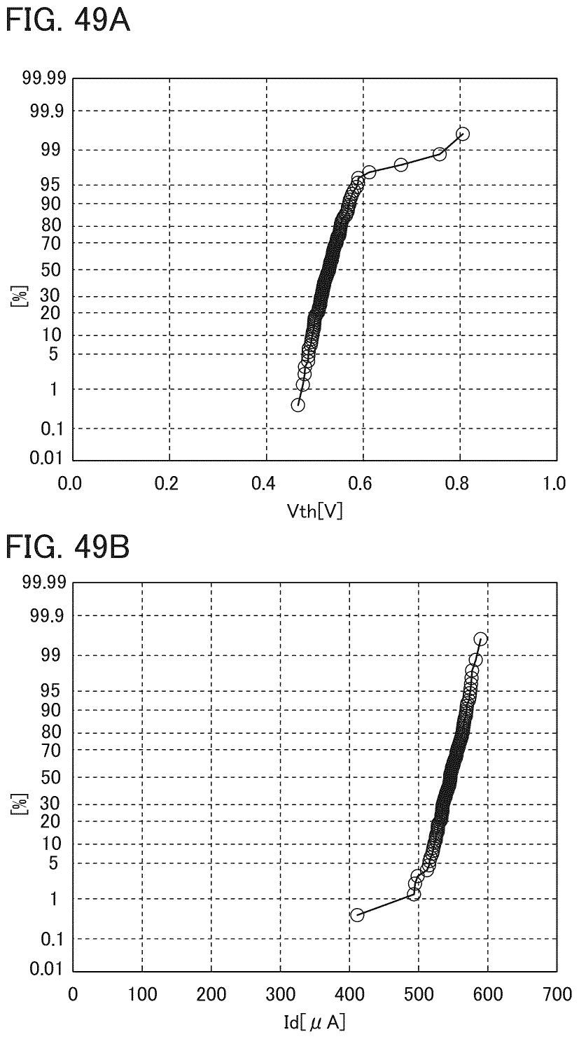

FIG. 49A shows the probability distribution of the threshold voltages Vth of the transistors manufactured in this example. FIG. 49B shows the probability distribution of the drain currents Id of the transistors manufactured in this example. In FIG. 49A, the threshold voltages Vth were measured with the source voltage Vs set to 0 V and the drain voltage Vd set to 0.1 V. In FIG. 49B, the drain currents Id were measured with the source voltage Vs set to 0 V, the drain voltage Vd set to 5.1 V, and the gate voltage set to 10 V. In FIG. 49B, the drain currents Id of the transistors in an on state were measured.

FIG. 49A and FIG. 49B show the cumulative probability of the threshold voltages Vth and the drain currents Id of 120 of the transistors. In FIG. 49A, the horizontal axis represents the threshold voltage Vth [V], and the vertical axis represents the cumulative probability [%]. In FIG. 49B, the horizontal axis represents the drain current Id [μA], and the vertical axis represents the cumulative probability [%]. Here, 3σ (σ is a standard deviation) of the threshold voltages Vth was 0.13 V, and 30 of the field-effect mobility μFE was 66.2 μA.

It was confirmed from FIG. 49A that each of the transistors manufactured in this example had a threshold voltage Vth higher than or equal to 0.46 V and normally-off characteristics. It was confirmed from FIG. 49B that each of the transistors manufactured in this example had a drain current Id higher than or equal to 400 μA in an on state and a high on-state current.

It was also confirmed from FIG. 49A that 116 of the 120 transistors had a threshold voltage Vth higher than or equal to 0.46 V and lower than or equal to 0.60 V. It was also confirmed from FIG. 49B that 116 of the 120 transistors had a drain current Id higher than or equal to 500 μA and lower than or equal to 600 μA. From the above, it was confirmed that a variation in electrical characteristics between the transistors was small.

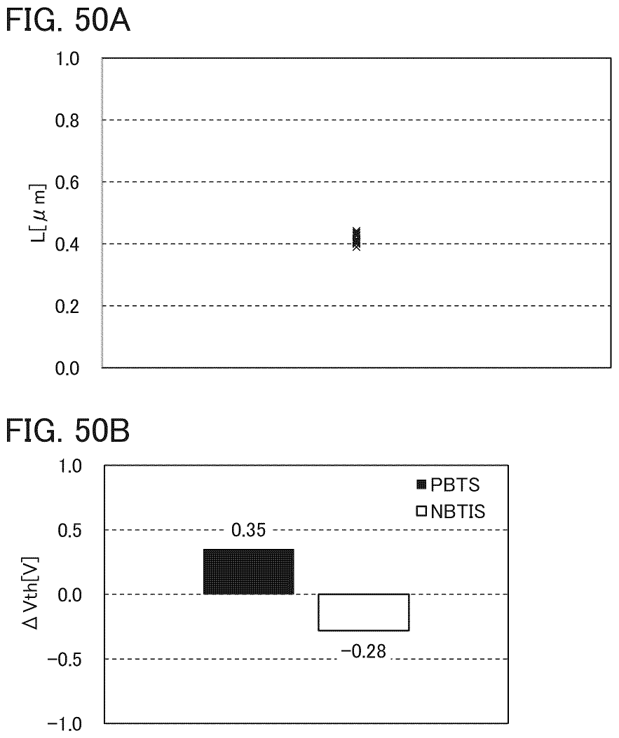

FIG. 50A is a graph showing the effective channel lengths L [μm] of the transistors manufactured in this example. The effective channel lengths L were calculated with reference to FIG. 48. The average value of the effective channel lengths L was 0.41 μm, which was close to the designed channel length, 0.50 μm. In addition, 3σ of the effective channel lengths L was 0.04 μm, which was much smaller than the average value of the effective channel lengths L, 0.41 μm. Thus, it was confirmed that a variation in the effective channel length L between the transistors was extremely small.

Next, the reliability of the transistors manufactured in the above manner was evaluated by a PBTS test and an NBTIS test. The PBTS test and the NBTIS test were performed under conditions similar to those described in Example 3. Here, the transistors had a threshold voltage of 0.29 V before the PBTS test and before the NBTIS test.

FIG. 50B shows the amount of change ΔVth [V] in threshold voltage before and after the PBTS test and the amount of change ΔVth [V] in threshold voltage before and after the NBTIS test. As shown in FIG. 50B, it was confirmed that both the amount of change in threshold voltage before and after the PBTS test and the amount of change in threshold voltage before and after the NBTIS test were small, indicating high reliability.

### Example 5

This example describes manufacture and evaluation results of a transistor of one embodiment of the present invention.

In this example, the transistor corresponding to the structure of the transistor 100 illustrated in FIG. 6A, FIG. 6B, FIG. 6C, and the like was manufactured. For the method for manufacturing the transistor, FIG. 24A to FIG. 27B can be referred to.

First, the insulating layer 101 and the conductive layer 112a were formed over the substrate 102, which was a glass substrate, under conditions similar to those described in Example 3. Then, the insulating layer 110a and the insulating layer 110b were formed in this order over the conductive layer 112a and the insulating layer 101. As the insulating layer 110a, an approximately 100-nm-thick silicon nitride film was formed by a PECVD method. Specifically, the insulating layer 110a was formed using a SiH₄ gas at a flow rate of 200 sccm, a N₂ gas at a flow rate of 2000 sccm, and a NH₃ gas at a flow rate of 100 sccm under the conditions where the pressure was 100 Pa, the power supply was 2000 W, and the substrate temperature was 350° C. As the insulating layer 110b, a 500-nm-thick silicon oxynitride film was formed by a PECVD method. Specifically, the insulating layer 110b was formed using a SiH₄ gas at a flow rate of 290 sccm and a N₂₀ gas at a flow rate of 8700 sccm under the conditions where the pressure was 200 Pa, the power supply was 1160 W, and the substrate temperature was 350° C.

Here, the thickness of the insulating layer 110b was set to the designed channel length of the transistor. In other words, the designed channel length of the transistor was 0.50 μm.

Next, plasma treatment was performed for 240 seconds in an atmosphere containing a N₂₀ gas. The flow rate of the N₂O gas was 3000 sccm, the pressure was 133 Pa, and the power supply was 500 W.

Subsequently, over the insulating layer 110b, an approximately 20-nm-thick In—Ga—Zn oxide film was formed, so that the metal oxide layer 149 was formed. The In—Ga—Zn oxide film was formed by a sputtering method using a metal oxide target whose atomic ratio was In:Ga:Zn=1:1:1 with an oxygen flow rate ratio of 100% at a substrate temperature of room temperature. After the formation of the In—Ga—Zn oxide film, heat treatment was performed at 250° C. for one hour. After that, the metal oxide layer 149 was removed by a wet etching method.

Then, the insulating layer 110c and the insulating layer 110d were formed in this order over the conductive layer 110b. As the insulating layer 110c, an approximately 50-nm-thick silicon nitride film was formed by a PECVD method. Specifically, the insulating layer 110c was formed using a SiH₄ gas at a flow rate of 200 sccm, a N₂ gas at a flow rate of 2000 sccm, and a NH₃ gas at a flow rate of 100 sccm under the conditions where the pressure was 100 Pa, the power supply was 2000 W, and the substrate temperature was 350° C. The insulating layer 110d was formed under conditions similar to those described in Example 3. Subsequently, the conductive layer 112b was formed under conditions similar to those described in Example 3.

Then, the conductive layer 112b was processed by a wet etching method, so that the openings 143 were formed in the conductive layer 112b. Furthermore, the insulating layer 110d, the insulating layer 110c, the insulating layer 110b, and the insulating layer 110a were processed by a dry etching method, so that the openings 141 were formed in the insulating layer 110d, the insulating layer 110c, the insulating layer 110b, and the insulating layer 110a. Three sets of the opening 143 and the opening 141 were formed in parallel.

Next, a metal oxide film was formed as the semiconductor film 108f over the insulating layer 110d and the conductive layer 112b. As the semiconductor film 108f, an approximately 50-nm-thick In—Ga—Zn oxide film was formed. The In—Ga—Zn oxide film was formed by a sputtering method using a metal oxide target whose atomic ratio was In:Ga:Zn=1:1:1 with an oxygen flow rate ratio of 50% at a substrate temperature of 200° C. After the formation of the In—Ga—Zn oxide film, heat treatment was performed at 350° C. in a CDA atmosphere for one hour. After that, the semiconductor film 108f was processed to form a metal oxide layer as the semiconductor layer 108.

Next, the insulating layer 106 was formed over the insulating layer 110d, the conductive layer 112b, and the semiconductor layer 108. The insulating layer 106 was formed under conditions similar to those described in Example 3.

Then, conductive films to be the conductive layer 104 were formed over the insulating layer 106 and processed, so that the conductive layer 104 was formed. As the conductive films to be the conductive layer 104, an approximately 50-nm-thick titanium film, an approximately 200-nm-thick aluminum film, and an approximately 50-nm-thick titanium film were formed in this order by a sputtering method.

After that, the insulating layer 109 and a planarization layer were formed under conditions similar to those described in Example 3.

The transistor manufactured in this example was an n-channel transistor, and the designed channel length was 0.50 μm as described above. The designed channel width was 18.84 μm (the three openings 141 each having an opening diameter of 2 μmφ).

Next, the transistor manufactured in this example was subjected to a constant current stress test. In the constant current stress test, a state where the source voltage Vs was 0 V, the drain voltage Vd was 6.0 V, the gate voltage Vg was 5.0 V, the drain current Id was 100 μA, and the substrate temperature was 85° C. was maintained for a predetermined time. In this example, the predetermined time is a retention time. Here, the conductive layer 112b was made to function as the source electrode.

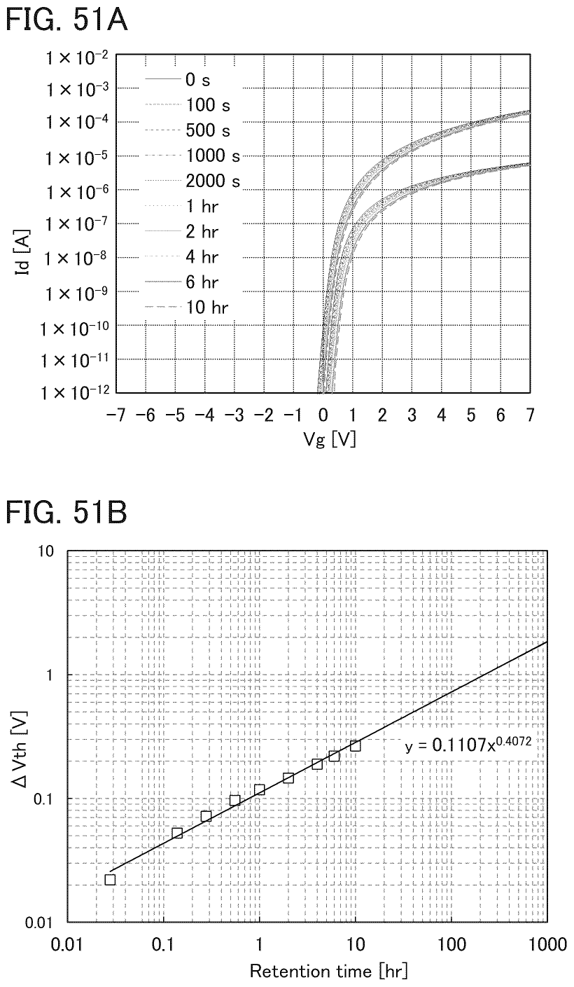

FIG. 51A shows the Id-Vg characteristics of the transistor of the case where the conductive layer 112b was made to function as the source electrode. In FIG. 51A, the vertical axis represents the drain current Id [A] and the horizontal axis represents the gate voltage Vg [V].

As the measurement conditions of the Id-Vg characteristics of the transistor, the voltage applied to the conductive layer 104 (gate voltage Vg) was changed from −7 V to +7 V in increments of 0.1 V. The voltage applied to the source electrode (source voltage Vs) was 0 V, and the voltage applied to the drain electrode (drain voltage Vd) was 0.1 V or 5.1 V. The Id-Vg characteristics of the transistor of the cases where the retention time was 0 s, 100 s, 500 s, 1000 s, 2000 s, 1 hr, 2 hr, 4 hr, 6 hr, and 10 hr were measured. Note that in FIG. 51A, two pieces of data are shown as the drain current Id [A]. Among the two pieces of data, the data with a larger value corresponds to the drain voltage Vd=5.1 V, and the data with a smaller value corresponds to the drain voltage Vd=0.1 V.

As shown in FIG. 51A, it was confirmed that the transistor manufactured in this example had a high on-state current irrespective of the retention time and had favorable switching characteristics. It was also confirmed that the transistor manufactured in this example had a threshold voltage higher than 0 V irrespective of the retention time and had normally-off characteristics.

FIG. 51B is a graph showing the amounts of change ΔVth [V] in threshold voltage of the transistor of the cases where the retention time was 100 s, 500 s, 1000 s, 2000 s, 1 hr, 2 hr, 4 hr, 6 hr, and 10 hr. As each of the amounts of change ΔVth, the amount of change relative to a retention time of 0 s is shown. Here, the drain voltage Vd was set to 5.1 V.

In FIG. 51B, the horizontal axis represents the retention time [hr], and the vertical axis represents the amount of change ΔVth [V]. FIG. 51B shows an approximate expression based on the actually measured value of the amount of change ΔVth. The approximate expression was y=0.1107×^{0.4072}, where x is the retention time [hr] and y is the amount of change Vth [V]. Extrapolation from the approximate expression showed that the amount of change ΔVth of the case where the retention time is 1000 hr is 1.85 V.

As shown in FIG. 51B, it was estimated that the amount of change in threshold voltage of the transistor manufactured in this example is less than 2.00 V even when the retention time is 1000 hr, which confirmed that the amount of change in threshold voltage of the transistor is small.

### REFERENCE NUMERALS

10A: semiconductor device, 10B: semiconductor device, 10: semiconductor device, 11B: subpixel, 11G: subpixel, 11R: subpixel, 50A: display device, 50B: display device, 50C: display device, 50D: display device, 50E: display device, 50F: display device, 50G: display device, 50H: display device, 50I: display device, 50J: display device, 50K: display device, 60: liquid crystal element, 100A: transistor, 100B: transistor, 100C: transistor, 100D: transistor, 100E: transistor, 100F: transistor, 100G: transistor, 100H: transistor, 100: transistor, 101a: insulating layer, 101b: insulating layer, 101: insulating layer, 102: substrate, 103: conductive layer, 104a: conductive layer, 104: conductive layer, 105: conductive layer, 106: insulating layer, 107a: conductive layer, 107b: conductive layer, 108a: semiconductor layer, 108f: semiconductor film, 108i: region, 108n: region, 108na: region, 108nb: region, 108: semiconductor layer, 109: insulating layer, 110a: insulating layer, 110b: insulating layer, 110c: insulating layer, 110d: insulating layer, 110e: insulating layer, 110: insulating layer, 111B: pixel electrode, 111G: pixel electrode, 111R: pixel electrode, 111S: pixel electrode, 112a: conductive layer, 112b: conductive layer, 112c: conductive layer, 112d: conductive layer, 112f: conductive film, 113B: EL layer, 113G: EL layer, 113R: EL layer, 113S: functional layer, 113: EL layer, 114: common layer, 115: common electrode, 117: light-blocking layer, 120: conductive layer, 121: insulating layer, 123: conductive layer, 124B: conductive layer, 124G: conductive layer, 124R: conductive layer, 125: insulating layer, 126B: conductive layer, 126G: conductive layer, 126R: conductive layer, 127: insulating layer, 128: layer, 130B: light-emitting element, 130G: light-emitting element, 130R: light-emitting element, 130S: light-receiving element, 131: protective layer, 132B: coloring layer, 132G: coloring layer, 132R: coloring layer, 133B: layer, 133G: layer, 133R: layer, 133: layer, 140: connection portion, 141a: opening, 141: opening, 142: adhesive layer, 143a: opening, 143: opening, 144: adhesive layer, 148: opening, 149: metal oxide layer, 150: transistor, 152: substrate, 153: insulating layer, 162: display portion, 164: circuit portion, 165a: conductive layer, 165b: conductive layer, 165: conductive layer, 166a: conductive layer, 166b: conductive layer, 166: conductive layer, 172: FPC, 173: IC, 190: capacitor, 200: transistor, 201: pixel, 204: connection portion, 205B: transistor, 205D: transistor, 205G: transistor, 205R: transistor, 205S: transistor, 223: connector, 224: insulating layer, 225: insulating layer, 235: insulating layer, 237: insulating layer, 242: connection layer, 260a: polarizing plate, 260b: polarizing plate, 261: insulating layer, 262: liquid crystal, 263: conductive layer, 264: conductive layer, 265: alignment layer, 352: finger, 353: layer, 355: circuit layer, 357: layer, 401: insulating layer, 402: glass substrate, 406: insulating layer, 408: metal oxide layer, 411a: conductive layer, 411b: conductive layer, 412a: conductive layer, 412b: conductive layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first insulating layer comprising hydrogen;
a first conductive layer over the first insulating layer;
a second insulating layer over the first conductive layer; and
a metal oxide layer,
wherein a first opening reaching the first conductive layer is provided in the second insulating layer, and
wherein the metal oxide layer comprises a region positioned in the first opening and being in contact with the first conductive layer.

2. A semiconductor device comprising:
a first insulating layer comprising hydrogen;
a first conductive layer over the first insulating layer;
a second insulating layer over the first conductive layer; and
a metal oxide layer,
wherein a first opening reaching the first conductive layer is provided in the second insulating layer,
wherein the metal oxide layer comprises a region positioned in the first opening and being in contact with the first conductive layer,
wherein the second insulating layer comprises a first layer and a second layer over the first layer,
wherein the first layer comprises a region in contact with the first insulating layer, and
wherein the first insulating layer comprises a region with a hydrogen content higher than or equal to a hydrogen content of the first layer.

3. (canceled)

4. The semiconductor device according to claim 2,
wherein a hydrogen diffusion coefficient of the first layer is lower than a hydrogen diffusion coefficient of the first conductive layer.

5. The semiconductor device according to claim 4,
wherein the hydrogen diffusion coefficient of the first layer and the hydrogen diffusion coefficient of the first conductive layer are measured by TDS or SIMS.

6. The semiconductor device according to claim 2,
wherein the second layer comprises oxygen.

7. The semiconductor device according to claim 1, further comprising:
a second conductive layer provided over the second insulating layer,
wherein a second opening overlapping with the first opening is provided in the second conductive layer, and
wherein the second conductive layer comprises a region in contact with the metal oxide layer.

8. The semiconductor device according to claim 7, further comprising:
a third insulating layer over the metal oxide layer and a third conductive layer comprising a region facing the metal oxide layer with the third insulating layer therebetween,
wherein the third insulating layer comprises a region positioned in the first opening.

9. The semiconductor device according to claim 2, further comprising:
a second conductive layer provided over the second insulating layer,
wherein a second opening overlapping with the first opening is provided in the second conductive layer,
wherein the second conductive layer comprises a region in contact with the metal oxide layer,
wherein the second insulating layer comprises a third layer over the second layer and a fourth layer over the third layer,
wherein the fourth layer comprises a region in contact with the second conductive layer, and
wherein the fourth layer comprises a region with a hydrogen content higher than or equal to a hydrogen content of the third layer.

10. The semiconductor device according to claim 9, further comprising:
a third insulating layer over the metal oxide layer and a third conductive layer comprising a region facing the metal oxide layer with the third insulating layer therebetween,
wherein the third insulating layer comprises a region positioned in the first opening.

11. The semiconductor device according to claim 10,
wherein the hydrogen content of the fourth layer and the hydrogen content of the third layer are measured by SIMS or TDS.

12. The semiconductor device according to claim 10,
wherein a hydrogen diffusion coefficient of the third layer is lower than a hydrogen diffusion coefficient of the second conductive layer.

13. The semiconductor device according to claim 12,
wherein the hydrogen diffusion coefficient of the third layer and the hydrogen diffusion coefficient of the second conductive layer are measured by TDS or SIMS.

14. The semiconductor device according to claim 9,
wherein the third layer comprises a material included in the first layer, and
wherein the fourth layer comprises a material included in the first insulating layer.

15. A method for manufacturing a semiconductor device,
the method comprising the steps of:
forming a first insulating layer comprising hydrogen;
forming a first conductive layer over the first insulating layer;
forming a second insulating layer over the first conductive layer;
forming a second conductive layer over the second insulating layer;
processing the second conductive layer to form a first opening, the first opening comprising a region overlapping with the first conductive layer;
processing the second insulating layer to form a second opening reaching the first conductive layer, the second opening comprising a region overlapping with the first opening;
forming a metal oxide layer comprising a region positioned in the second opening and in contact with the first conductive layer and a region in contact with the second conductive layer;
forming a third insulating layer over the metal oxide layer, the third insulating layer comprising a region positioned in the second opening; and
forming a third conductive layer, the third conductive layer comprising a region facing the metal oxide layer with the third insulating layer therebetween.

16. The method for manufacturing the semiconductor device, according to claim 15,
wherein the second insulating layer comprises a first layer comprising a region in contact with the first insulating layer and a second layer over the first layer, and
wherein a proportion of molecules comprising hydrogen in a film formation gas for the first layer is lower than or equal to a proportion of molecules comprising hydrogen in a film formation gas for the first insulating layer.

17. The method for manufacturing the semiconductor device, according to claim 16,
wherein the first layer is formed to have a hydrogen diffusion coefficient lower than a hydrogen diffusion coefficient of the first conductive layer.

18. The method for manufacturing the semiconductor device, according to claim 16, the method further comprising the step of:
supplying oxygen to the second layer before the second conductive layer is formed.

19. (canceled)

20. (canceled)

21. (canceled)
